(19) United States
(12) Patent Application Publication
(10) Pub. No.: US 2024/0315133 A1
(43) Pub. Date: Sep. 19, 2024

(54) ORGANIC LIGHT EMITTING DEVICE AND METHOD OF PRODUCING SAME

(71) Applicant: KYULUX, INC., Fukuoka-shi, Fukuoka (JP)

(72) Inventors: Asuka YOSHIZAKI, Fukuoka-shi, Fukuoka (JP); Hayato KAKIZOE, Fukuoka-shi, Fukuoka (JP)

(21) Appl. No.: 18/569,767

(22) PCT Filed: Jun. 6, 2022
(86) PCT No.: PCT/JP2022/022823

§ 371 Date: Dec. 13, 2023

(30) Foreign Application Priority Data
Jun. 15, 2021 (JP) 2021-099117

(51) Int. Cl. H10K 85/60; C09K 11/06; H10K 50/11; H10K 50/18

(52) U.S. Cl. CPC H10K 85/6574; C09K 11/06; H10K 85/657; H10K 85/6572; C09K 2211/1018; H10K 50/11; H10K 50/181

(57) ABSTRACT

To provide an organic light emitting device having a light emitting layer excellent in orientation. An organic light emitting device including a base layer containing a compound represented by the following general formula, having formed on the surface thereof a light emitting layer containing a host material and a delayed fluorescent material. X represents O, S, or N(R⁹); R¹ to R⁸ each represent a hydrogen atom, a deuterium atom, or a substituent; R⁹ represents a substituent; and a benzofuro structure, a benzothieno structure, or an indolo structure is condensed to the benzene ring of the following general formula, or R⁶ represents a carbazolyl group, a dibenzofuryl group, or a dibenzothienyl group.

### TECHNICAL FIELD

The present invention relates to an organic light emitting device using a delayed fluorescent material and a method of producing the device.

### BACKGROUND ART

Studies for enhancing the light emission efficiency of organic light-emitting devices such as organic electroluminescent devices (organic EL devices) are being made actively. In particular, various kinds of efforts have been made for increasing light emission efficiency by newly developing and combining an electron transporting material, a hole transporting material, a host material and a light emitting material to constitute an organic electroluminescent device. Among them, there are seen studies relating to an organic light emitting device that utilizes a delayed fluorescent material.

A delayed fluorescent material is a material which, in an excited state, after having undergone reverse intersystem crossing from an excited triplet state to an excited singlet state, emits fluorescence when returning back from the excited singlet state to a ground state thereof. Fluorescence through the route is observed later than fluorescence from the excited singlet state directly occurring from the ground state (ordinary fluorescence), and is therefore referred to as delayed fluorescence. Here, for example, in the case where a light-emitting compound is excited through carrier injection thereinto, the occurring probability of the excited singlet state to the excited triplet state is statistically 25%/75%, and therefore improvement of light emission efficiency by the fluorescence alone from the directly occurring excited singlet state is limited. On the other hand, in a delayed fluorescent material, not only the excited singlet state thereof but also the excited triplet state can be utilized for fluorescent emission through the route via the above-mentioned reverse intersystem crossing, and therefore as compared with an ordinary fluorescent material, a delayed fluorescent material can realize a higher emission efficiency.

As such a delayed fluorescent material, there has been proposed a benzene derivative having a heteroaryl group such as a carbazolyl group or a diphenylamino group, and at least two cyano groups, and it has been confirmed that an organic EL device using the benzene derivative in a light emitting layer provides a high emission efficiency (see PTL 1).

Also, NPL 1 reports that a carbazolyldicyanobenzene derivative (4CzTPN) is a thermally activated delayed fluorescent material and that an organic electroluminescent device using the carbazolyldicyanobenzene derivative attained a high internal EL quantum efficiency.

On the other hand, using a delayed fluorescent material in a light emitting layer as an assist dopant but not as a light emitting material therein has been reported (see PTL 2). This describes adding, in addition to a host material and a fluorescent material, a delayed fluorescent material having an intermediate lowest excited singlet energy between the host material and the fluorescent light emitting material to the light emitting layer to improve emission efficiency.

### CITATION LIST

### Patent Literature

PTL 1: JP2014-43541A
PTL 2: JP2015-179809A

### Non-Patent Literature

NPL 1: H. Uoyama, et al., Nature 492, 234 (2012)

### SUMMARY OF INVENTION

### Technical Problem

As described above, studies have been actively made for improving the light emission efficiency by using a delayed fluorescent material in a light emitting layer of an organic electroluminescent device. For further enhancing the light emission efficiency of an organic electroluminescent device, it is desirable to enhance the orientation of the light emitting material in the light emitting layer. Accordingly, there is a demand of enhancing the orientation also in the light emitting layer using the delayed fluorescent material, but sufficient studies on measures for enhancing the orientation have not yet been made.

Under the circumstances, the present inventors have made earnest investigations for achieving the object, i.e., the enhancement of the orientation of a light emitting layer in an organic light emitting device having the light emitting layer that contains a delayed fluorescent material.

### Solution to Problem

As a result of the earnest investigations performed for achieving the object, the present inventors have found that the orientation of the light emitting material of the light emitting layer can be enhanced by forming the light emitting layer containing a delayed fluorescent material on the surface of a base layer containing a compound that has a particular structure. The present invention is proposed based on the knowledge, and specifically has the following configurations.
[1] An organic light emitting device including a base layer and a light emitting layer laminated on a surface of the base layer,
the light emitting layer containing a first organic compound and a second organic compound,
the second organic compound being a delayed fluorescent material having lowest excited singlet energy that is lower than the first organic compound,
the base layer containing a compound represented by the following general formula (1):

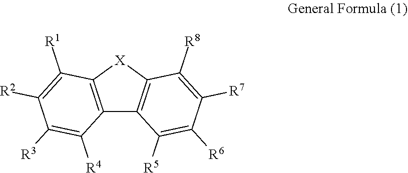

wherein in the general formula (1), X represents O, S, or N(R⁹), R¹ to R⁸ each independently represent a hydrogen atom, a deuterium atom, or a substituent, and R⁹ represents a substituent, in which R¹ and R², R² and R³, R³ and R⁴, R⁵ and R⁶, R⁶ and R⁷, and R⁷ and R⁸ each may be bonded to each other to form a hydrocarbon ring, and a hydrogen atom of the hydrocarbon ring may be substituted,
provided that R¹ and R², R² and R³, or R³ and R⁴ are bonded to each other to form a substituted or unsubstituted benzofuro structure, a substituted or unsubstituted benzothieno structure, or a substituted or unsubstituted indolo structure, or
R⁶ represents a substituted or unsubstituted carbazolyl group, a substituted or unsubstituted dibenzofuryl group, or a substituted or unsubstituted dibenzothienyl group.
[2] The organic light emitting device according to the item [1], wherein all condensed ring structures included in the compound each contain 5 or less rings.
[3] The organic light emitting device according to the item [1] or [2], wherein all condensed ring structures included in the compound each contain 3 or less rings.
[4] The organic light emitting device according to any one of the items [1] to [3], wherein X represents N(R⁹), and R⁹ represents a substituted or unsubstituted aryl group.
[5] The organic light emitting device according to any one of the items [1] to [4], wherein R¹ and R², R² and R³, or R³ and R⁴ are bonded to each other to form a substituted or unsubstituted benzofuro structure.
[6] The organic light emitting device according to any one of the items [1] to [5], wherein in the case where X represents N(R⁹), and R⁶ represents a substituted or unsubstituted carbazolyl group, the carbazolyl group is a substituted or unsubstituted carbazol-9-yl group.
[7] The organic light emitting device according to any one of the items [1] to [6], wherein the first organic compound includes a carbazole structure, a dibenzofuran structure, or a dibenzothiophene structure.
[8] The organic light emitting device according to any one of the items [1] to [7], wherein the first organic compound is a compound represented by the general formula (1), and may be the same as or different from the compound contained in the base layer.
[9] The organic light emitting device according to any one of the items [1] to [8], wherein the second organic compound includes a carbazole structure, a dibenzofuran structure, or a dibenzothiophene structure.
[10] The organic light emitting device according to any one of the items [1] to [9], wherein the second organic compound has a difference ΔE_{ST} in energy between lowest excited singlet state and lowest excited triplet state at 77 K of 0.3 eV or less.
[11] The organic light emitting device according to any one of the items [1] to [10], wherein the second organic compound is a compound consisting of atoms selected from the group consisting of a carbon atom, a hydrogen atom, a deuterium atom, a nitrogen atom, an oxygen atom, and a sulfur atom.
[12] The organic light emitting device according to any one of the items [1] to [11], wherein the light emitting layer has a concentration of the second organic compound of 5 to 50% by weight.
[13] The organic light emitting device according to any one of the items [1] to [12], wherein the light emitting layer further contains a third organic compound having lowest excited singlet energy that is lower than the first organic compound and the second organic compound.
[14] The organic light emitting device according to the item [13], wherein the light emitting layer has a concentration of the third organic compound of 3% by weight or less.
[15] The organic light emitting device according to the item or [14], wherein the third organic compound is a compound consisting of atoms selected from the group consisting of a carbon atom, a hydrogen atom, a deuterium atom, a nitrogen atom, a boron atom, a fluorine atom, an oxygen atom, and a sulfur atom.
[16] The organic light emitting device according to any one of the items [1] to [15], wherein the organic light emitting device is an organic electroluminescent device.
[17] The organic light emitting device according to the item [16], wherein the base layer is an electron barrier layer.
[18] A method of producing an organic light emitting device, including forming a light emitting layer on a surface of a base layer,
the light emitting layer containing a first organic compound and a second organic compound,
the second organic compound being a delayed fluorescent material having lowest excited singlet energy that is lower than the first organic compound,
the base layer containing a compound represented by the general formula (1).

### Advantageous Effects of Invention

The organic light emitting device of the present invention contains a light emitting material having a high orientation in a light emitting layer containing a delayed fluorescent material. Accordingly, the organic light emitting device of the present invention has a high light emission efficiency. According to the production method of the present invention, an organic light emitting device containing a light emitting material having a high orientation in a light emitting layer can be easily produced.

### BRIEF DESCRIPTION OF DRAWINGS

FIG. 1 is a schematic cross sectional view showing an example of a layer configuration of an organic electroluminescent device.

### DESCRIPTION OF EMBODIMENT

The contents of the present invention will be described in detail below. The description of the constitutional elements described below may be made with reference to representative embodiments or specific examples of the present invention in some cases, but the present invention is not limited to the embodiments and the examples. In the description herein, the numeral range expressed by using “to” means a range that encompasses the numerals described before and after “to” as the lower limit value and the upper limit value. In the description herein, the expression “consisting of” means that only the items described before “consisting of” are contained, but no other item is contained. A part or the whole of the hydrogen atoms existing in the molecule of the compound used in the present invention may be replaced by a deuterium atom (²H or D). In the chemical structural formulae in the description herein, a hydrogen atom is shown by H, or the presence thereof is omitted. For example, the position of a benzene ring where the presence of an atom bonded to the ring skeleton-forming carbon atom thereof is omitted means that H is bonded to the ring skeleton-forming carbon atom. In the description herein, the term “substituent” means an atom or an atomic group other than a hydrogen atom and a deuterium atom. The expression “substituted or unsubstituted” means that a hydrogen atom may be replaced by a deuterium atom or a substituent.

### (Features of Organic Light Emitting Device)

The organic light emitting device of the present invention includes a base layer containing a compound represented by the general formula (1), and a light emitting layer laminated on the surface of the base layer. The light emitting layer contains a first organic compound and a second organic compound. The second organic compound is a delayed fluorescent material having lowest excited singlet energy that is lower than the first organic compound.

The light emitting layer may be laminated to cover directly the entire of one surface of the base layer (i.e., the surface on one side of the base layer), or may be laminated to cover directly a part thereof. At least a part of the light emitting layer is laminated directly on the surface of the base layer, and it is preferred that the entire of the light emitting layer is laminated directly on the surface of the base layer.

According to the present invention, the light emitting layer containing the second organic compound as a delayed fluorescent material is formed on the surface of the base layer containing the compound represented by the general formula (1), and thereby the orientation of the second organic compound in the light emitting layer can be enhanced. For example, as compared to the case where the base layer is not formed, and the case where the base layer is constituted by the first organic compound of the light emitting layer (the first organic compound in this case is not a compound represented by the general formula (1)), the use of the base layer of the present invention can enhance the orientation of the light emitting layer formed on the surface thereof. The orientation of the light emitting layer can be further enhanced by using a compound represented by the general formula (1) as the first organic compound.

The light emitting layer may further contain, in addition to the first organic compound and the second organic compound, a third organic compound having lowest excited singlet energy that is lower than these compound. In this case, according to the present invention, the third organic compound as a light emitting material also shows a high orientation in addition to the second organic compound. Therefore, the present invention can be effectively applied not only to an organic electroluminescent device having a light emitting layer of two-component system containing the first organic compound and the second organic compound, but also to an organic electroluminescent device having a light emitting layer of three-component system containing the first organic compound, the second organic compound, and the third organic compound. The present invention can also be applied to an organic electroluminescent device having a light emitting layer of four or higher-component system containing multiple third organic compounds.

In the description herein, the orientation can be evaluated by an S value as an orientation parameter. The S value is also referred to as an orientation value, and is an index showing the extent of orientation of the light emitting material in the light emitting layer. A larger negative value (i.e., a smaller value) thereof means a higher orientation. The S value can be determined by the method described in Scientific Reports, 2017, 7, 8405.

### (Base Layer)

The base layer contains a compound represented by the following general formula (1).

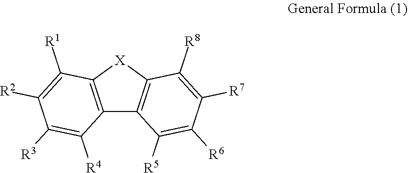

In the general formula (1), X represents O, S, or N(R⁹). X may be O. X may be S. X may be N(R⁹), and R⁹ represents a substituent. R⁹ is preferably a substituted or unsubstituted aryl group, a substituted or unsubstituted heteroaryl group, or a substituted or unsubstituted alkyl group, more preferably a substituted or unsubstituted aryl group or a substituted or unsubstituted heteroaryl group, and further preferably a group bonded via a benzene ring. Examples of the substituent in the case where the aryl group, the heteroaryl group, or the alkyl group is substituted include the groups of the substituent group D described later. Preferred examples of R⁹ include a phenyl group substituted by the substituent group D and a naphthyl group substituted by the substituent group D, and also include an unsubstituted phenyl group and an unsubstituted naphthyl group.

In the general formula (1), R¹ to R⁸ each independently represent a hydrogen atom, a deuterium atom, or a substituent. R¹ and R², R² and R³, R³ and R⁴, R⁵ and R⁶, R⁶ and R⁷, and R⁷ and R⁸ each may be bonded to each other to form a hydrocarbon ring, and a hydrogen atom of the hydrocarbon ring may be substituted. The hydrocarbon ring herein may be either an aliphatic hydrocarbon ring or an aromatic hydrocarbon ring. The aliphatic hydrocarbon ring and the aromatic hydrocarbon ring each may be condensed with another ring, or may not be condensed therewith. The aliphatic hydrocarbon ring is preferably a 5-membered to 7-membered ring, and more preferably 5-membered or 6-membered ring. The aromatic hydrocarbon ring may be a benzene ring. Preferred examples of the substituent on the hydrocarbon ring include the groups of the substituent group D described later. A compound in which all R¹ and R², R² and R³, R³ and R⁴, R⁵ and R⁶, R⁶ and R⁷, and R⁷ and R⁸ are not bonded to each other may also be preferably used.

In the general formula (1), R¹ and R², R² and R³, or R³ and R⁴ are bonded to each other to form a substituted or unsubstituted benzofuro structure, a substituted or unsubstituted benzothieno structure, or a substituted or unsubstituted indolo structure (first condition), or R⁶ represents a substituted or unsubstituted carbazolyl group, a substituted or unsubstituted dibenzofuryl group, or a substituted or unsubstituted dibenzothienyl group (second condition). Both the first condition and the second condition may be satisfied.

In the case where the first condition is satisfied, X may be O or may be S, and is preferably N(R⁹).

The formation of a substituted or unsubstituted benzofuro structure by bonding R¹ and R², R² and R³, or R³ and R⁴ each other forms the following skeletons.

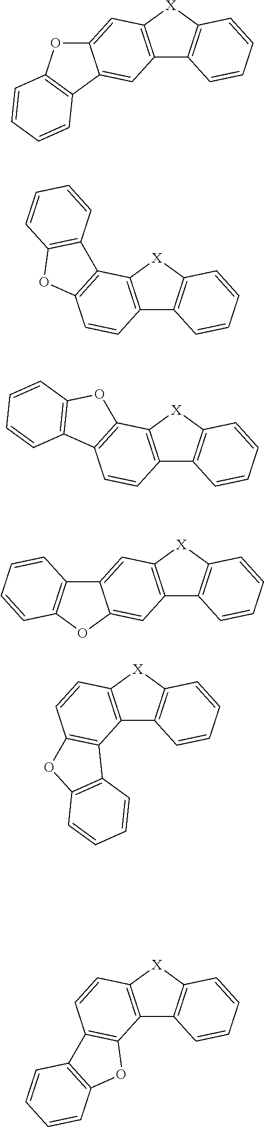

In one preferred embodiment of the present invention, a compound having any of the following skeletons is selected.

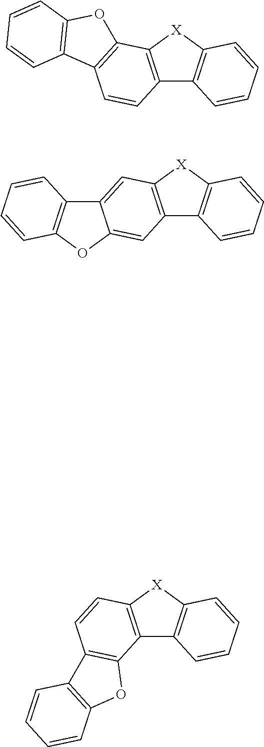

The formation of a substituted or unsubstituted benzothieno structure by bonding R¹ and R², R² and R³, or R³ and R⁴ each other forms the following skeletons.

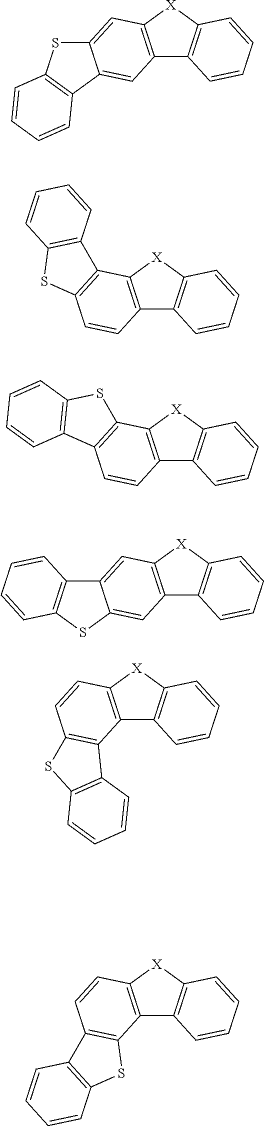

In one preferred embodiment of the present invention, a compound having any of the following skeletons is selected.

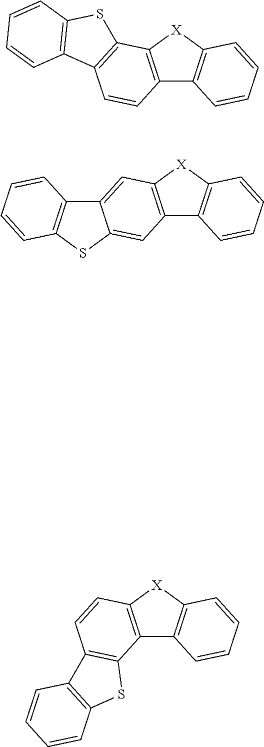

The formation of a substituted or unsubstituted indolo structure by bonding R¹ and R², R² and R³, or R³ and R⁴ each other forms the following skeletons. R represents a substituent, and for the description and the preferred ranges thereof, reference may be made to the description and the preferred ranges of R⁹ described above.

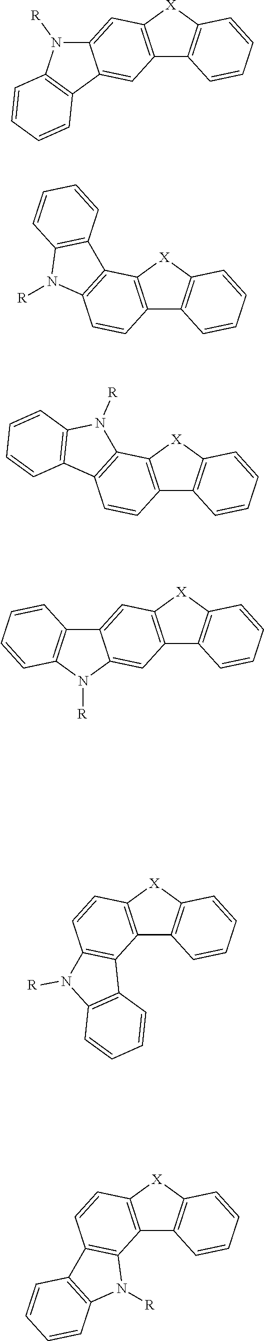

In one preferred embodiment of the present invention, a compound having any of the following skeletons is selected.

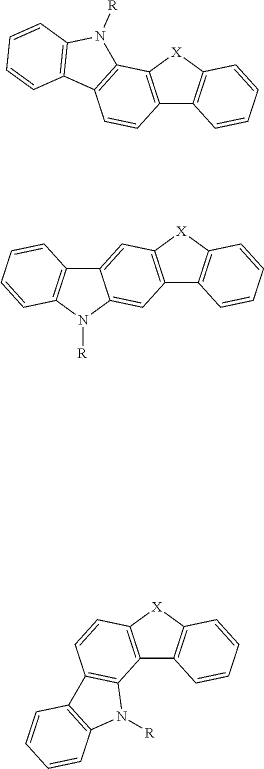

A hydrogen atom of the aforementioned skeletons may be substituted, and preferred examples of the substituent include the substituent group D described later.

In the case where the second condition is satisfied, R⁶ may be a substituted or unsubstituted carbazolyl group, R⁶ may be a substituted or unsubstituted dibenzofuryl group, or R⁶ may be a substituted or unsubstituted dibenzothienyl group.

In the case where R⁶ is a substituted or unsubstituted carbazolyl group, the carbazolyl group is preferably a substituted or unsubstituted carbazol-9-yl group. The carbazolyl group may be a substituted or unsubstituted carbazol-1-yl group, may be a substituted or unsubstituted carbazol-2-yl group, may be a substituted or unsubstituted carbazol-3-yl group, may be a substituted or unsubstituted carbazol-4-yl group, or may be a substituted or unsubstituted carbazol-9-yl group. In one preferred embodiment of the present invention, the carbazolyl group is a substituted or unsubstituted carbazol-9-yl group or a substituted or unsubstituted carbazol-9-yl group. In the case where X is N(R⁹), in particular, the carbazolyl group is preferably a substituted or unsubstituted carbazol-9-yl group.

In the case where R⁶ is a substituted or unsubstituted dibenzofuryl group, the dibenzofuryl may be a dibenzofuryl-1-yl group, may be a dibenzofuryl-2-yl group, may be a dibenzofuryl-3-yl group, or may be a dibenzofuryl-4-yl group. In one preferred embodiment of the present invention, the dibenzofuryl is a substituted or unsubstituted dibenzofuryl-3-yl group.

In the case where R⁶ is a substituted or unsubstituted dibenzothienyl group, the dibenzothienyl may be a dibenzothienyl-1-yl group, may be a dibenzothienyl-2-yl group, may be a dibenzothienyl-3-yl group, or may be a dibenzothienyl-4-yl group. In one preferred embodiment of the present invention, the dibenzothienyl is a substituted or unsubstituted dibenzothienyl-3-yl group.

Examples of the preferred substituent of the carbazolyl group, the dibenzofuryl group, and the dibenzothienyl group include the substituent group D described later.

In one preferred embodiment of the present invention, the compound represented by the general formula (1) that satisfies the second condition is represented by the following general formula (2).

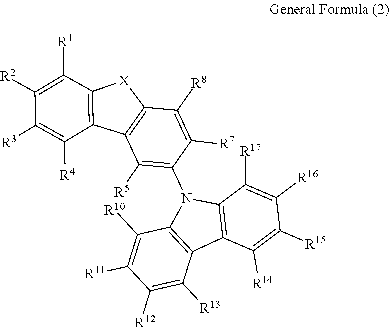

In the general formula (2), X represents O, S, or N(R⁹). For the description and the preferred ranges of X, reference may be made to the corresponding description in the general formula (1).

In the general formula (2), R¹ to R⁸ and R¹⁰ to R¹⁶ each independently represent a hydrogen atom, a deuterium atom, or a substituent. R¹ and R², R² and R³, R³ and R⁴, R⁷ and R⁸, R¹⁰ and R¹¹, R¹¹ and R¹², R¹² and R¹³, R¹⁴ and R¹⁵, R¹⁵ and R¹⁶, and R¹⁶ and R¹⁷ each may be bonded to each other to form a hydrocarbon ring, and a hydrogen atom of the hydrocarbon ring may be substituted. For the description and the preferred ranges of the hydrocarbon ring, reference may be made to the corresponding description in the general formula (1). A compound in which all R¹ and R², R² and R³, R³ and R⁴, R⁷ and R⁸, R¹⁰ and R¹¹, R¹¹ and R¹², R¹² and R¹³, R¹⁴ and R¹⁵, R¹⁵ and R¹⁶, and R¹⁶ and R¹⁷ are not bonded to each other may also be preferably used. The substituent that R¹ to R⁸ and R¹⁰ to R¹⁶ each represent is preferably the substituent group D described later. Examples thereof include a substituted or unsubstituted carbazolyl group and a substituted or unsubstituted aryl group. Examples of the substituent include the substituent group D described later. In the general formula (2), it is preferred that one to three selected from the group consisting of R³, R¹², and R¹⁵ is a substituent. In one preferred embodiment of the present invention, only one to three selected from the group consisting of R³, R¹², and R¹⁵ among R¹ to R⁸ and R¹⁰ to R¹⁶ is substituted.

In one preferred embodiment of the present invention, the compound represented by the general formula (1) that satisfies the second condition is represented by the following general formula (3).

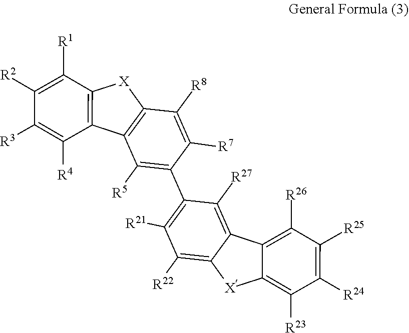

In the general formula (3), X and X′ each independently represent O, S, or N(R⁹). For the description and the preferred ranges of X and X′, reference may be made to the corresponding description in the general formula (1). In the case where X represents N(R⁹), X′ preferably represents O or S.

In the general formula (3), R¹ to R⁸ and R²¹ to R²⁷ each independently represent a hydrogen atom, a deuterium atom, or a substituent. R¹ and R², R² and R³, R³ and R⁴, R⁷ and R⁸, R²¹ and R²², R²³ and R²⁴, R²⁴ and R²⁵, and R²⁵ and R²⁶ each may be bonded to each other to form a hydrocarbon ring, and a hydrogen atom of the hydrocarbon ring may be substituted. For the description and the preferred ranges of the hydrocarbon ring, reference may be made to the corresponding description in the general formula (1). A compound in which all R¹ and R², R² and R³, R³ and R⁴, R⁷ and R⁸, R²¹ and R²², R²³ and R²⁴, R²⁴ and R²⁵, and R²⁵ and R²⁶ are not bonded to each other may also be preferably used. The substituent that R¹ to R⁸ and R²¹ to R²⁷ each represent is preferably the substituent group D described later. Examples thereof include a substituted or unsubstituted carbazolyl group and a substituted or unsubstituted aryl group. Examples of the substituent include the substituent group D described later. In the general formula (3), it is preferred that one or two selected from the group consisting of R³ to R²⁵ is a substituent. In one preferred embodiment of the present invention, only one or two selected from the group consisting of R³ to R²⁵ among R¹ to R⁸ and R²¹ to R²⁷ is substituted.

It is preferred that all the condensed ring structures included in the compound represented by the general formula (1) each contain 5 or less rings. In other words, it is preferred that the compound represented by the general formula (1) does not include a condensed ring structure containing 6 or more rings. All the condensed ring structures included in the compound represented by the general formula (1) each may contain 3 or less rings. It is possible that the compound represented by the general formula (1) includes at least one condensed ring structure containing 5 rings. It is possible that the compound represented by the general formula (1) includes at least one condensed ring structure containing 5 rings and at least one condensed ring structure containing 3 rings, and does not include condensed ring structures containing other numbers of rings. In one preferred embodiment of the present invention, the compound represented by the general formula (1) includes one condensed ring structure containing 5 rings and one condensed ring structure containing 3 rings, and does not include other condensed ring structures than them. In one preferred embodiment of the present invention, the compound represented by the general formula (1) includes two condensed ring structures each containing 5 rings and one condensed ring structure containing 3 rings, and does not include other condensed ring structures than them. In one preferred embodiment of the present invention, the compound represented by the general formula (1) includes three condensed ring structures each containing 3 rings, and does not include other condensed ring structures than them.

Specific examples of the compound represented by the general formula (1) are shown below.

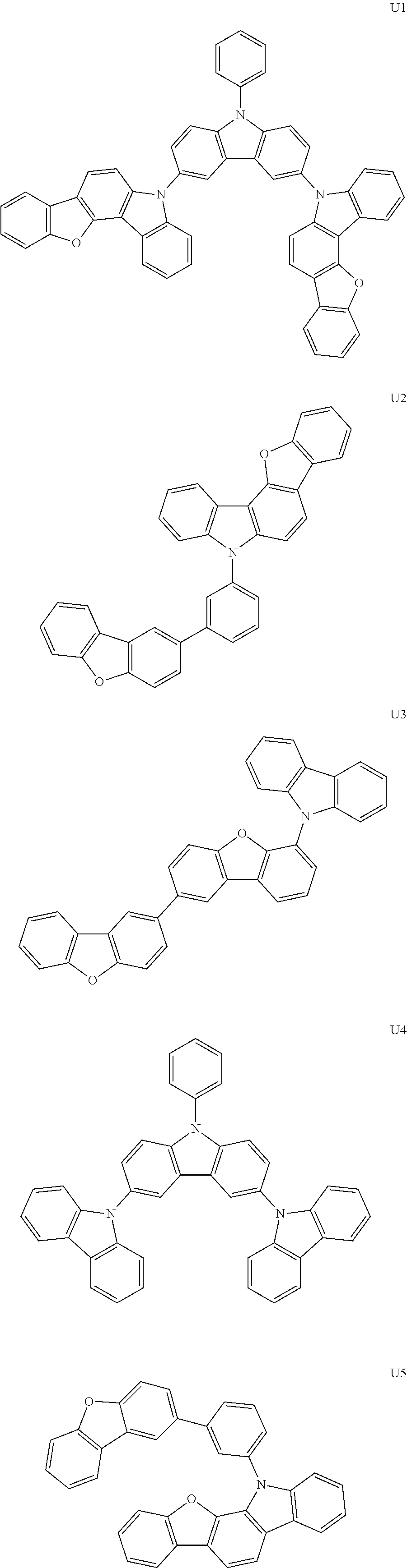

The base layer is preferably constituted only by the compound represented by the general formula (1), or may be a layer mainly containing the compound represented by the general formula (1). The concentration of the compound represented by the general formula (1) in the base layer is preferably 90% by weight or more, and more preferably 99% by weight or more, and for example, may be 99.9% by weight or more, or may be 99.99% by weight or more. Examples of a compound contained in the base layer other than the compound represented by the general formula (1) include a compound having lowest excited singlet energy (E_{S1}) and lowest excited triplet energy (E_{T1}) that are close to the compound represented by the general formula (1). The expression that the energy is close means a difference in energy of less than 0.1 eV, which is preferably less than 0.05 eV, more preferably less than 0.03 eV, and further preferably less than 0.01 eV.

The thickness of the base layer is preferably 1 nm or more, and more preferably 3 nm or more, and for example, may be 5 nm or more, or may be 10 nm or more. The thickness of an layer in contact with the base layer is preferably less than 30 nm, and more preferably less than 20 nm, and for example, may be 10 nm or less.

The thickness of the base layer is preferably smaller than the thickness of the light emitting layer. The thickness of the base layer is preferably ½ or less of the thickness of the light emitting layer, and more preferably ⅓ or less thereof, and for example, may be ¼ or less. The thickness of the base layer is preferably 1/20 or more thereof, and for example, may be 1/10 or more thereof.

### (Constitutional Materials of Light Emitting Layer)

The light emitting layer contains a first organic compound and a second organic compound. The second organic compound is a delayed fluorescent material having lowest excited singlet energy that is lower than the first organic compound. The light emitting layer may additionally contain a third organic compound having lowest excited singlet energy that is lower than the first organic compound and the second organic compound.

The difference in lowest excited singlet energy E_{S1}(1)−E_{S1}(2) between the first organic compound and the second organic compound may be in a range of 0.3 eV or more, may be in a range of 0.5 eV or more, or may be in a range of 0.7 eV or more, and may be in a range of 1.6 eV or less, may be in a range of 1.3 eV or less, or may be in a range of 0.9 eV or less.

In the case where the third organic compound is used, the difference in lowest excited singlet energy E_{S1}(2)−E_{S1}(3) between the second organic compound and the third organic compound may be in a range of 0.03 eV or more, or may be in a range of 0.06 eV or more, and may be in a range of 0.6 eV or less, may be in a range of 0.3 eV or less, or may be in a range of 0.1 eV or less.

The first organic compound preferably has lowest excited triplet energy at 77 K (Kelvin) that is larger than the second organic compound and the third organic compound. The lowest excited triplet energy at 77 K (Kelvin) thereof is preferably larger than the second organic compound and the third organic compound, but may be smaller than the compounds.

The concentration of the first organic compound contained in the light emitting layer is preferably the concentration of the second organic compound or more. The concentration of the second organic compound in the light emitting layer is preferably 5 to 50% by weight.

In the case where the light emitting layer contains the third organic compound, the concentrations of the first organic compound, the second organic compound, and the third organic compound in the light emitting layer preferably satisfy the relationship of the following expression.

Conc(1)>Conc(2)>Conc(3)

Conc(1) represents the concentration of the first organic compound in the light emitting layer, Conc(2) represents the concentration of the second organic compound in the light emitting layer, and Conc(3) represents the concentration of the third organic compound in the light emitting layer. The unit used herein is percentage by weight.

In the organic light emitting device of the present invention, Conc(1) is preferably 30% by weight or more, may be in a range of 50% by weight or more, or may be in a range of 65% by weight or more, and may be in a range of 99% by weight or less, may be in a range of 85% by weight or less, or may be in a range of 75% by weight or less.

In the organic light emitting device of the present invention, Conc(2) is preferably 5% by weight or more, may be in a range of 20% by weight or more, or may be in a range of 30% by weight or more, and may be in a range of 50% by weight or less, may be in a range of 40% by weight or less, or may be in a range of 35% by weight or less.

In the organic light emitting device of the present invention, Conc(3) is preferably 5% by weight or less, and more preferably 3% by weight or less. Conc(3) may be in a range of 1% by weight or less, or may be in a range of 0.5% by weight or less, and may be in a range of 0.01% by weight or more, may be in a range of 0.1% by weight or more, or may be in a range of 0.3% by weight or more. The following condition (d) is preferably satisfied.

Conc(2)/Conc(3)>5 Condition (d)

Conc(2)/Conc(3) may be in a range of 10 or more, may be in a range of 30 or more, or may be in a range of 50 or more, and may be in a range of 500 or less, may be in a range of 300 or less, or may be in a range of 100 or less.

### (First Organic Compound)

The first organic compound used in the light emitting layer of the organic light emitting device of the present invention is selected from compounds that have lowest excited singlet energy that is larger than the second organic compound. In the case where the light emitting layer contains the third organic compound, the first organic compound is selected from compounds that have lowest excited singlet energy that is larger than the second organic compound and the third organic compound. The first organic compound preferably has a function of a host material assuming transportation of a carrier. The first organic compound preferably has a function confining the energy of a compound that mainly emits light in the light emitting layer. According to the configuration, the compound emitting light can convert the energy generated through recombination of a hole and an electron within the molecule and the energy received from the first organic compound to light emission with high efficiency.

The first organic compound is preferably an organic compound that has a hole transporting function and an electron transporting function, prevents the light emission from becoming a longer wavelength, and has a high glass transition temperature. In one preferred embodiment of the present invention, the first organic compound is selected from a compound that does not emit delayed fluorescent light. The light emission from the first organic compound is preferably less than 1%, and more preferably less than 0.1%, for example, may be less than 0.01%, of the light emission from the organic light emitting device of the present invention, and may be the detection limit or less.

The first organic compound preferably contains no metal atom. For example, a compound consisting of atoms selected from the group consisting of a carbon atom, a hydrogen atom, a nitrogen atom, an oxygen atom, and a sulfur atom may be selected as the first organic compound. For example, a compound consisting of atoms selected from the group consisting of a carbon atom, a hydrogen atom, a nitrogen atom, and an oxygen atom may be selected as the first organic compound. For example, a compound consisting of atoms selected from the group consisting of a carbon atom, a hydrogen atom, and a nitrogen atom may be selected as the first organic compound.

A compound including a carbazole structure can be preferably selected as the first organic compound. A compound including a dibenzofuran structure can be preferably selected as the first organic compound. A compound including a dibenzothiophene structure can be preferably selected as the first organic compound. In one preferred embodiment of the present invention, a compound including two or more selected from the group consisting of a carbazole structure, a dibenzofuran structure, and a dibenzothiophene structure, can be selected as the first organic compound, for example, a compound having two of these structures, or a compound having three of these structures can also be selected. In one preferred embodiment of the present invention, a compound including a 1,3-phenylene structure can be selected as the first organic compound. In one preferred embodiment of the present invention, a compound including a biphenylene structure can be selected as the first organic compound. In one preferred embodiment of the present invention, a compound having 5 to 8 benzene rings included in the molecule thereof can be selected as the first organic compound, for example, a compound having 5 benzene rings, a compound having 6 benzene rings, or a compound having 7 benzene rings can also be selected.

The first organic compound may be a compound represented by the general formula (1) or a compound that is not represented by the general formula (1). The use of a compound represented by the general formula (1) as the first organic compound can further enhance the orientation of the light emitting material in the light emitting layer. In one embodiment of the present invention, the first organic compound and the compound contained in the base layer have the same structure. In one embodiment of the present invention, the first organic compound is a compound represented by the general formula (1) having a structure that is different from the compound contained in the base layer. In this case, the molecular weight of the first organic compound may be smaller than the compound represented by the general formula (1) contained in the base layer, for example, by 50 or more. In alternative, in one embodiment of the present invention, the number of a dibenzofuran structure included in the first organic compound is larger than the compound represented by the general formula contained in the base layer. In alternative, in one embodiment of the present invention, the number of a carbazole structure included in the first organic compound is larger than the compound represented by the general formula contained in the base layer.

Preferred compounds that can be used as the first organic compound are shown below.

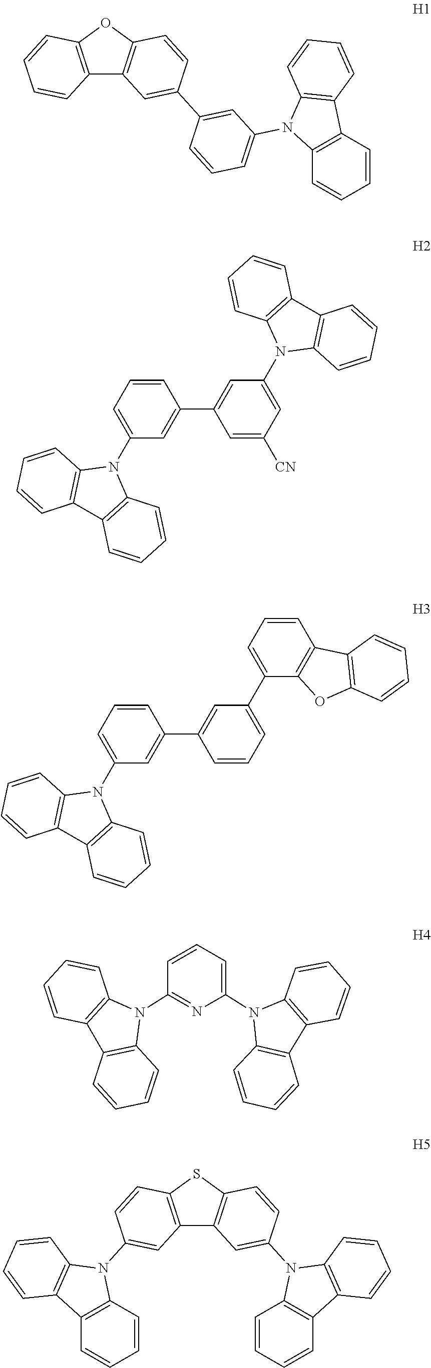 [SMILES: c1cc(-c2ccc3oc4ccccc4c3c2)cc(-n2c3ccccc3c3ccccc32)c1 ; N#Cc1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-c2cccc3c2oc2ccccc23)c1 ; c1cc(-n2c3ccccc3c3ccccc32)nc(-n2c3ccccc3c3ccccc32)c1 ; c1ccc2c(c1)c1ccccc1n2-c1ccc2sc3ccc(-n4c5ccccc5c5ccccc54)cc3c2c1]

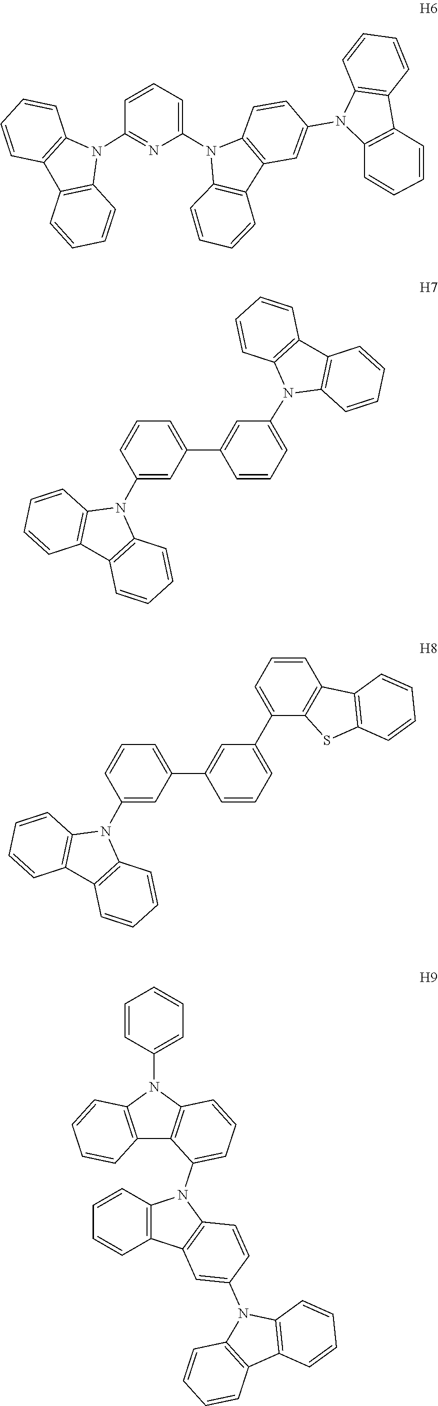 [SMILES: c1cc(-n2c3ccccc3c3ccccc32)nc(-n2c3ccccc3c3cc(-n4c5ccccc5c5ccccc54)ccc32)c1 ; c1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-c2cccc3c2sc2ccccc23)c1 ; c1ccc(-n2c3ccccc3c3c(-n4c5ccccc5c5cc(-n6c7ccccc7c7ccccc76)ccc54)cccc32)cc1]

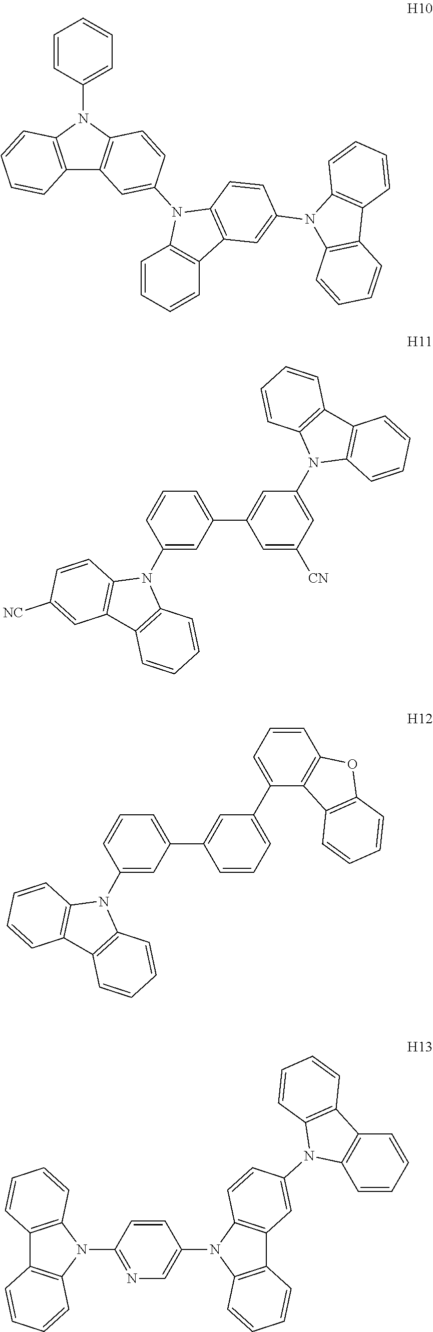 [SMILES: c1ccc(-n2c3ccccc3c3cc(-n4c5ccccc5c5cc(-n6c7ccccc7c7ccccc76)ccc54)ccc32)cc1 ; N#Cc1cc(-c2cccc(-n3c4ccccc4c4cc(C#N)ccc43)c2)cc(-n2c3ccccc3c3ccccc32)c1 ; c1cc(-c2cccc(-n3c4ccccc4c4ccccc43)c2)cc(-c2cccc3oc4ccccc4c23)c1 ; c1ccc2c(c1)c1ccccc1n2-c1ccc2c(c1)c1ccccc1n2-c1ccc(-n2c3ccccc3c3ccccc32)nc1]

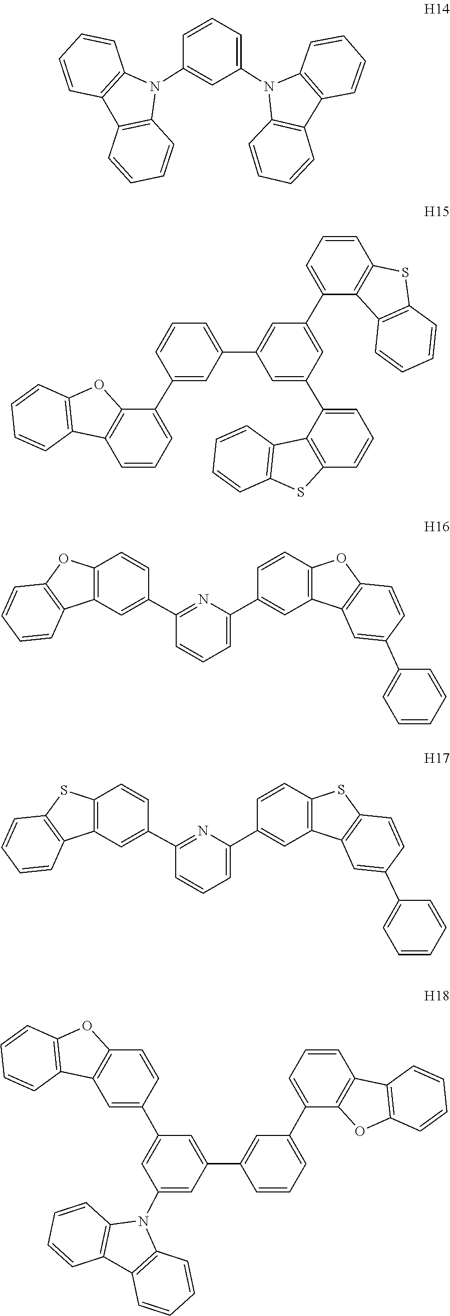 [SMILES: c1cc(-n2c3ccccc3c3ccccc32)cc(-n2c3ccccc3c3ccccc32)c1 ; c1cc(-c2cc(-c3cccc4sc5ccccc5c34)cc(-c3cccc4sc5ccccc5c34)c2)cc(-c2cccc3c2oc2ccccc23)c1 ; c1ccc(-c2ccc3oc4ccc(-c5cccc(-c6ccc7oc8ccccc8c7c6)n5)cc4c3c2)cc1 ; c1ccc(-c2ccc3sc4ccc(-c5cccc(-c6ccc7sc8ccccc8c7c6)n5)cc4c3c2)cc1 ; c1cc(-c2cc(-c3ccc4oc5ccccc5c4c3)cc(-n3c4ccccc4c4ccccc43)c2)cc(-c2cccc3c2oc2ccccc23)c1]

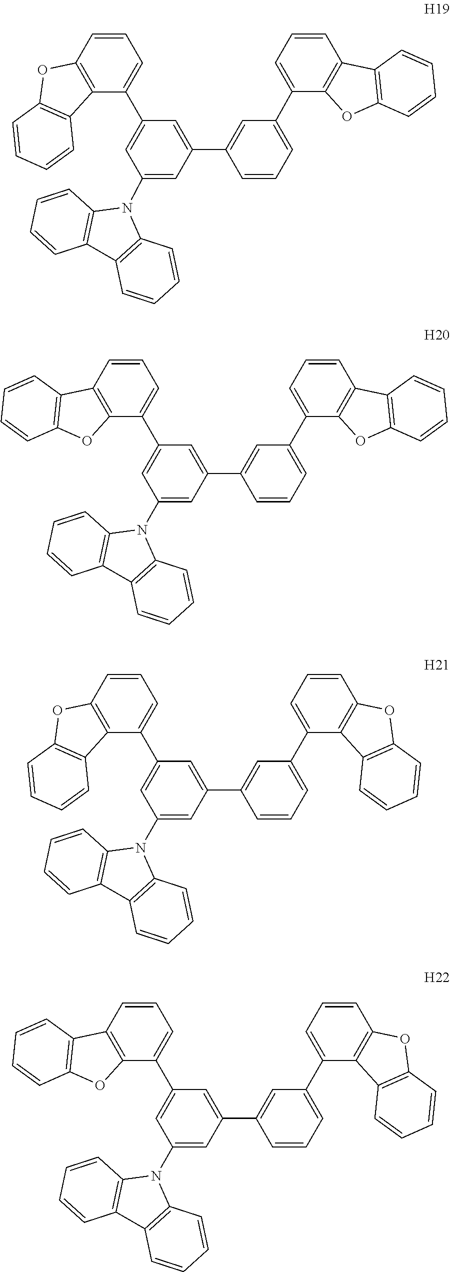 [SMILES: c1cc(-c2cc(-c3cccc4oc5ccccc5c34)cc(-n3c4ccccc4c4ccccc43)c2)cc(-c2cccc3c2oc2ccccc23)c1 ; c1cc(-c2cc(-c3cccc4c3oc3ccccc34)cc(-n3c4ccccc4c4ccccc43)c2)cc(-c2cccc3c2oc2ccccc23)c1 ; c1cc(-c2cc(-c3cccc4oc5ccccc5c34)cc(-n3c4ccccc4c4ccccc43)c2)cc(-c2cccc3oc4ccccc4c23)c1 ; c1cc(-c2cc(-c3cccc4c3oc3ccccc34)cc(-n3c4ccccc4c4ccccc43)c2)cc(-c2cccc3oc4ccccc4c23)c1]

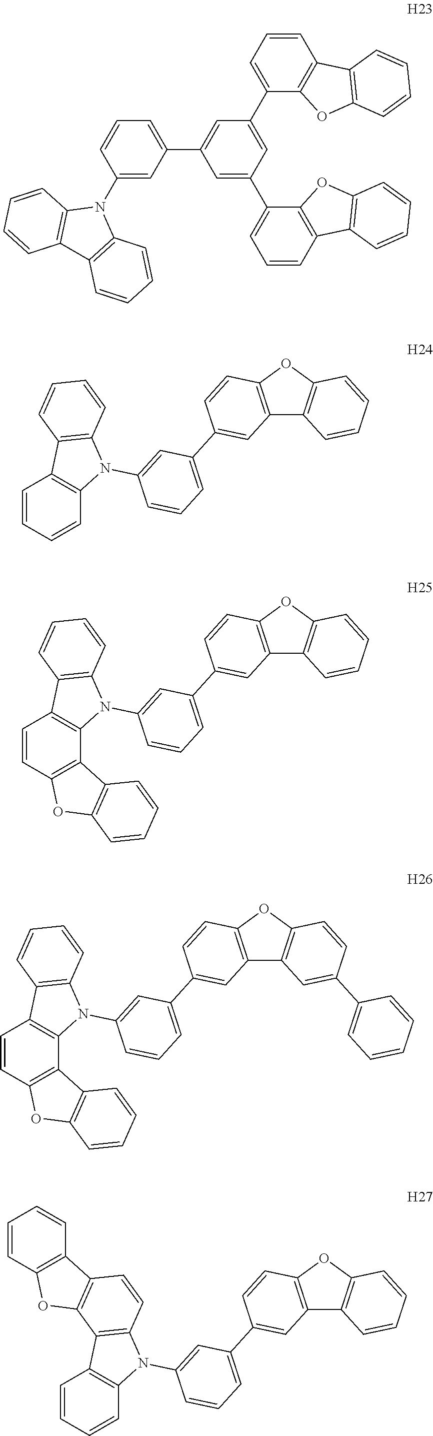 [SMILES: c1cc(-c2cc(-c3cccc4c3oc3ccccc34)cc(-c3cccc4c3oc3ccccc34)c2)cc(-n2c3ccccc3c3ccccc32)c1 ; c1cc(-c2ccc3oc4ccccc4c3c2)cc(-n2c3ccccc3c3ccccc32)c1 ; c1cc(-c2ccc3oc4ccccc4c3c2)cc(-n2c3ccccc3c3ccc4oc5ccccc5c4c32)c1 ; c1ccc(-c2ccc3oc4ccc(-c5cccc(-n6c7ccccc7c7ccc8oc9ccccc9c8c76)c5)cc4c3c2)cc1 ; c1cc(-c2ccc3oc4ccccc4c3c2)cc(-n2c3ccccc3c3c4oc5ccccc5c4ccc32)c1]

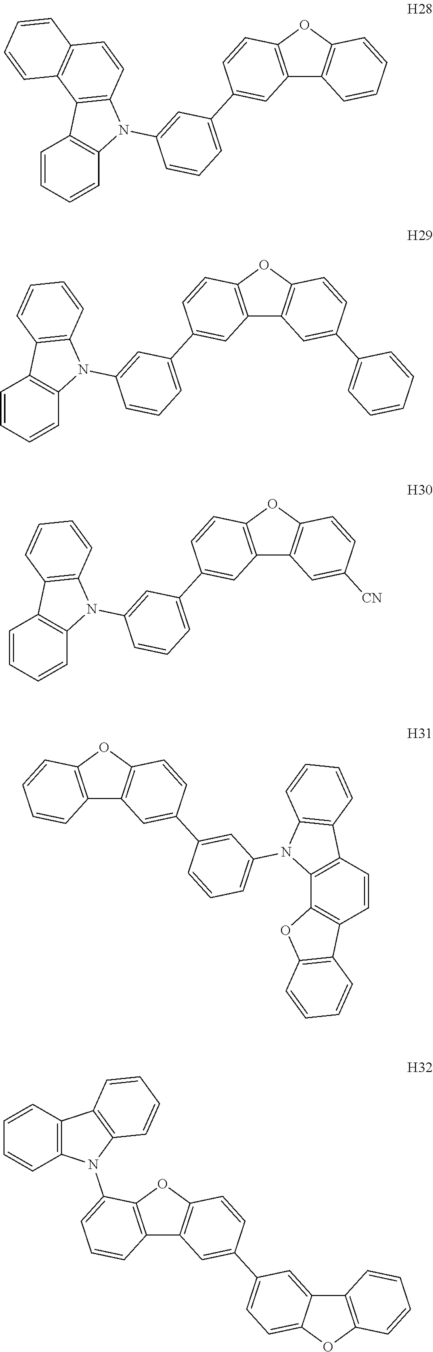 [SMILES: c1cc(-c2ccc3oc4ccccc4c3c2)cc(-n2c3ccccc3c3c4ccccc4ccc32)c1 ; c1ccc(-c2ccc3oc4ccc(-c5cccc(-n6c7ccccc7c7ccccc76)c5)cc4c3c2)cc1 ; N#Cc1ccc2oc3ccc(-c4cccc(-n5c6ccccc6c6ccccc65)c4)cc3c2c1 ; c1cc(-c2ccc3oc4ccccc4c3c2)cc(-n2c3ccccc3c3ccc4c5ccccc5oc4c32)c1 ; c1ccc2c(c1)oc1ccc(-c3ccc4oc5c(-n6c7ccccc7c7ccccc76)cccc5c4c3)cc12]

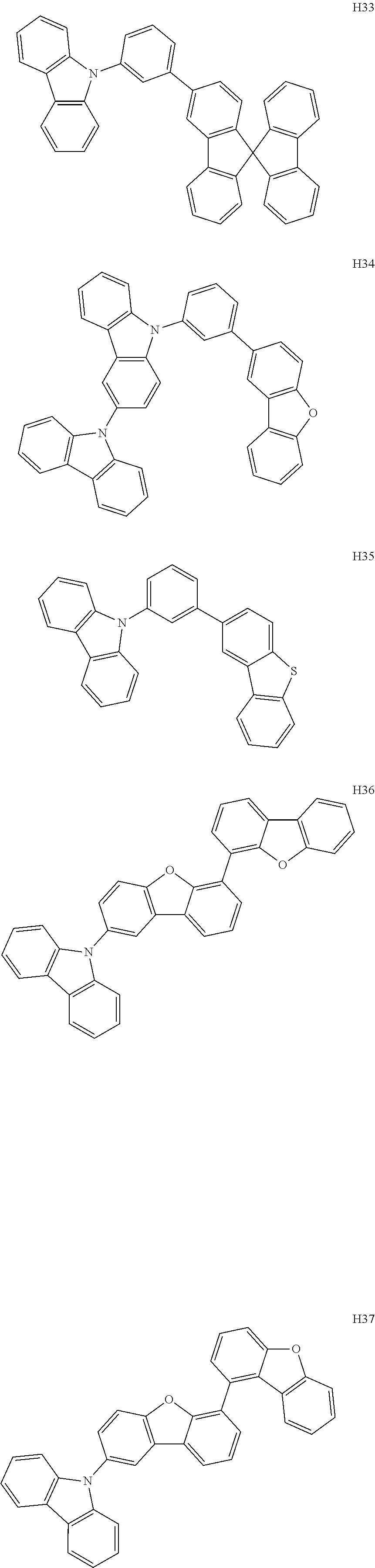 [SMILES: c1cc(-c2ccc3c(c2)-c2ccccc2C32c3ccccc3-c3ccccc32)cc(-n2c3ccccc3c3ccccc32)c1 ; c1cc(-c2ccc3oc4ccccc4c3c2)cc(-n2c3ccccc3c3cc(-n4c5ccccc5c5ccccc54)ccc32)c1 ; c1cc(-c2ccc3sc4ccccc4c3c2)cc(-n2c3ccccc3c3ccccc32)c1 ; c1ccc2c(c1)oc1c(-c3cccc4c3oc3ccc(-n5c6ccccc6c6ccccc65)cc34)cccc12 ; c1ccc2c(c1)oc1cccc(-c3cccc4c3oc3ccc(-n5c6ccccc6c6ccccc65)cc34)c12]

### (Second Organic Compound)

The second organic compound used in the light emitting layer of the organic light emitting device of the present invention is a delayed fluorescent material that has lowest excited singlet energy that is smaller than the first organic compound. In the case where the light emitting layer contains the third organic compound, the second organic compound is a delayed fluorescent material that has lowest excited singlet energy that is larger than the third organic compound. The “delayed fluorescent material” in the present invention is an organic compound that causes reverse intersystem crossing from the excited triplet state to the excited singlet state in the excited state, and emits fluorescent light (delayed fluorescent light) in returning the excited singlet state to the ground state. In the present invention, a compound emitting fluorescent light having a light emission lifetime of 100 ns (nanosecond) or more observed when measured by a fluorescent lifetime measurement system (such as a streak camera system available from Hamamatsu Photonics K.K.) is referred to as the delayed fluorescent material. The second organic compound is a material capable of emitting delayed fluorescent light, but it is not essential to emit delayed fluorescent light derived from the second organic compound used in the organic light emitting device of the present invention. The light emission from the second organic compound is preferably less than 10%, for example, may be less than 1%, may be less than 0.1%, or may be less than 0.01%, of the light emission from the organic light emitting device of the present invention, and may be the detection limit or less.

In the organic light emitting device of the present invention, the second organic compound transitions to the excited singlet state through reception of energy from the first organic compound in the excited singlet state. The second organic compound may transition to the excited triplet state through reception of energy from the first organic compound in the excited triplet state. The second organic compound has a small difference (ΔE_{ST}) between the excited singlet energy and the excited triplet energy, and therefore the second organic compound in the excited triplet state is likely to cause reverse intersystem crossing to the second organic compound in the excited singlet state. The second organic compound in the excited singlet state formed via these routes emits fluorescent light in returning to the ground state. In the case where the third organic compound exists in the light emitting layer, the second organic compound in the excited singlet state donates energy to the third organic compound, so as to allow the third organic compound to transition to the excited singlet state.

The second organic compound preferably has a difference ΔE_{ST} between the lowest excited singlet energy and the lowest excited triplet energy at 77 K of 0.3 eV or less, more preferably 0.25 eV or less, further preferably 0.2 eV or less, still further preferably 0.15 eV or less, still more further preferably 0.1 eV or less, even further preferably 0.07 eV or less, even still further preferably 0.05 eV or less, even still more further preferably 0.03 eV or less, and particularly preferably 0.01 eV or less.

With smaller ΔE_{ST}, the reverse intersystem crossing is likely to occur from the excited singlet state to the excited triplet state through reception of heat energy, and therefore the second organic compound functions as a heat activation type delayed fluorescent material. The heat activation type delayed fluorescent material relatively easily causes reverse intersystem crossing from the excited triplet state to the excited singlet state through reception of heat generated by the device, and can allow the excited triplet energy to contribute to the light emission efficiently.

In the present invention, the lowest excited singlet energy (E_{S1}) and the lowest excited triplet energy (E_{T1}) of the compound are values that are obtained in the following procedure. ΔE_{ST} is a value that is obtained by calculating E_{S1}−E_{T1}.

### (1) Lowest Excited Singlet Energy (E_{S1})

A thin film or a toluene solution (concentration: 10⁻⁵ mol/L) of the target compound to be measured is prepared and designated as a specimen. The specimen was measured for the fluorescent spectrum at ordinary temperature (300 K). The fluorescent spectrum has an ordinate as the light emission and an abscissa as the wavelength. A tangent line is drawn to the rise on the short wavelength side of the light emission spectrum, and the wavelength value λ_{edge} (nm) at the intersection point of the tangent line and the abscissa is obtained. The wavelength value is converted to the energy value according to the following conversion expression, and is designated as E_{S1}.

$$Conversion expression : {E}_{S 1} ( eV ) = 1239 \text{.85} / {λ}_{edge}$$

The measurement of the light emission spectrum in the examples described later is performed by using an LED light source (M300L4, available from Thorlabs, Inc.) as the excitation light source and a detector (PMA-12 Multichannel Spectroscope C10027-01, available from Hamamatsu Photonics K.K.).

### (2) Lowest Excited Triplet Energy (E_{T1})

The same specimen as used in the measurement of the lowest excited singlet energy (E_{S1}) is cooled to 77 (K) with liquid nitrogen, the specimen for measuring phosphorescent light is irradiated with excitation light (300 nm), and the phosphorescent light is measured with a detector. The light emission after 100 ms or later from the irradiation of excitation light is designated as a phosphorescent light spectrum. A tangent line is drawn to the rise on the short wavelength side of the phosphorescent light spectrum, and the wavelength value λ_{edge} (nm) at the intersection point of the tangent line and the abscissa is obtained. The wavelength value is converted to the energy value according to the following conversion expression, and is designated as E_{T1}.

$$Conversion expression : {E}_{T 1} ( eV ) = 1239 \text{.85} / {λ}_{edge}$$

The tangent line to the rise on the short wavelength side of the phosphorescent light spectrum is drawn in the following manner. In moving on the spectrum curve to the maximum value on the shortest wavelength side among the maximum values of the spectrum from the short wavelength side of the phosphorescent light spectrum, tangent lines to points on the curve are considered toward the long wavelength side. The tangent lines increase the gradient as the curve rises (i.e., as the ordinate increases). The tangent line that is drawn on the point where the gradient value becomes maximum is designated as the tangent line to the rise on the short wavelength side of the phosphorescent light spectrum.

A maximum value having a peak intensity of 10% or less of the maximum peak intensity of the spectrum is not included in the aforementioned maximum value on the shortest wavelength side, and the tangent line drawn on the point where the gradient value becomes maximum that is closest to the maximum value on the shortest wavelength side is designated as the tangent line to the rise on the short wavelength side of the phosphorescent light spectrum.

The second organic compound preferably contains no metal atom. For example, a compound consisting of atoms selected from the group consisting of a carbon atom, a hydrogen atom, a deuterium atom, a nitrogen atom, an oxygen atom, and a sulfur atom may be selected as the second organic compound. For example, a compound consisting of atoms selected from the group consisting of a carbon atom, a hydrogen atom, a deuterium atom, a nitrogen atom, and an oxygen atom may be selected as the second organic compound. For example, a compound consisting of atoms selected from the group consisting of a carbon atom, a hydrogen atom, a deuterium atom, and a nitrogen atom may be selected as the second organic compound. For example, a compound consisting of atoms selected from the group consisting of a carbon atom, a hydrogen atom, and a nitrogen atom may be selected as the second organic compound.

A compound including a carbazole structure may be preferably selected as the second organic compound. A compound including a dibenzofuran structure may be preferably selected as the second organic compound. A compound including a dibenzothiophene structure may be preferably selected as the second organic compound.

Typical examples of the second organic compound include a compound including a structure including a benzene ring having bonded thereto one or two acceptor groups and at least one donor group. Preferred examples of the acceptor group include a cyano group and a group containing a heteroaryl ring containing a nitrogen atom as a ring skeleton-forming atom, such as a triazinyl group. Preferred examples of the donor group include a substituted or unsubstituted carbazol-9-yl group. Examples of the compound include a compound including a benzene ring having bonded thereto 3 or more substituted or unsubstituted carbazol-9-yl groups, and a compound including a carbazol-9-yl group, at least one of the two benzene ring of which is condensed with a 5-membered ring of any of a substituted or unsubstituted benzofuran ring, a substituted or unsubstituted benzothiophene ring, a substituted or unsubstituted indole ring, a substituted or unsubstituted indene ring, and a substituted or unsubstituted silaindene ring.

In the description herein, the acceptor group is a group that attracts an electron from the ring to which the acceptor group is bonded, and for example, can be selected from groups having a positive Hammett's σₚ value. In the description herein, the donor group is a group that donates an electron from the ring to which the donor group is bonded, and for example, can be selected from groups having a negative Hammett's σₚ value.

The “Hammett's σₚ value” is one propounded by L. P. Hammett, and is one to quantify the influence of a substituent on the reaction rate or the equilibrium of a para-substituted benzene derivative. Specifically, the value is a constant (σₚ) peculiar to the substituent in the following equation that is established between a substituent and a reaction rate constant or an equilibrium constant in a para-substituted benzene derivative:

$$log ( k / {k}_{0} ) = p {σ}_{p}$$

$$or$$

$$log ( K / {K}_{0} ) = p {σ}_{p}$$

In the above equations, k represents a rate constant of a benzene derivative not having a substituent; k₀ represents a rate constant of a benzene derivative substituted with a substituent; K represents an equilibrium constant of a benzene derivative not having a substituent; K₀ represents an equilibrium constant of a benzene derivative substituted with a substituent; ρ represents a reaction constant to be determined by the kind and the condition of reaction. Regarding the description relating to the “Hammett's σₚ value” and the numerical value of each substituent, reference may be made to the description relating to σₚ value in Hansch, C. et. al., Chem. Rev., 91, 165-195 (1991).

Specific examples of the acceptor group include a cyano group, and also include the following groups, in which * represents the bonding position, and D represents a deuterium atom. In the following specific examples, a hydrogen atom may be substituted by an alkyl group. A substituted or unsubstituted benzene ring may be further condensed thereto. A part or the entire of hydrogen atoms may be replaced by a deuterium atom.

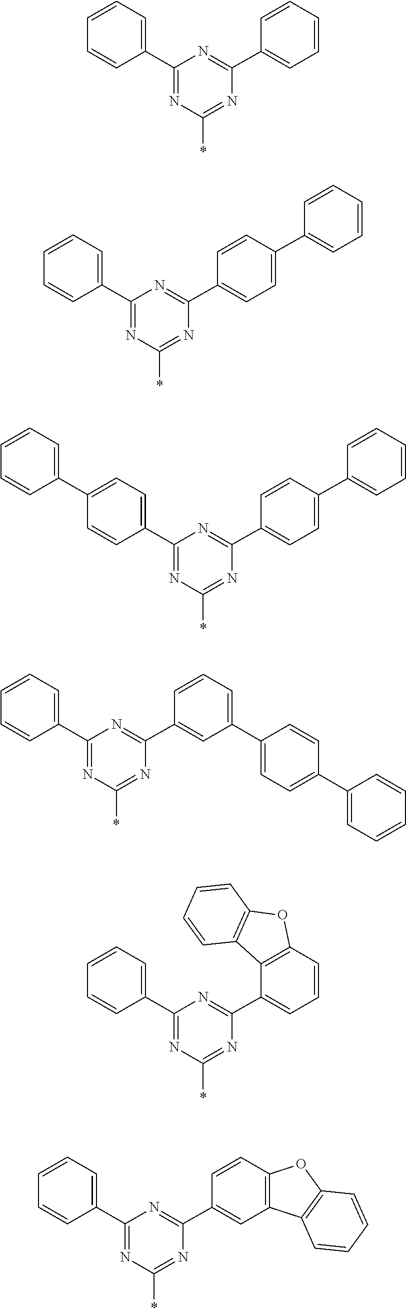

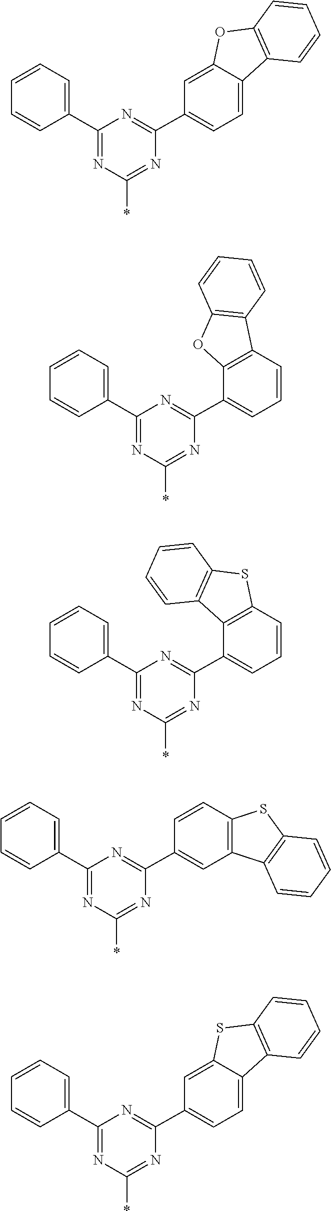 [SMILES: *c1nc(-c2ccccc2)nc(-c2ccc3c(c2)oc2ccccc23)n1 ; *c1nc(-c2ccccc2)nc(-c2cccc3c2oc2ccccc23)n1 ; *c1nc(-c2ccccc2)nc(-c2cccc3sc4ccccc4c23)n1 ; *c1nc(-c2ccccc2)nc(-c2ccc3sc4ccccc4c3c2)n1 ; *c1nc(-c2ccccc2)nc(-c2ccc3c(c2)sc2ccccc23)n1]

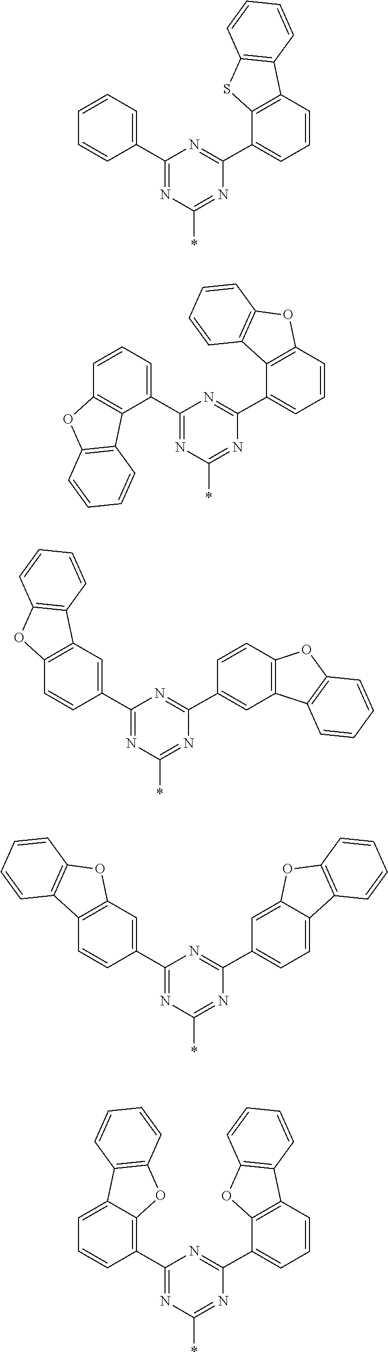

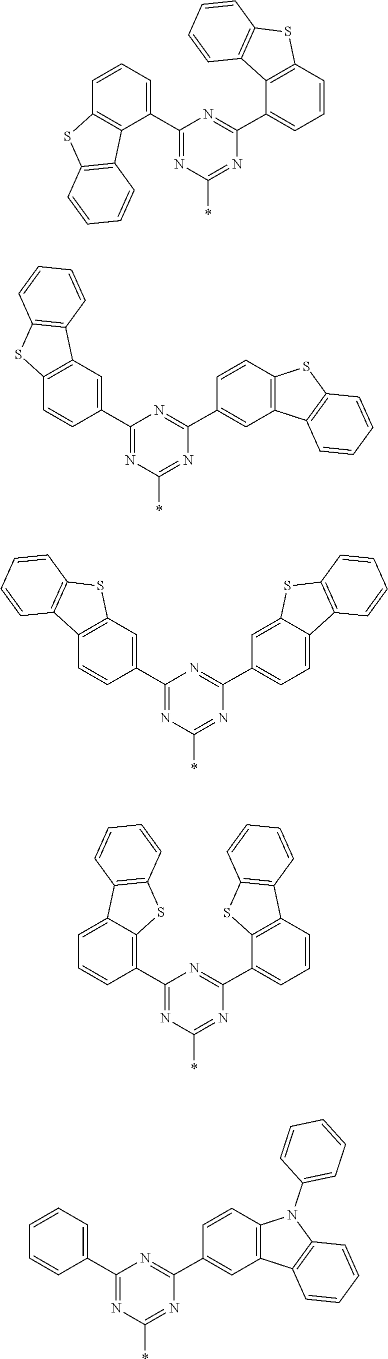 [SMILES: *c1nc(-c2cccc3sc4ccccc4c23)nc(-c2cccc3sc4ccccc4c23)n1 ; *c1nc(-c2ccc3sc4ccccc4c3c2)nc(-c2ccc3sc4ccccc4c3c2)n1 ; *c1nc(-c2ccc3c(c2)sc2ccccc23)nc(-c2ccc3c(c2)sc2ccccc23)n1 ; *c1nc(-c2cccc3c2sc2ccccc23)nc(-c2cccc3c2sc2ccccc23)n1 ; *c1nc(-c2ccccc2)nc(-c2ccc3c(c2)c2ccccc2n3-c2ccccc2)n1]

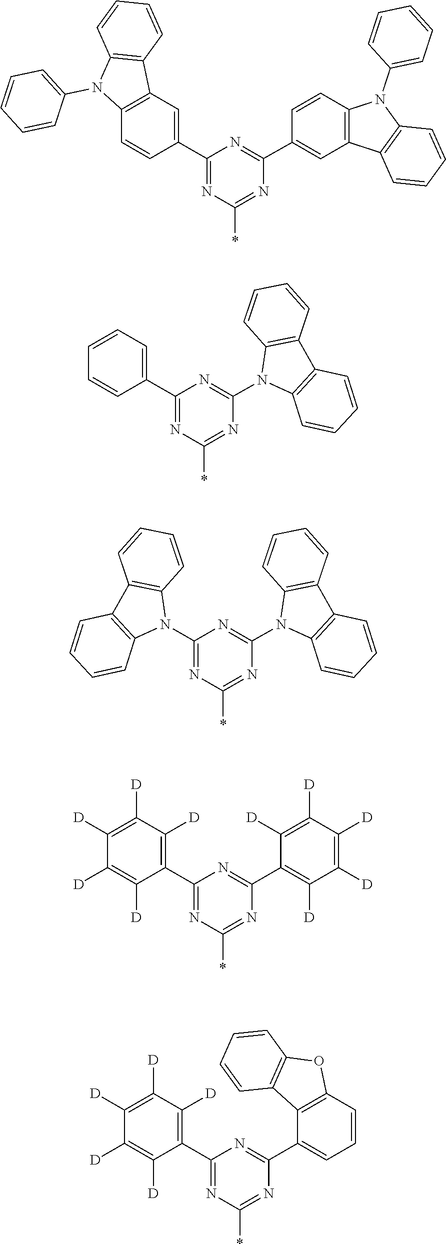 [SMILES: *c1nc(-c2ccc3c(c2)c2ccccc2n3-c2ccccc2)nc(-c2ccc3c(c2)c2ccccc2n3-c2ccccc2)n1 ; *c1nc(-c2ccccc2)nc(-n2c3ccccc3c3ccccc32)n1 ; *c1nc(-n2c3ccccc3c3ccccc32)nc(-n2c3ccccc3c3ccccc32)n1 ; *c1nc(-c2c([2H])c([2H])c([2H])c([2H])c2[2H])nc(-c2c([2H])c([2H])c([2H])c([2H])c2[2H])n1 ; *c1nc(-c2c([2H])c([2H])c([2H])c([2H])c2[2H])nc(-c2cccc3oc4ccccc4c23)n1]

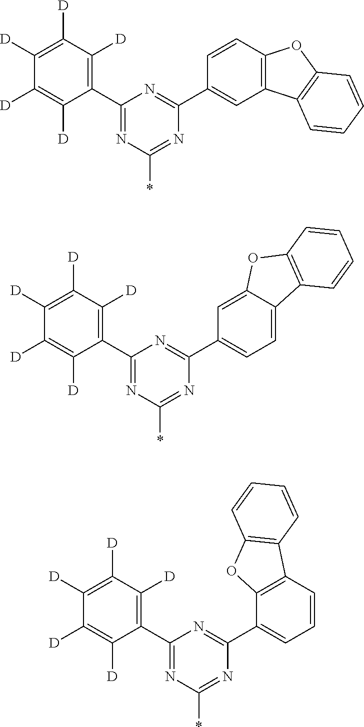 [SMILES: *c1nc(-c2ccc3oc4ccccc4c3c2)nc(-c2c([2H])c([2H])c([2H])c([2H])c2[2H])n1 ; *c1nc(-c2ccc3c(c2)oc2ccccc23)nc(-c2c([2H])c([2H])c([2H])c([2H])c2[2H])n1 ; *c1nc(-c2c([2H])c([2H])c([2H])c([2H])c2[2H])nc(-c2cccc3c2oc2ccccc23)n1]

Specific examples of the donor group include the following groups, in which * represents the bonding position, and D represents a deuterium atom. In the following specific examples, a hydrogen atom may be substituted by an alkyl group. A substituted or unsubstituted benzene ring may be further condensed thereto. A part or the entire of hydrogen atoms may be replaced by a deuterium atom.

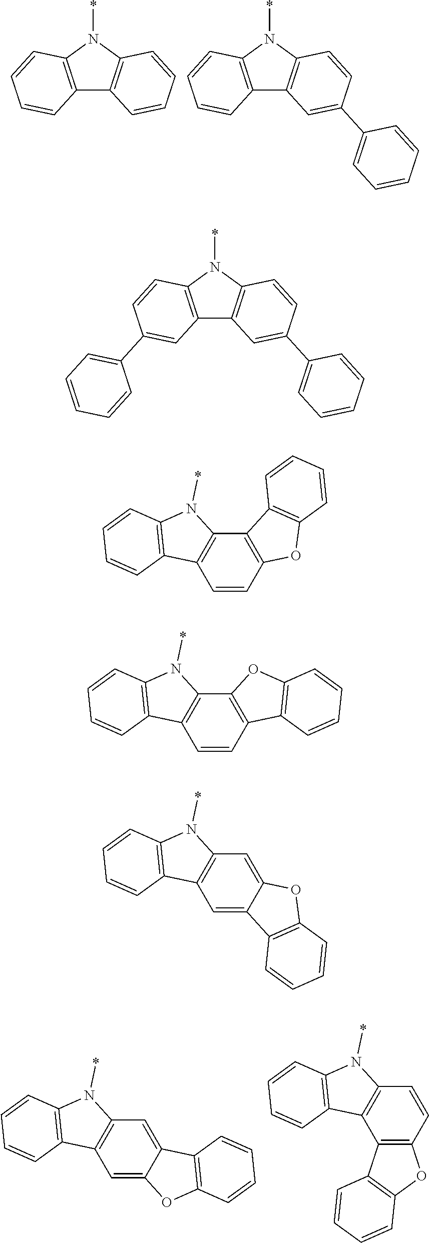

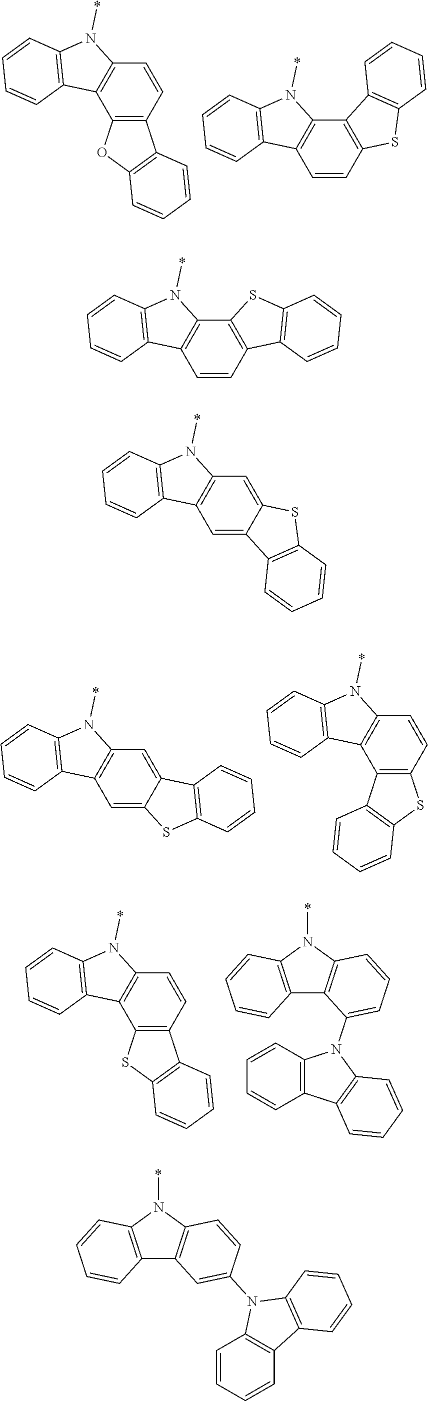

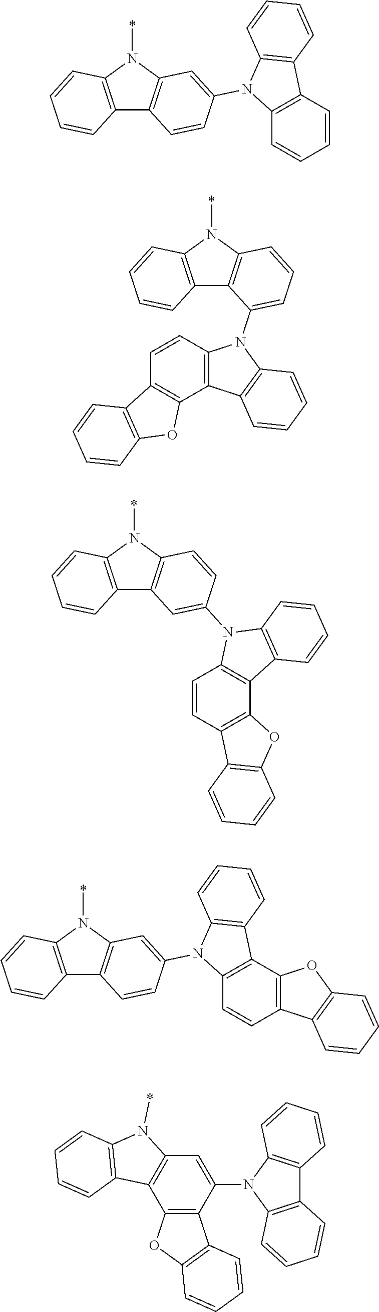

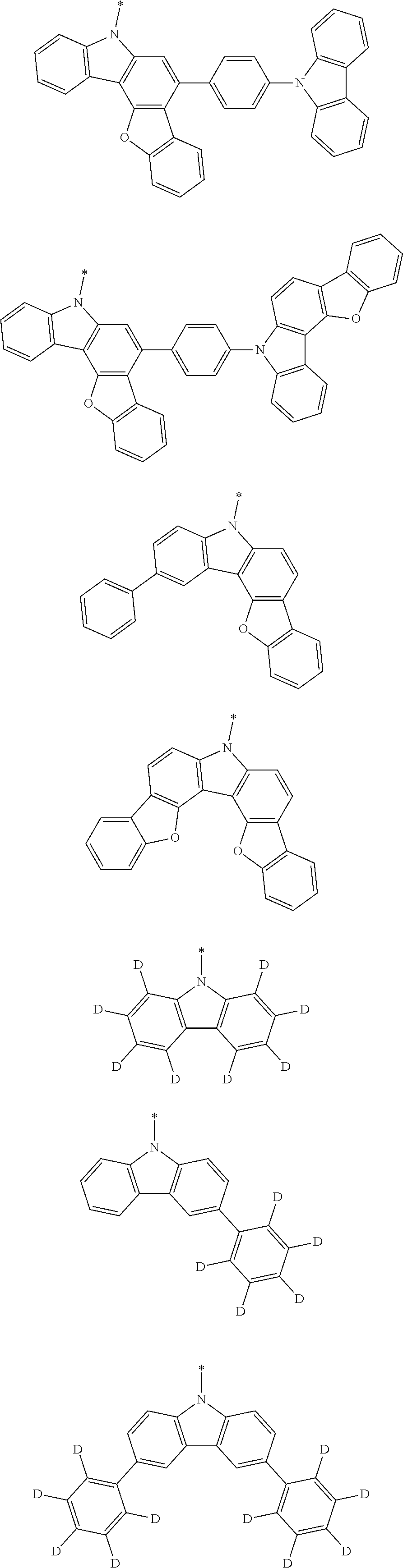

The second organic compound used is preferably a compound represented by the following general formula (4) emitting delayed fluorescent light.

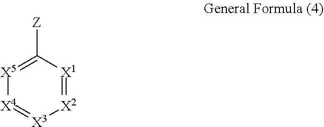

In the general formula (4), X¹ to X⁵ each represent N or C—R, in which R represents a hydrogen atom, a deuterium atom, or a substituent. In the case where two or more of X¹ to X⁵ represent C—R, the groups represented by C—R may be the same as or different from each other. At least one of X¹ to X⁵ represents C-D (wherein D represents a donor group). In the case where all X¹ to X⁵ represent C—R, Z represents an acceptor group.

The compound represented by the general formula (4) is particularly preferably a compound represented by the following general formula (5).

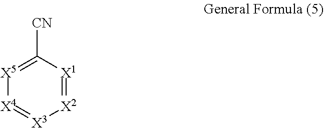

In the general formula (5), X¹ to X⁵ each represent N or C—R, in which R represents a hydrogen atom, a deuterium atom, or a substituent. In the case where two or more of X¹ to X⁵ represent C—R, the groups represented by C—R may be the same as or different from each other. At least one of X¹ to X⁵ represents C-D (wherein D represents a donor group).

In one preferred embodiment of the present invention, all X¹ to X⁵ do not represent C—CN, which accordingly provides a compound including a structure including a benzene ring having bonded thereto one cyano group and at least one donor group. In another preferred embodiment of the present invention, only X² represents C—CN, and X¹ and X³ to X⁵ do not represent C—CN, which accordingly provides a compound including a structure including a benzene ring of isophthalonitrile having bonded thereto at least one donor group. In still another embodiment of the present invention, only X³ represents C—CN, and X¹, X², X⁴, and X⁵ do not represent C—CN, which accordingly provides a compound including a structure including a benzene ring of terephthalonitrile having bonded thereto at least one donor group.

In the general formulae (4) and (5), X¹ to X⁵ each represent N or C—R, and at least one of which represents C-D. The number of N in X¹ to X⁵ is 0 to 4, and examples thereof include cases where X¹, X³, and X⁵ are N, X¹ and X³ are N, X¹ and X⁴ are N, X² and X³ are N, X¹ and X⁵ are N, X² and X⁴ are N, only X¹ is N, only X² is N, and only X³ is N. The number of C-D in X¹ to X⁵ is 1 to 5, and more preferably 2 to 5, and examples thereof include cases where X¹, X², X³, X⁴, and X⁵ are C-D, X¹, X², X⁴, and X⁵ are C-D, X¹, X², X³, and X⁴ are C-D, X¹, X³, X⁴, and X³ are C-D, X¹, X³, and X³ are C-D, X¹, X², and X⁵ are C-D, X¹, X², and X⁴ are C-D, X¹, X³, and X⁴ are C-D, X¹ and X³ are C-D, X¹ and X⁴ are C-D, X² and X³ are C-D, X¹ and X⁵ are C-D, X² and X⁴ are C-D, only X¹ is C-D, only X² is C-D, and only X³ is C-D. At least one of X¹ to X⁵ may be C-A, in which A represents an acceptor group. The number of C-A in X¹ to X⁵ is preferably 0 to 2, and more preferably 0 or 1. Preferred examples of A in C-A include a cyano group and a heterocyclic aromatic group having an unsaturated nitrogen atom. X¹ to X⁵ each independently may represent C-D or C-A.

In the case where adjacent two of X¹ to X⁵ represent C—R, two groups of R may be bonded to each other to form a cyclic structure. The cyclic structure formed by bonding to each other may be an aromatic ring or an aliphatic ring, and may contain a hetero atom, and the cyclic structure may also be a condensed ring of two or more rings. The hetero atom herein is preferably selected from the group consisting of a nitrogen atom, an oxygen atom, and a sulfur atom. Examples of the cyclic structure formed include a benzene ring, a naphthalene ring, a pyridine ring, a pyridazine ring, a pyrimidine ring, a pyrazine ring, a pyrrole ring, an imidazole ring, a pyrazole ring, an imidazoline ring, an oxazole ring, an isoxazole ring, a thiazole ring, an isothiazole ring, a cyclohexadiene ring, a cyclohexene ring, a cyclopentaene ring, a cycloheptatriene ring, a cycloheptadiene ring, a cycloheptaene ring, a furan ring, a thiophene ring, a naphthyridine ring, a quinoxaline ring, and a quinoline ring. For example, a ring including multiple rings condensed each other, such as a phenanthrene ring and a triphenylene ring, may also be formed.

The donor group D in the general formula (4) and the general formula (5) is preferably a group represented by, for example, the following general formula (6).

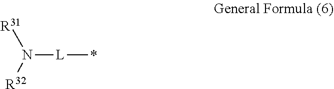

In the general formula (6), R³¹ and R³² each independently represent a substituted or unsubstituted alkyl group, a substituted or unsubstituted alkenyl group, a substituted or unsubstituted aryl group, or a substituted or unsubstituted heteroaryl group. R³¹ and R³² can bond to each other to form a cyclic structure. L represents a single bond, a substituted or unsubstituted arylene group, or a substituted or unsubstituted heteroarylene group. The substituent that can be introduced into the arylene group or the heteroarylene group of L can be a group including a structure represented by the general formula (4) or the general formula (5), or can be a group represented by the general formulae (7) to (9) to be mentioned hereinunder. These groups can be introduced in an amount up to the maximum number of the substituents capable of being introduced into L. In the case where plural groups are introduced, these substituents can be the same as or different from each other. * indicates the bonding position to the carbon atom (C) that constitutes the ring skeleton of the ring in the general formula (4) or the general formula (5).

The substituent means a monovalent group capable of substituting a hydrogen atom, and for example, can be selected from the substituent group A described later, can be selected from the substituent group B described later, can be selected from the substituent group C described later, and can be selected from the substituent group D described later.

The group represented by the general formula (6) is preferably a group represented by any of the following general formulae (7) to (9).

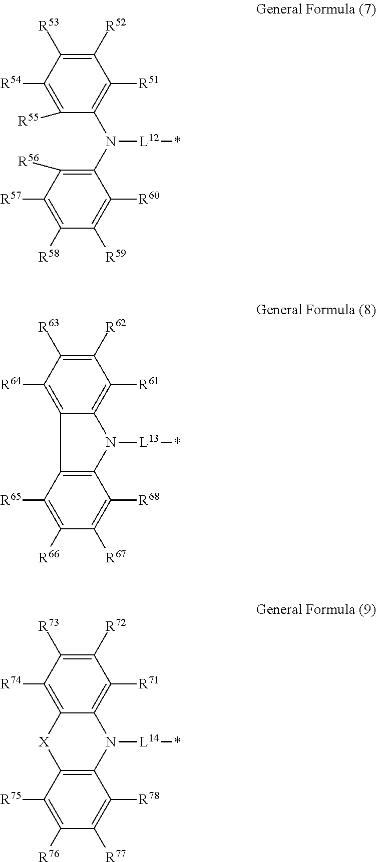

In the general formulae (7) to (9), R⁵¹ to R⁶⁰, R⁶¹ to R⁶⁸, and R⁷¹ to R⁷⁸ each independently represent a hydrogen atom, a deuterium atom, or a substituent. For the description and the preferred ranges of the substituent herein, reference may be made to the description and the preferred ranges for the substituent in the general formula (10) described later. R⁵¹ to R⁶⁰, R⁶¹ to R⁶⁸, and R⁷¹ to R⁷⁸ each independently preferably represent a group represented by any of the general formulae (7) to (9). The number of the substituent in the general formulae (7) to (9) is not limited. The case completely unsubstituted (i.e., all are hydrogen atoms or deuterium atoms) is also preferred. In the case where two or more substituents exist in the general formulae (7) to (9), the substituents may be the same as or different from each other. In the case where a substituent exists in the general formulae (7) to (9), the substituent is preferably any of R⁵² to R⁵⁹ for the general formula (7), any of R⁶² to R⁶⁷ for the general formula (8), and any of R⁷² to R⁷⁷ for the general formula (9).

In the general formula (9), X represents an oxygen atom, a sulfur atom, a substituted or unsubstituted nitrogen atom, a substituted or unsubstituted carbon atom, a substituted or unsubstituted silicon atom or a carbonyl group that is divalent and has a linking chain length of one atom, or represents a substituted or unsubstituted ethylene group, a substituted or unsubstituted vinylene group, a substituted or unsubstituted o-arylene group or a substituted or unsubstituted o-heteroarylene group that is divalent and has a linking chain length of two atoms. For example, the substituent can be selected from the substituent group A described later, can be selected from the substituent group B described later, can be selected from the substituent group C described later, or can be selected from the substituent group D described later.

In the general formulae (7) to (9), L¹² to L¹⁴ each represent a single bond, a substituted or unsubstituted arylene group or a substituted or unsubstituted heteroarylene group. Regarding the description and the preferred range of the arylene group and the heteroarylene group that L¹² to L¹⁴ represent, reference can be made to the description and the preferred range of the arylene group and the heteroarylene group that L represents. L¹² to L¹⁴ each are preferably a single bond, or a substituted or unsubstituted arylene group. Here the substituent for the arylene group and the heteroarylene group can be the group represented by the general formulae (7) to (9). The group represented by the general formulae (7) to (9) can be introduced into L¹¹ to L¹⁴ in an amount up to the maximum number of the substituents that can be introduced thereinto. In the case where plural groups of the general formulae (7) to (9) are introduced, these substituents can be the same as or different from each other. * indicates the bonding position to the carbon atom (C) that constitutes the ring skeleton of the ring in the general formula (4) or the general formula (5).

In the general formulae (7) to (9), R⁵¹ and R⁵², R⁵² and R⁵³, R⁵³ and R⁵⁴, R⁵⁴ and R⁵⁵, R⁵⁵ and R⁵⁶, R⁵⁶ and R⁵⁷, R⁵⁷ and R⁵⁸, R⁵⁸ and R⁵⁹, R⁵⁹ and R⁶⁰, R⁶¹ and R⁶², R⁶² and R⁶³, R⁶³ and R⁶⁴, R⁶⁵ and R⁶⁶, R⁶⁶ and R⁶⁷, R⁶⁷ and R⁶⁸, R⁷¹ and R⁷², R⁷² and R⁷³, R⁷³ and R⁷⁴, R⁷⁵ and R⁷⁶, R⁷⁶ and R⁷⁷, and R⁷⁷ and R⁷⁸ each may be bonded to each other to form a cyclic structure. For the description and the preferred ranges of the cyclic structure, reference may be made to the description and the preferred ranges for the cyclic structure of X¹ to X⁵ in the general formulae (4) and (5).

Preferred examples of the cyclic structure include a structure including a substituted or unsubstituted benzofuran ring, a substituted or unsubstituted benzothiophene ring, a substituted or unsubstituted indole ring, a substituted or unsubstituted indene ring, or a substituted or unsubstituted silaindene ring that is condensed to at least one benzene rings of the general formulae (7) to (9). More preferred examples thereof include a group represented by any of the following general formulae (8a) to (8f) obtained by condensing to the general formula (8).

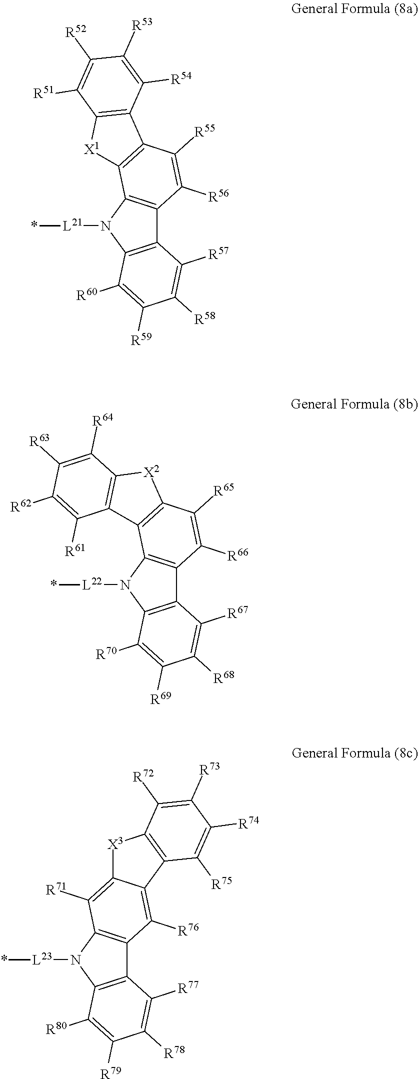

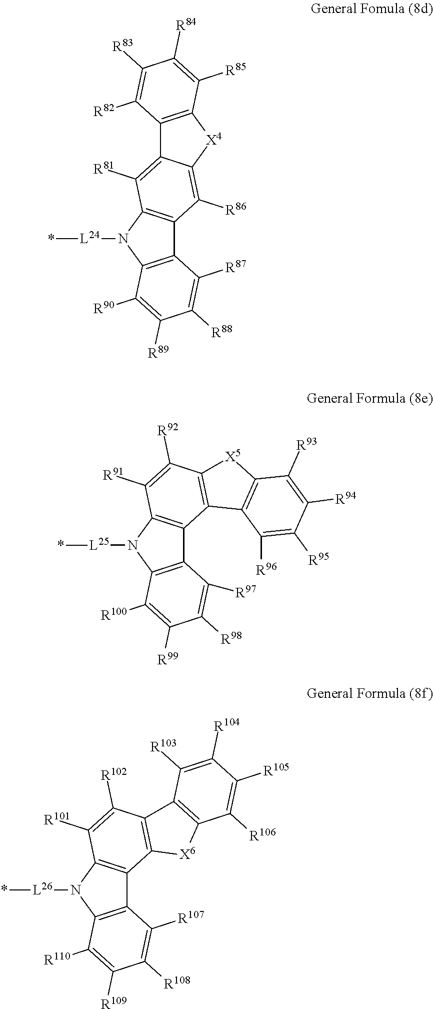

In the general formulae (8a) to (8f), L¹¹ and L²¹ to L²⁶ each represent a single bond or a divalent linking group. For the description and the preferred ranges of L¹¹ and L²¹ to L²⁶, reference may be made to the description and the preferred ranges for L² described above.

In the general formulae (8a) to (8f), R⁴¹ to R¹¹⁰ each independently represent a hydrogen atom or a substituent. R⁴¹ and R⁴², R⁴² and R⁴³, R⁴³ and R⁴⁴, R⁴⁴ and R⁴⁵, R⁴⁵ and R⁴⁶, R⁴⁶ and R⁴⁷, R⁴⁷ and R⁴⁸, R⁵¹ and R⁵², R⁵² and R⁵³, R⁵³ and R⁵⁴, R⁵⁴ and R³⁵, R⁵⁵ and R⁵⁶, R⁵⁶ and R³⁷, R⁵⁷ and R⁵⁸, R⁵⁸ and R⁵⁹, R⁵⁹ and R⁶⁰, R⁶¹ and R⁶², R⁶² and R⁶³, R⁶³ and R⁶⁴, R⁶⁵ and R⁶⁶, R⁶⁶ and R⁶⁷, R⁶⁷ and R⁶⁸, R⁶⁸ and R⁶⁹, R⁶⁹ and R⁷⁰, R⁷² and R⁷³, R⁷³ and R⁷⁴, R⁷⁴ and R⁷⁵, R⁷⁵ and R⁷⁶, R⁷⁶ and R⁷⁷, R⁷⁷ and R⁷⁸, R⁷⁸ and R⁷⁹, R⁷⁹ and R⁸⁰, R⁸¹ and R⁸², R⁸² and R⁸³, R⁸³ and R⁸⁴, R⁸⁴ and R⁸⁵, R⁸⁶ and R⁸⁷, R⁸⁷ and R⁸⁸, R⁸⁸ and R⁸⁹, R⁸⁹ and R⁹⁰, R⁹¹ and R⁹², R⁹³ and R⁹⁴, R⁹⁴ and R⁹⁵, R⁹⁵ and R⁹⁶, R⁹⁶ and R⁹⁷, R⁹⁷ and R⁹⁸, R⁹⁹ and R¹⁰⁰, R¹⁰¹ and R¹⁰², R¹⁰² and R¹⁰³, R¹⁰³ and R¹⁰⁴, R¹⁰⁴ and R¹⁰⁵, R¹⁰⁵ and R¹⁰⁶, R¹⁰⁷ and R¹⁰⁸, R¹⁰⁸ and R¹⁰⁹, and R¹⁰⁹ and R¹¹⁰ each may be bonded to each other to form a cyclic structure. The cyclic structure formed by bonding to each other may be an aromatic ring or an aliphatic ring, and may contain a hetero atom, and the cyclic structure may also be a condensed ring of two or more rings. The hetero atom herein is preferably selected from the group consisting of a nitrogen atom, an oxygen atom, and a sulfur atom. Examples of the cyclic structure formed include a benzene ring, a naphthalene ring, a pyridine ring, a pyridazine ring, a pyrimidine ring, a pyrazine ring, a pyrrole ring, an imidazole ring, a pyrazole ring, an imidazoline ring, an oxazole ring, an isoxazole ring, a thiazole ring, an isothiazole ring, a cyclohexadiene ring, a cyclohexene ring, a cyclopentaene ring, a cycloheptatriene ring, a cycloheptadiene ring, a cycloheptaene ring, a furan ring, a thiophene ring, a naphthyridine ring, a quinoxaline ring, and a quinoline ring. For example, a ring including multiple rings condensed each other, such as a phenanthrene ring and a triphenylene ring, may also be formed. The number of rings contained in the group represented by the general formula (9) may be selected from a range of 3 to 5, and may be selected from a range of 5 to 7. The number of rings contained in the group represented by the general formulae (8a) to (8f) may be selected from a range of 5 to 7, and may be 5.

The substituent that R⁴¹ to R¹¹⁰ each can represent can be selected from the groups of the substituent group B described later, can be selected from the groups of the substituent group C described later, and can be selected from the groups of the substituent group D described later. The substituent is preferably an unsubstituted alkyl group having 1 to 10 carbon atoms, and an aryl group having 6 to 10 carbon atoms, which may be substituted by an unsubstituted alkyl group having 1 to 10 carbon atoms. In one preferred embodiment of the present invention, R⁴¹ to R¹¹⁰ each represent a hydrogen atom or an unsubstituted alkyl group having 1 to 10 carbon atoms. In one preferred embodiment of the present invention, R⁴¹ to R¹¹⁰ each represent a hydrogen atom or an unsubstituted aryl group having 6 to 10 carbon atoms. In one preferred embodiment of the present invention, all R⁴¹ to R¹¹⁰ represent hydrogen atoms.

In the general formulae (8a) to (8f), the carbon atoms, to which R⁴¹ to R¹¹⁰ are bonded, (i.e., ring skeleton-forming carbon atoms) each independently may be replaced by a nitrogen atom. Accordingly, in the general formulae (8a) to (8f), C—R⁴¹ to C—R¹¹⁰ each independently may be replaced by N. The number of a carbon atom that is replaced by a nitrogen atom is preferably 0 to 4, and more preferably 1 to 2, in the group represented by the general formulae (8a) to (8f). In one embodiment of the present invention, the number of a carbon atom that is replaced by a nitrogen atom is 0. In the case where 2 or more carbon atoms are replaced by nitrogen atoms, the number of a nitrogen atom that is substituted in one ring is preferably 1.

In the general formulae (8a) to (8f), X¹ to X⁶ each represent an oxygen atom, a sulfur atom, or N—R. In one embodiment of the present invention, X¹ to X⁶ represent oxygen atoms. In one embodiment of the present invention, X¹ to X⁶ represent sulfur atoms. In one embodiment of the present invention, X¹ to X⁶ represent N—R. R represents a hydrogen atom or a substituent, and preferably represents a substituent. The substituent can be selected from the groups of the substituent group A described later, can be selected from the groups of the substituent group B described later, can be selected from the groups of the substituent group C described later, or can be selected from the groups of the substituent group D described later. Preferred examples thereof used include an unsubstituted phenyl group and a phenyl group substituted by one group selected from an alkyl group and an aryl group, or a group combining two or more thereof.

In the general formulae (8a) to (8f), * indicates the bonding position.

In the present invention, a compound represented by the following general formula (10) emitting delayed fluorescent light is particularly preferably used as the delayed fluorescent material. In a preferred embodiment of the present invention, a compound represented by the general formula (10) may be used as the second organic compound.

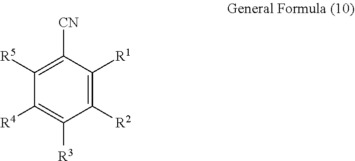

In the general formula (10), 0 to 4 of R¹ to R⁵ represent a cyano group, at least one of R¹ to R⁵ represent a substituted amino group, and the rest of R¹ to R⁵ represent a hydrogen atom, a deuterium atom, or a substituent other than a cyano group and a substituted amino group.

The substituted amino group herein is preferably a substituted or unsubstituted diarylamino group, in which two aryl groups constituting the substituted or unsubstituted diarylamino group may be bonded to each other. The aryl groups may be bonded via a single bond (resulting in a carbazole ring in this case), or may be bonded via a linking group, such as —O—, —S—, —N(R⁶)—, —C(R⁷)(R⁸)—, and Si(R⁹)(R¹⁰)—, wherein R⁶ to R¹⁰ each represent a hydrogen atom, a deuterium atom, or a substituent, and R⁷ and R⁸, and R⁹ and R¹⁰ each may be bonded to each other to form a cyclic structure.

The substituted amino group may be any of R¹ to R⁵, and for example, R¹ and R²; R¹ and R³; R¹ and R⁴; R¹ and R⁵; R² and R³; R² and R⁴; R¹ and R² and R³; R¹, R², and R⁴; R¹, R², and R⁵; R¹, R³, and R⁴; R¹, R³, and R⁵; R², R³, and R⁴; R¹, R², R³, and R⁴; R¹, R², R³, and R⁵; R¹, R², R⁴, and R⁵; or R¹, R², R³, R⁴, and R⁵ may be a substituted amino group. The cyano group may also be any of R¹ to R⁵, and for example, R¹; R²; R³; R¹ and R²; R¹ and R³; R¹ and R⁴, R¹ and R⁵; R² and R³, R² and R⁴; R¹, R², and R³; R¹, R², and R⁴; R¹, R², and R⁵; R¹, R³, and R⁴; R¹, R³, and R⁵; or R², R³, and R⁴ may be a cyano group.

R¹ to R⁵ that are not a cyano group and a substituted amino group represent a hydrogen atom, a deuterium atom, or a substituent. Examples of the substituent herein include the substituent group A described later. Preferred examples of the substituent in the case where the aryl group of the diarylamino group is substituted include the groups of the substituent group A, and also include a cyano group and a substituted amino group. Instead of the substituent group A, the substituent can be selected from the substituent group B, can be selected from the substituent group C, or can be selected from the substituent group D.

For the specific examples of the compound group and the compounds encompassed in the general formula (10), reference may be made to WO 2013/154064, paragraphs 0008 to 0048; WO 2015/080183, paragraphs 0009 to 0030; WO 2015/129715, paragraphs 0006 to 0019; JP 2017-119663 A, paragraphs 0013 to 0025; and JP 2017-119664 A, paragraphs 0013 to 0026, which are incorporated as a part of this description by reference.

A compound represented by the following general formula (11) emitting delayed fluorescent light is also particularly preferably used as the delayed fluorescent material in the present invention. In a preferred embodiment of the present invention, a compound represented by the general formula (11) may be used as the second organic compound.

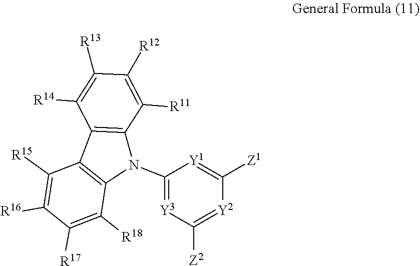

In the general formula (11), any two of Y¹, Y², and Y³ represent nitrogen atoms, and the remaining one thereof represents a methine group, or all Y¹, Y², and Y³ represent nitrogen atoms. Z¹ and Z² each independently represent a hydrogen atom, a deuterium atom, or a substituent. R¹¹ to R¹⁸ each independently represent a hydrogen atom, a deuterium atom, or a substituent, in which at least one of R¹¹ to R¹⁸ preferably represents a substituted or unsubstituted arylamino group or a substituted or unsubstituted carbazolyl group. The benzene ring constituting the arylamino group and the benzene ring constituting the carbazolyl group each may form a single bond or a linking group with R¹¹ to R¹⁸. The compound represented by the general formula (11) includes at least two carbazole structures in the molecule thereof. For example, the substituent that Z¹ and Z² can be selected from the substituent group A described later, can be selected from the substituent group B described later, can be selected from the substituent group C described later, and can be selected from the substituent group D described later. Specific examples of the substituent that R¹¹ to R¹⁸, the arylamino group, and the carbazolyl group can have include the substituents of the substituent group A described later, a cyano group, a substituted arylamino group, and a substituted alkylamino group. R¹¹ and R¹², R¹² and R¹³, R¹³ and R¹⁴, R¹⁵ and R¹⁶, R¹⁶ and R¹⁷, and R¹⁷ and R¹⁸ each may be bonded to each other to form a cyclic structure.

In the compound represented by the general formula (11), a compound represented by the following general formula (12) is particularly useful.

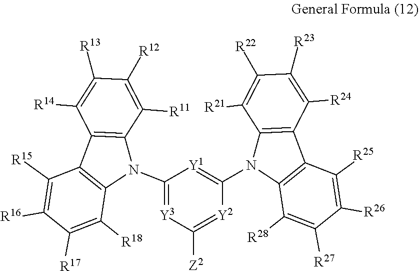

In the general formula (12), any two of Y¹, Y², and Y³ represent nitrogen atoms, and the remaining one thereof represents a methine group, or all Y¹, Y², and Y³ represent nitrogen atoms. Z² represents a hydrogen atom, a deuterium atom, or a substituent. R¹¹ to R¹⁸ and R²¹ to R²⁸ each independently represent a hydrogen atom, a deuterium atom, or a substituent, in which at least one of R¹¹ to R¹⁸ and/or at least one of R²¹ to R²⁸ preferably represents a substituted or unsubstituted arylamino group or a substituted or unsubstituted carbazolyl group. The benzene ring constituting the arylamino group and the benzene ring constituting the carbazolyl group each may form a single bond or a linking group with R¹¹ to R¹⁸ or R²¹ to R²⁸. Examples of the substituent that Z² can represent include the substituents of the substituent group A described later, the substituents of the substituent group B described later, the substituents of the substituent group C described later, and the substituents of the substituent group D described later. Specific examples of the substituent that R¹¹ to R¹⁸, R²¹ to R²⁸, the arylamino group, and the carbazolyl group can have include the substituents of the substituent group A described later, a cyano group, a substituted arylamino group, and a substituted alkylamino group. R¹¹ and R¹², R¹² and R¹³, R¹³ and R¹⁴, R¹⁵ and R¹⁶, R¹⁶ and R¹⁷, R¹⁷ and R¹⁸, R²¹ and R²², R²² and R²³, R²³ and R²⁴, R²⁵ and R²⁶, R²⁶ and R²⁷, and R²⁷ and R²⁸ each may be bonded to each other to form a cyclic structure.

For the specific examples of the compound group and the compounds encompassed in the general formula (12), reference may be made to the compounds described in WO 2013/081088, paragraphs 0020 to 0062, and Appl. Phys. Let., 98, 083302 (2011), which are incorporated as a part of this description by reference.

A compound represented by the following general formula (13) emitting delayed fluorescent light is also particularly preferably used as the delayed fluorescent material in the present invention.

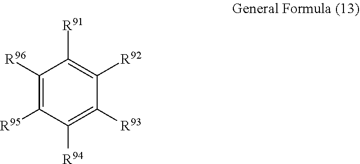

In the general formula (13), R⁹¹ to R⁹⁶ each independently represent a hydrogen atom, a deuterium atom, a donor group, or an acceptor group, in which at least one thereof is the donor group, and at least two thereof are the acceptor groups. The substitution positions of the at least two acceptor groups are not particularly limited, and it is preferred that two acceptor groups that are respectively in meta-positions are contained. For example, in the case where R⁹¹ represents the donor group, preferred examples of the structure include a structure where at least R⁹² and R⁹⁴ represent the acceptor groups, and a structure where at least R⁹² and R⁹⁶ represent the acceptor groups. The acceptor groups existing in the molecule may be the same as or different from each other, and a structure where all the groups are the same may be employed. The number of the acceptor groups is preferably 2 to 3, and for example, 2 may be selected therefor. Two or more donor groups may exist, and in this case, the donor groups may be the same as or different from each other. The number of donor group is preferably 1 to 3, and for example, may be 1, or may be 2. For the description and the preferred ranges of the donor group and the acceptor group, reference may be made to the corresponding description and the corresponding preferred ranges in the general formula (4). In the general formula (13), in particular, the donor group is preferably a group represented by the general formula (6), and the acceptor group is preferably a cyano group or a group represented by the following general formula (14).

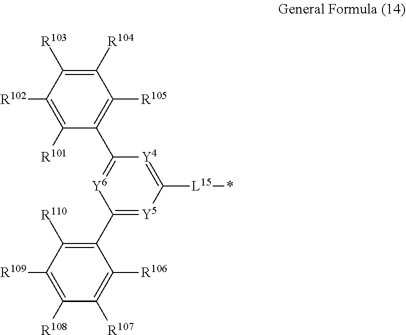

In the general formula (14), Y⁴ to Y⁶ each represent a nitrogen atom or a methine group, in which at least one thereof represents a nitrogen atom, and all thereof preferably represent nitrogen atoms. R¹⁰¹ to R¹¹⁰ each independently represent a hydrogen atom, a deuterium atom, or a substituent, in which at least one thereof preferably represents an alkyl group. For the description and the preferred ranges of the substituent herein, reference may be made to the description and the preferred ranges for the substituent in the general formula (10). L¹⁵ represents a single bond or a linking group, and therefor, reference may be made to the description and the preferred ranges for L in the general formula (6). In one preferred embodiment of the present invention, L¹⁵ in the general formula (14) represents a single bond. * indicates the bonding position to the carbon atom (C) constituting the ring skeleton of the ring in the general formula (13).

Preferred examples of the compound that can be used as the second organic compound are shown below. In the following structural formulae of the example compounds, t-Bu represents a tert-butyl group.

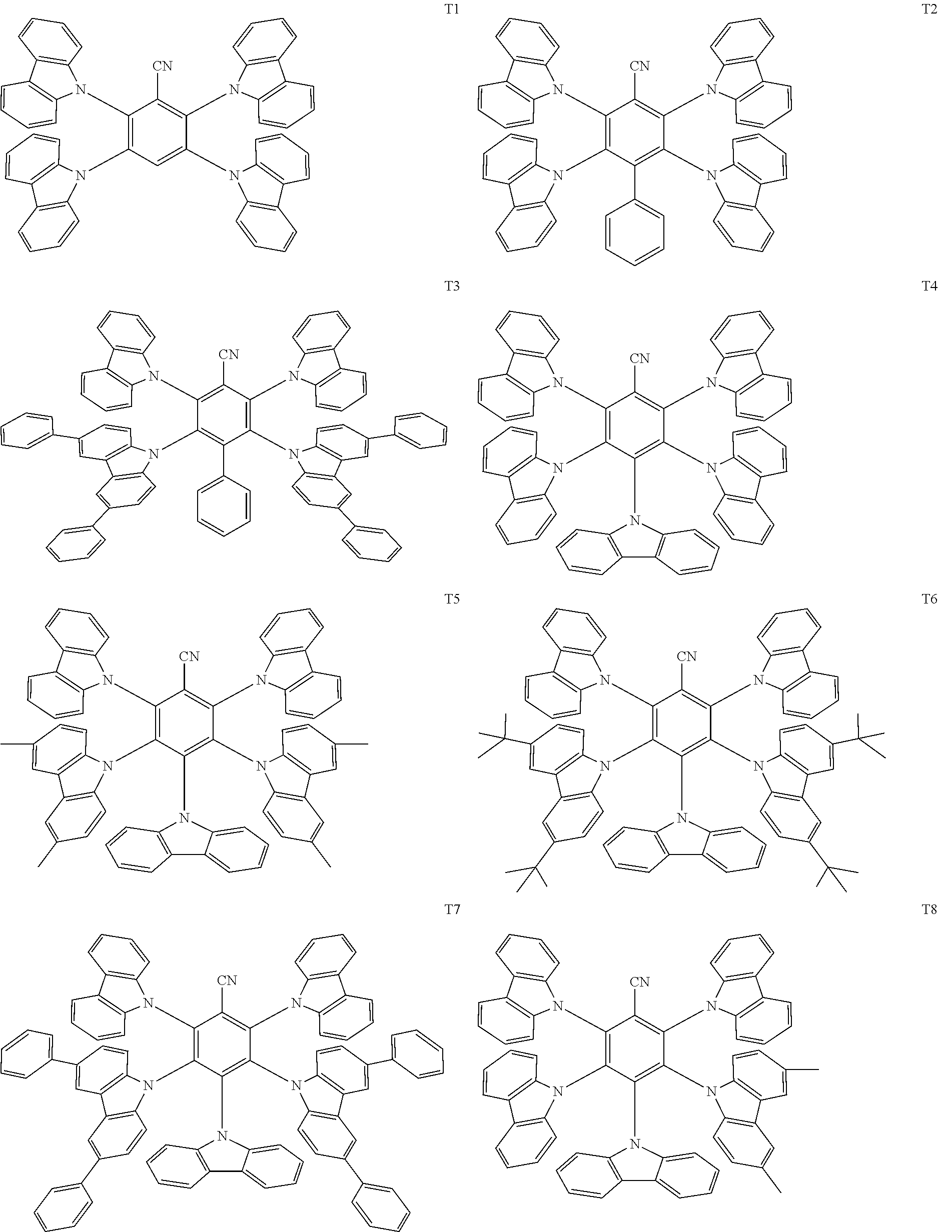

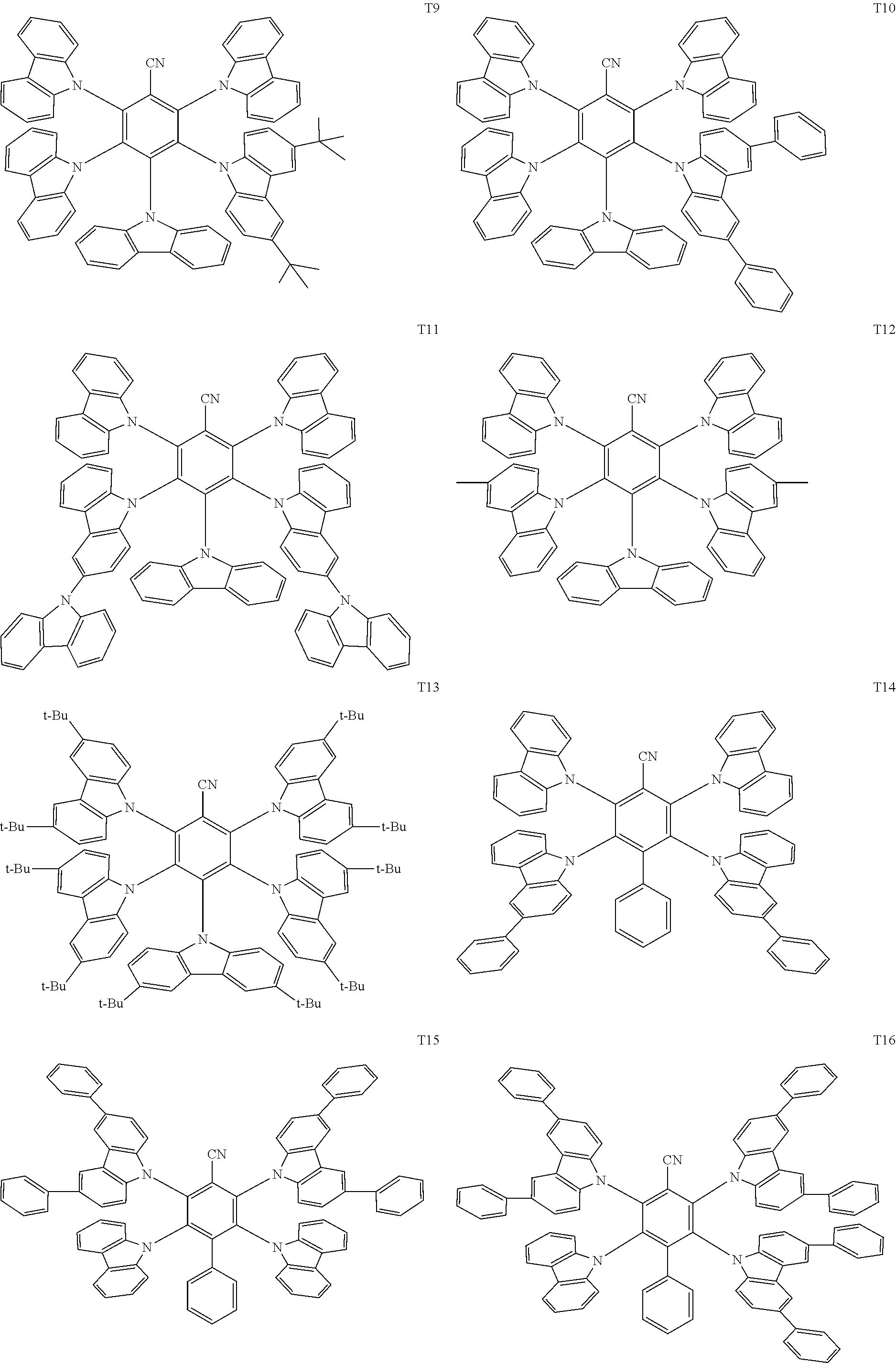

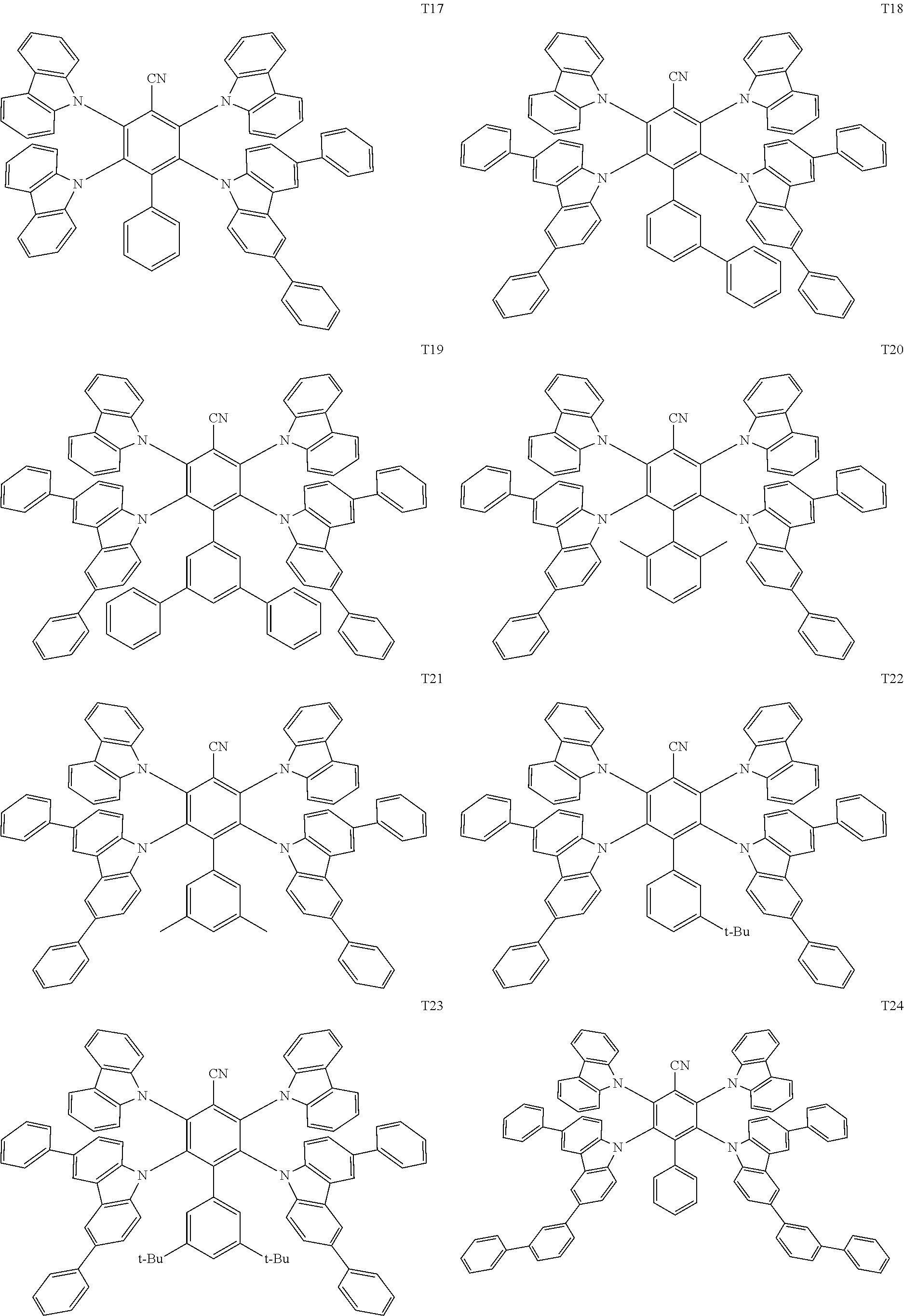

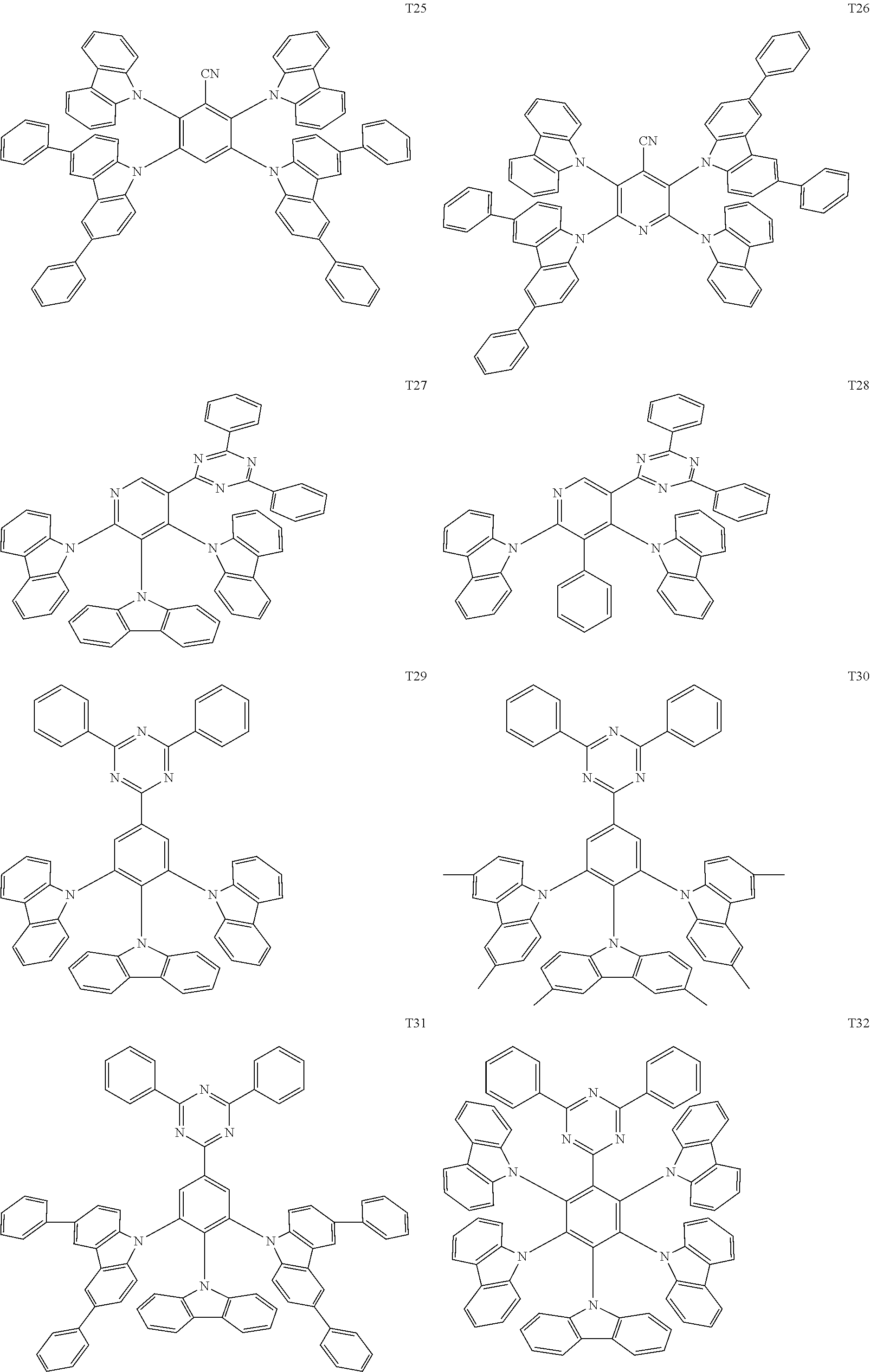

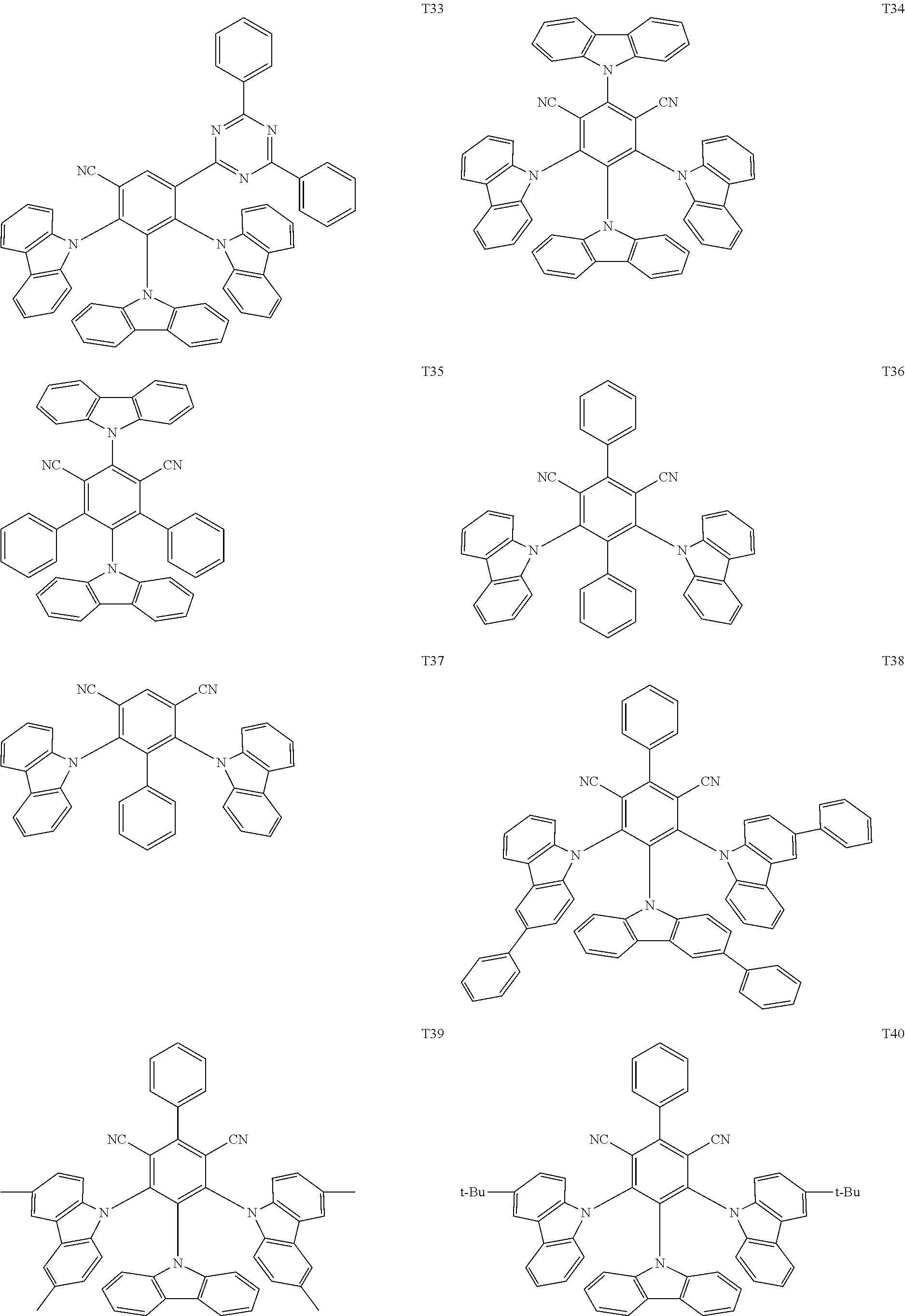

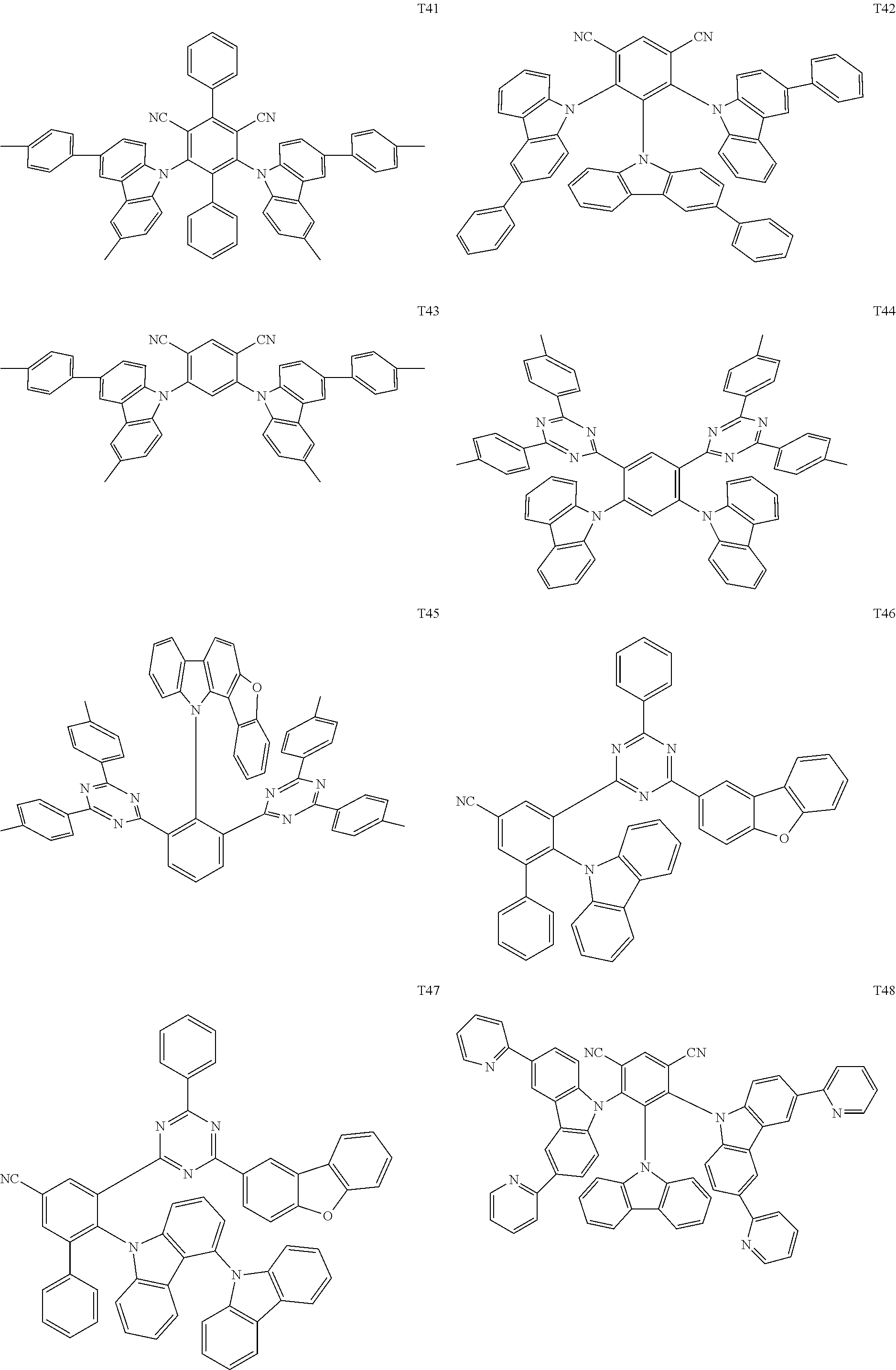

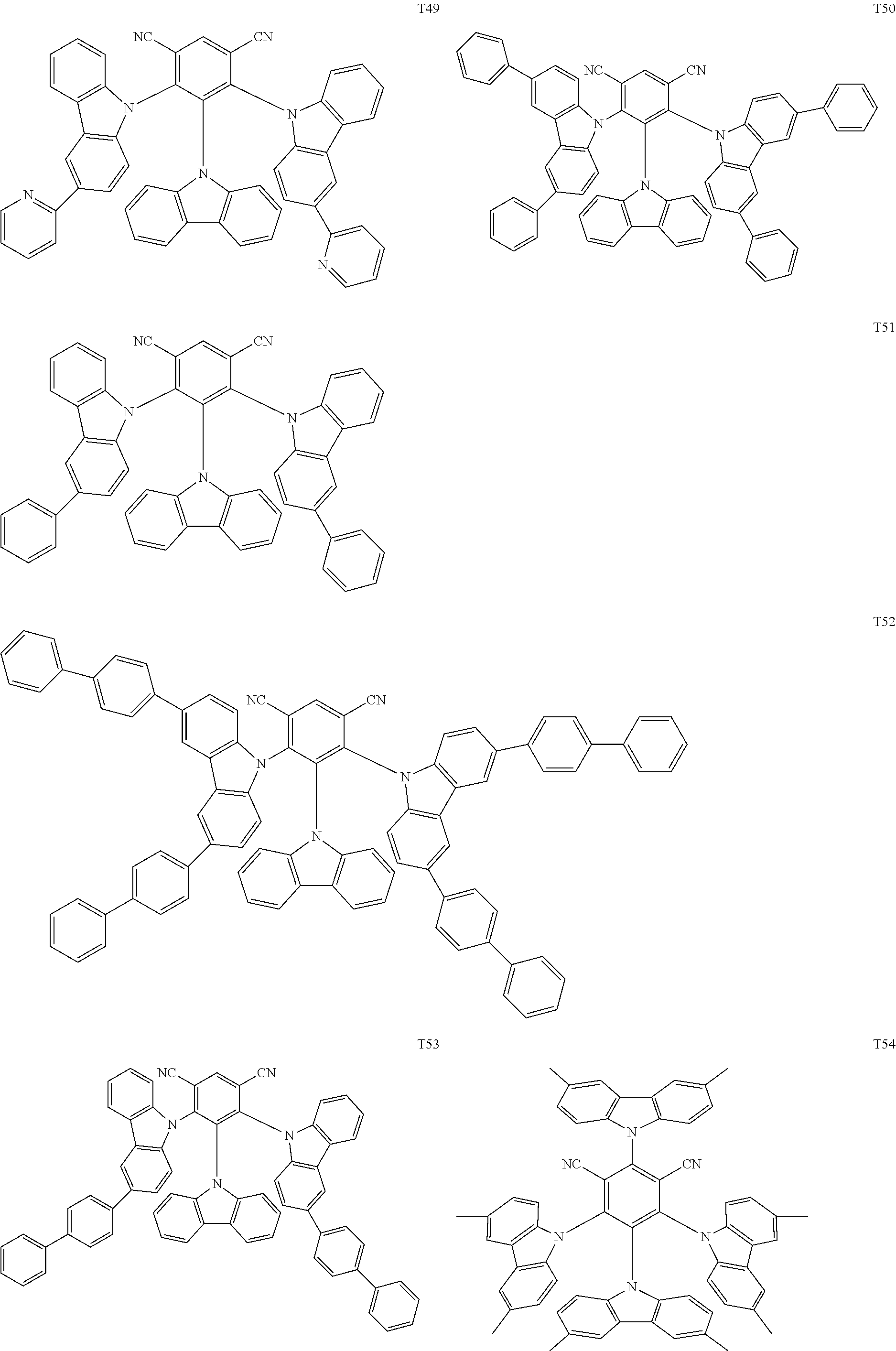

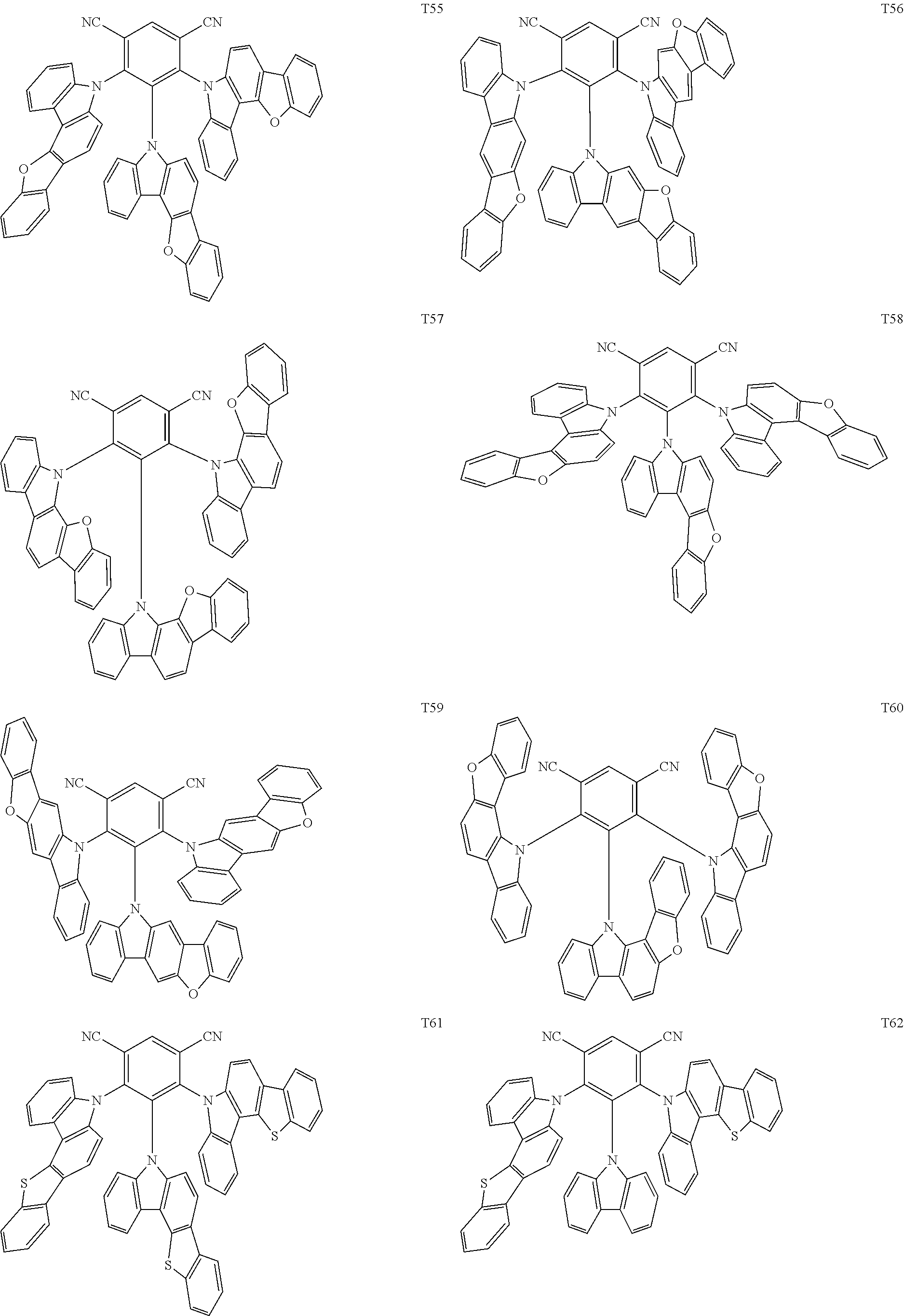

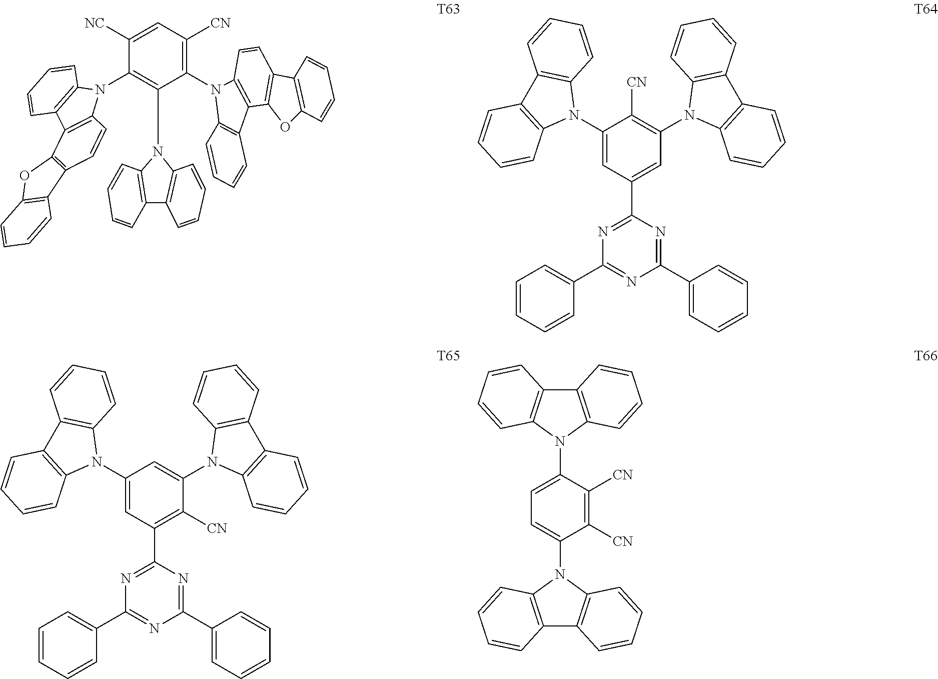

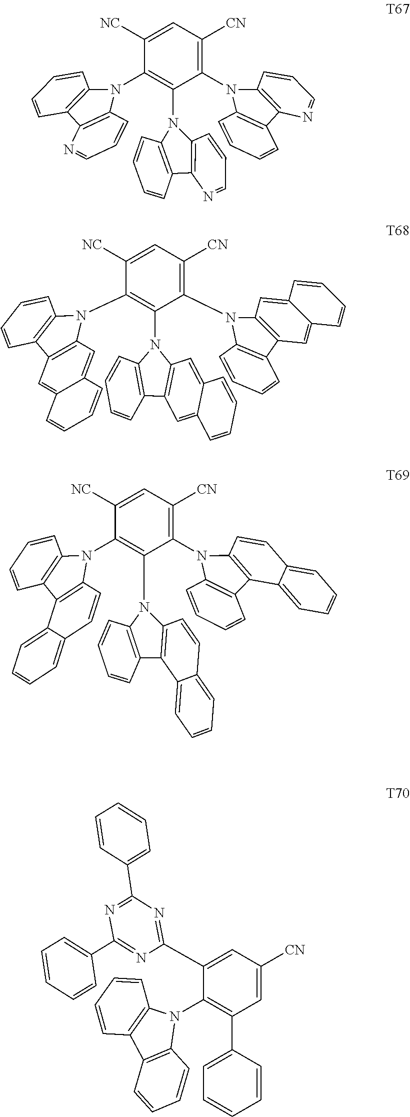 [SMILES: N#Cc1cc(C#N)c(-n2c3ccccc3c3ncccc32)c(-n2c3ccccc3c3ncccc32)c1-n1c2ccccc2c2ncccc21 ; N#Cc1cc(C#N)c(-n2c3ccccc3c3cc4ccccc4cc32)c(-n2c3ccccc3c3cc4ccccc4cc32)c1-n1c2ccccc2c2cc3ccccc3cc21 ; N#Cc1cc(C#N)c(-n2c3ccccc3c3c4ccccc4ccc32)c(-n2c3ccccc3c3c4ccccc4ccc32)c1-n1c2ccccc2c2c3ccccc3ccc21 ; N#Cc1cc(-c2ccccc2)c(-n2c3ccccc3c3ccccc32)c(-c2nc(-c3ccccc3)nc(-c3ccccc3)n2)c1]

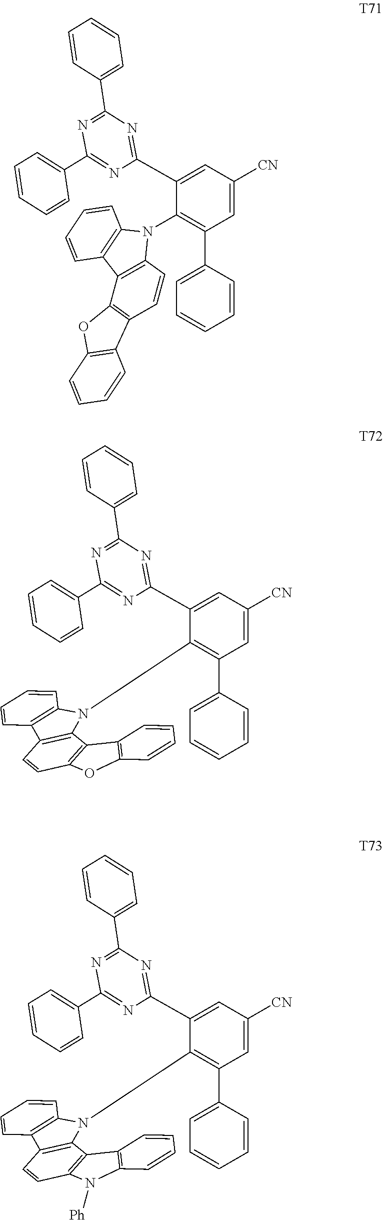

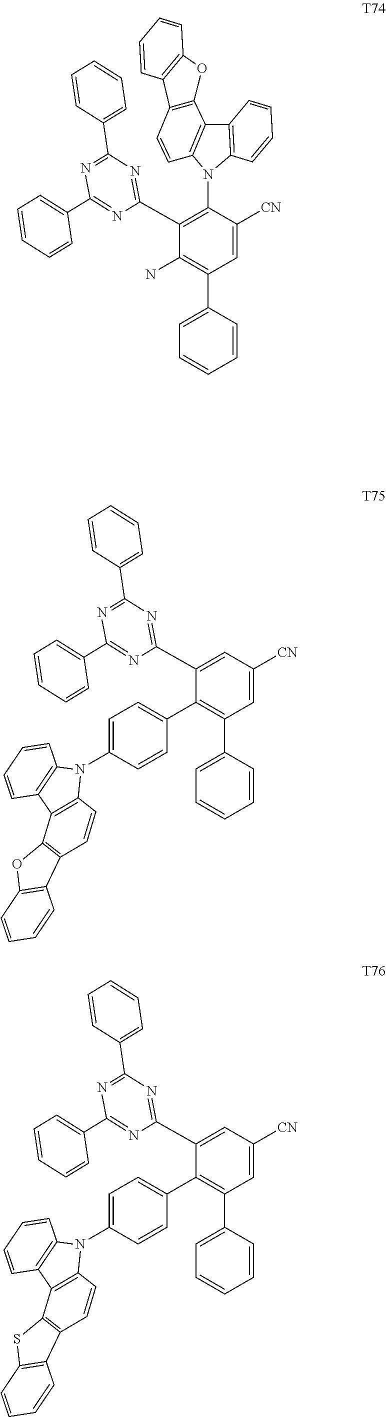 [SMILES: N#Cc1cc(-c2ccccc2)c(N)c(-c2nc(-c3ccccc3)nc(-c3ccccc3)n2)c1-n1c2ccccc2c2c3oc4ccccc4c3ccc21 ; N#Cc1cc(-c2ccccc2)c(-c2ccc(-n3c4ccccc4c4c5oc6ccccc6c5ccc43)cc2)c(-c2nc(-c3ccccc3)nc(-c3ccccc3)n2)c1 ; N#Cc1cc(-c2ccccc2)c(-c2ccc(-n3c4ccccc4c4c5sc6ccccc6c5ccc43)cc2)c(-c2nc(-c3ccccc3)nc(-c3ccccc3)n2)c1]

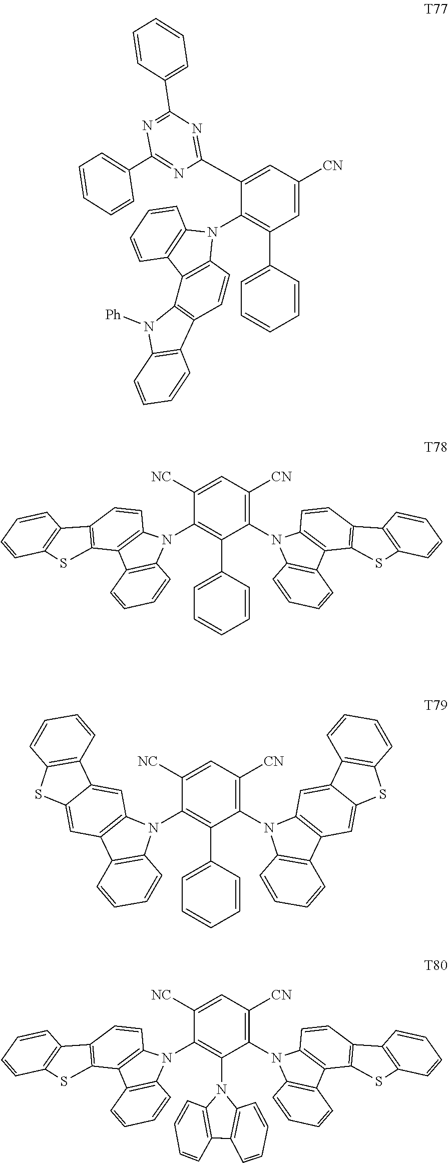

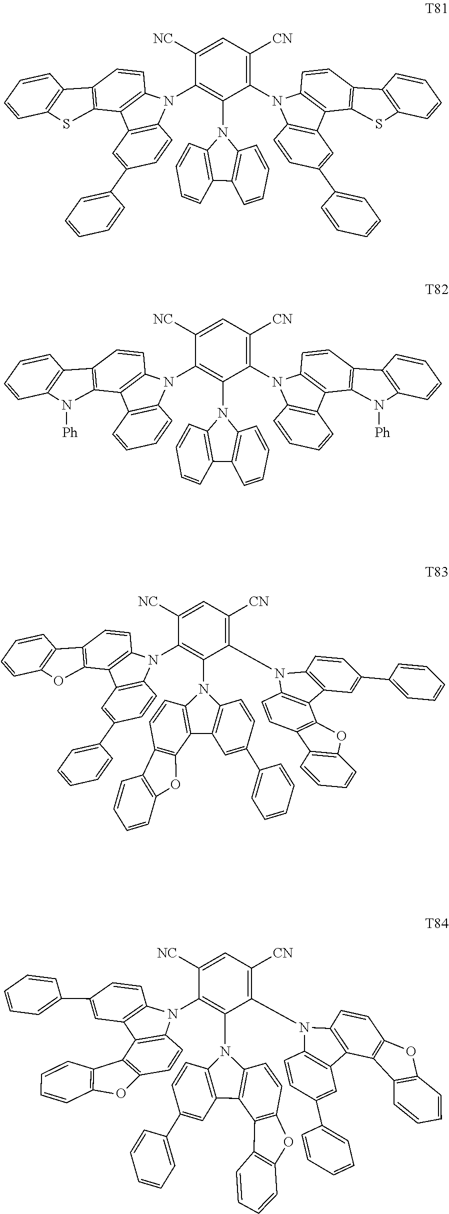

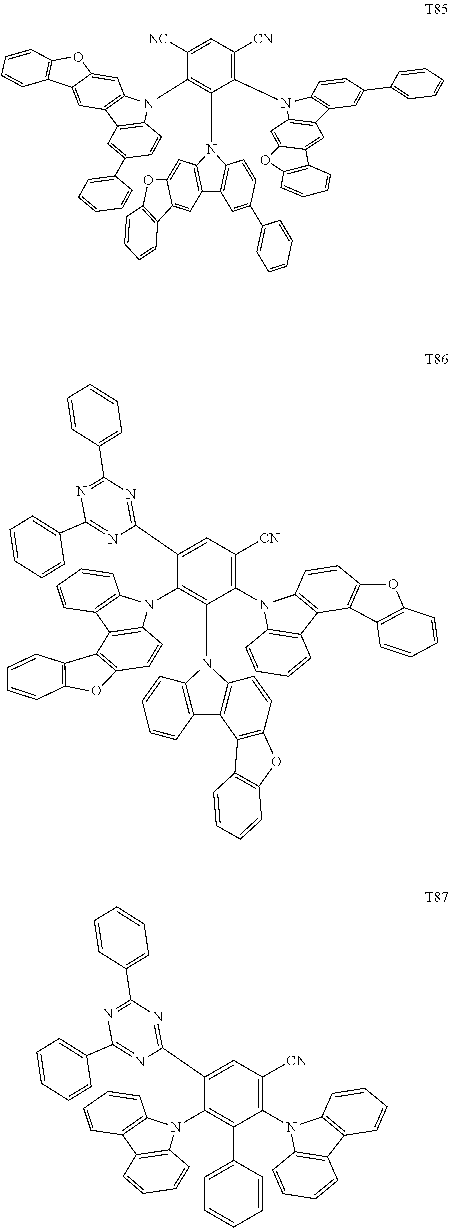 [SMILES: N#Cc1cc(C#N)c(-n2c3ccc(-c4ccccc4)cc3c3cc4c(cc32)oc2ccccc24)c(-n2c3ccc(-c4ccccc4)cc3c3cc4c(cc32)oc2ccccc24)c1-n1c2ccc(-c3ccccc3)cc2c2cc3c(cc21)oc1ccccc13 ; N#Cc1cc(-c2nc(-c3ccccc3)nc(-c3ccccc3)n2)c(-n2c3ccccc3c3c4c(ccc32)oc2ccccc24)c(-n2c3ccccc3c3c4c(ccc32)oc2ccccc24)c1-n1c2ccccc2c2c3c(ccc21)oc1ccccc13 ; N#Cc1cc(-c2nc(-c3ccccc3)nc(-c3ccccc3)n2)c(-n2c3ccccc3c3ccccc32)c(-c2ccccc2)c1-n1c2ccccc2c2ccccc21]

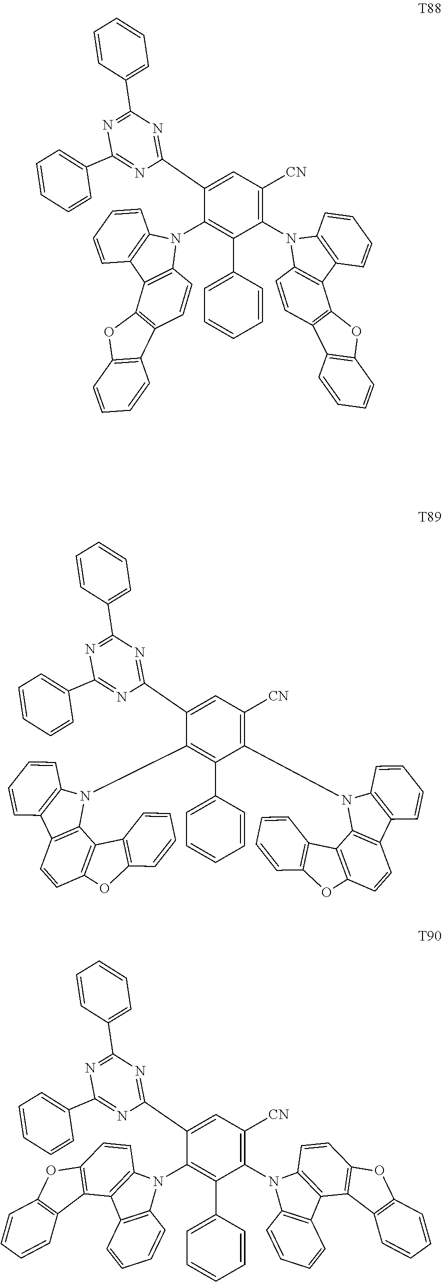 [SMILES: N#Cc1cc(-c2nc(-c3ccccc3)nc(-c3ccccc3)n2)c(-n2c3ccccc3c3c4oc5ccccc5c4ccc32)c(-c2ccccc2)c1-n1c2ccccc2c2c3oc4ccccc4c3ccc21 ; N#Cc1cc(-c2nc(-c3ccccc3)nc(-c3ccccc3)n2)c(-n2c3ccccc3c3ccc4oc5ccccc5c4c32)c(-c2ccccc2)c1-n1c2ccccc2c2ccc3oc4ccccc4c3c21 ; N#Cc1cc(-c2nc(-c3ccccc3)nc(-c3ccccc3)n2)c(-n2c3ccccc3c3c4c(ccc32)oc2ccccc24)c(-c2ccccc2)c1-n1c2ccccc2c2c3c(ccc21)oc1ccccc13]

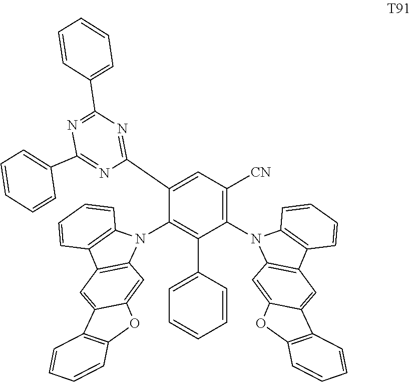 [SMILES: N#Cc1cc(-c2nc(-c3ccccc3)nc(-c3ccccc3)n2)c(-n2c3ccccc3c3cc4c(cc32)oc2ccccc24)c(-c2ccccc2)c1-n1c2ccccc2c2cc3c(cc21)oc1ccccc13]

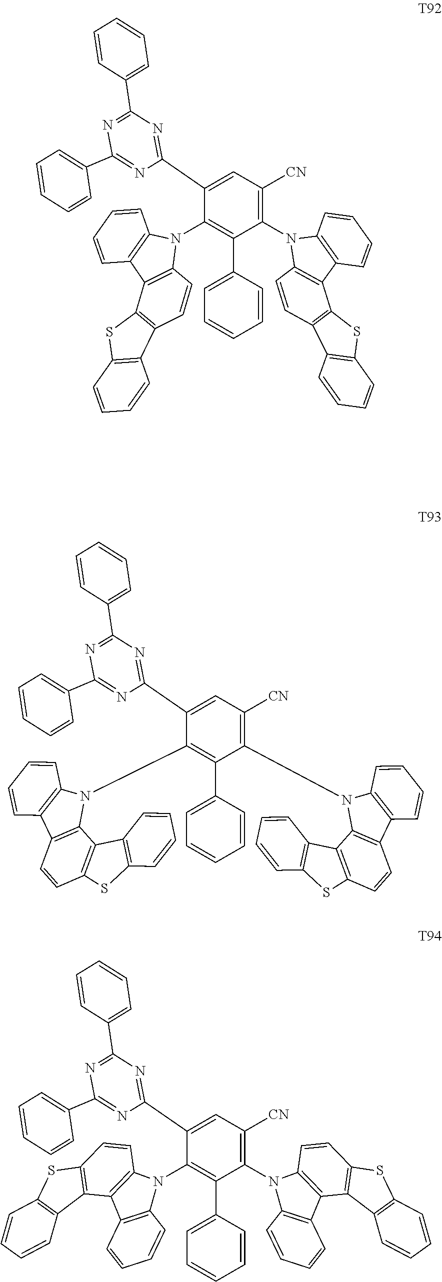 [SMILES: N#Cc1cc(-c2nc(-c3ccccc3)nc(-c3ccccc3)n2)c(-n2c3ccccc3c3c4sc5ccccc5c4ccc32)c(-c2ccccc2)c1-n1c2ccccc2c2c3sc4ccccc4c3ccc21 ; N#Cc1cc(-c2nc(-c3ccccc3)nc(-c3ccccc3)n2)c(-n2c3ccccc3c3ccc4sc5ccccc5c4c32)c(-c2ccccc2)c1-n1c2ccccc2c2ccc3sc4ccccc4c3c21 ; N#Cc1cc(-c2nc(-c3ccccc3)nc(-c3ccccc3)n2)c(-n2c3ccccc3c3c4c(ccc32)sc2ccccc24)c(-c2ccccc2)c1-n1c2ccccc2c2c3c(ccc21)sc1ccccc13]

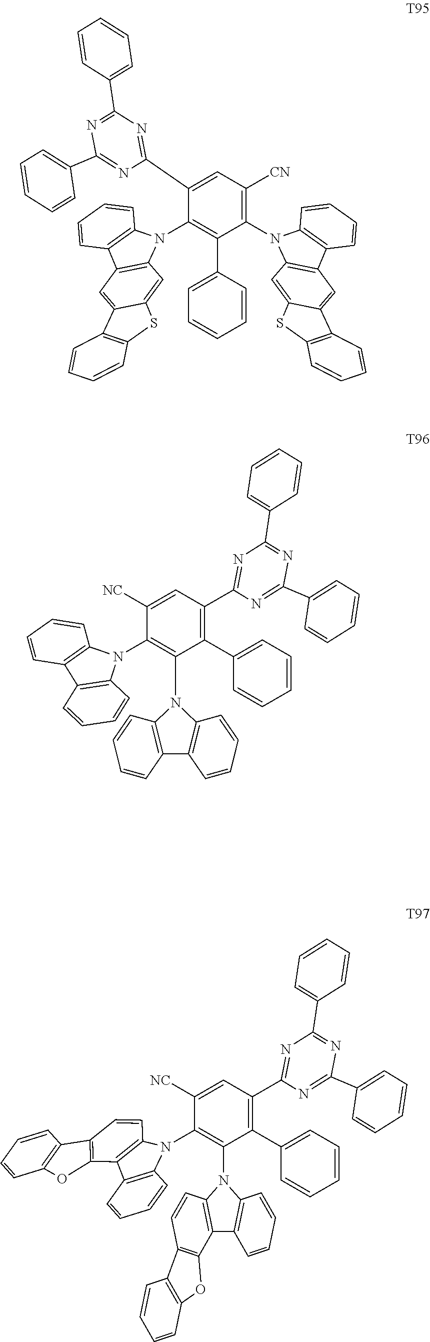 [SMILES: N#Cc1cc(-c2nc(-c3ccccc3)nc(-c3ccccc3)n2)c(-n2c3ccccc3c3cc4c(cc32)sc2ccccc24)c(-c2ccccc2)c1-n1c2ccccc2c2cc3c(cc21)sc1ccccc13 ; N#Cc1cc(-c2nc(-c3ccccc3)nc(-c3ccccc3)n2)c(-c2ccccc2)c(-n2c3ccccc3c3ccccc32)c1-n1c2ccccc2c2ccccc21 ; N#Cc1cc(-c2nc(-c3ccccc3)nc(-c3ccccc3)n2)c(-c2ccccc2)c(-n2c3ccccc3c3c4oc5ccccc5c4ccc32)c1-n1c2ccccc2c2c3oc4ccccc4c3ccc21]

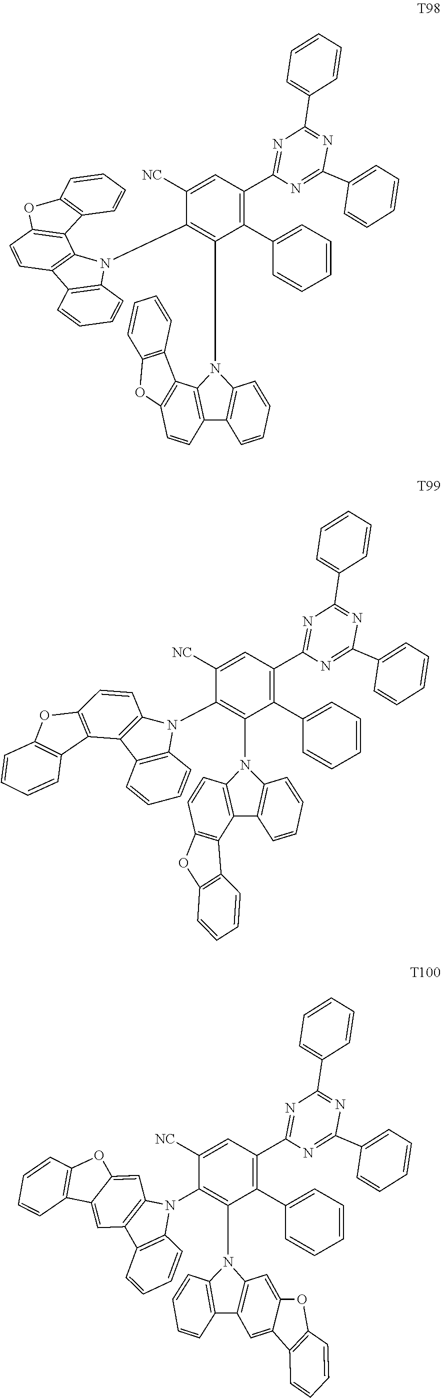 [SMILES: N#Cc1cc(-c2nc(-c3ccccc3)nc(-c3ccccc3)n2)c(-c2ccccc2)c(-n2c3ccccc3c3ccc4oc5ccccc5c4c32)c1-n1c2ccccc2c2ccc3oc4ccccc4c3c21 ; N#Cc1cc(-c2nc(-c3ccccc3)nc(-c3ccccc3)n2)c(-c2ccccc2)c(-n2c3ccccc3c3c4c(ccc32)oc2ccccc24)c1-n1c2ccccc2c2c3c(ccc21)oc1ccccc13 ; N#Cc1cc(-c2nc(-c3ccccc3)nc(-c3ccccc3)n2)c(-c2ccccc2)c(-n2c3ccccc3c3cc4c(cc32)oc2ccccc24)c1-n1c2ccccc2c2cc3c(cc21)oc1ccccc13]

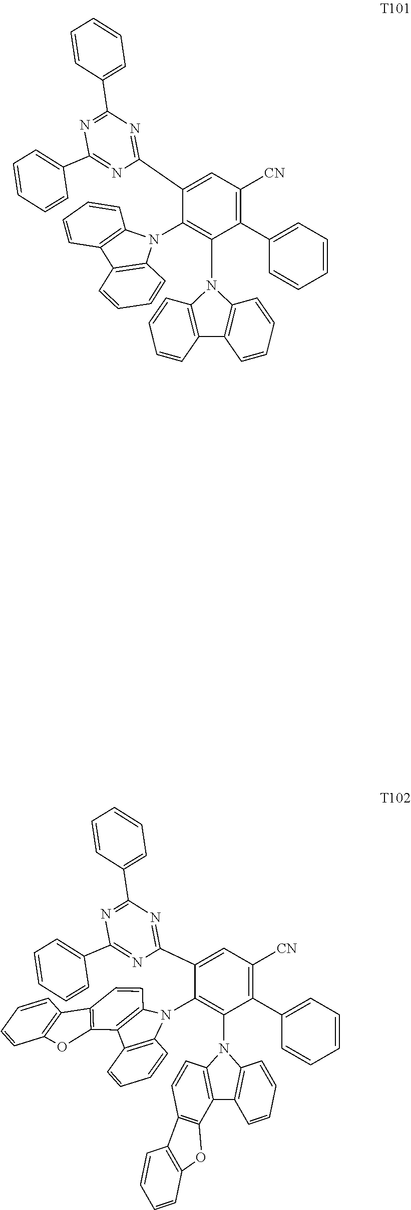 [SMILES: N#Cc1cc(-c2nc(-c3ccccc3)nc(-c3ccccc3)n2)c(-n2c3ccccc3c3ccccc32)c(-n2c3ccccc3c3ccccc32)c1-c1ccccc1 ; N#Cc1cc(-c2nc(-c3ccccc3)nc(-c3ccccc3)n2)c(-n2c3ccccc3c3c4oc5ccccc5c4ccc32)c(-n2c3ccccc3c3c4oc5ccccc5c4ccc32)c1-c1ccccc1]

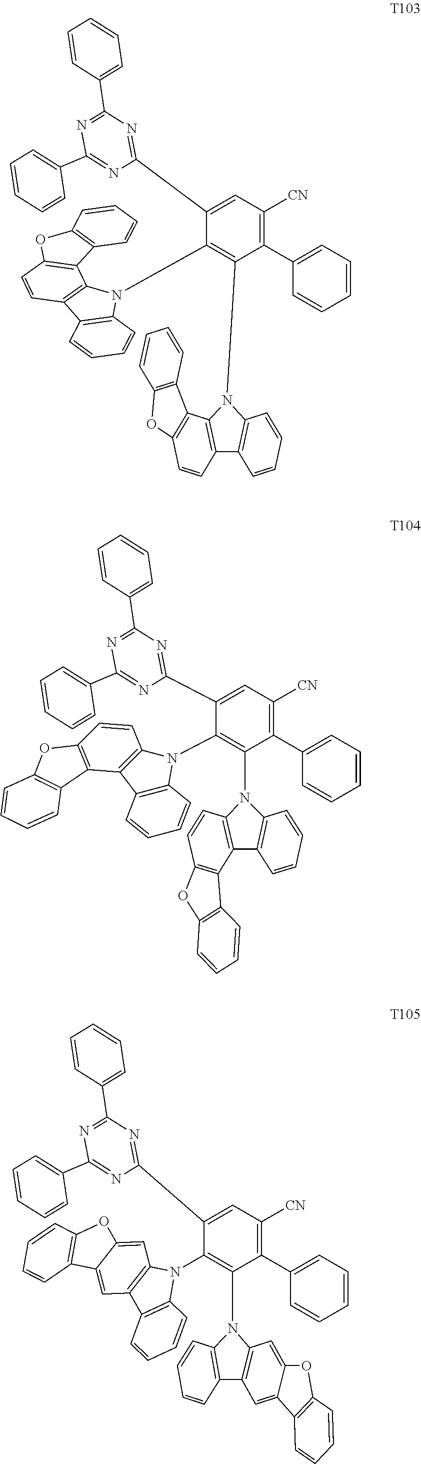 [SMILES: N#Cc1cc(-c2nc(-c3ccccc3)nc(-c3ccccc3)n2)c(-n2c3ccccc3c3ccc4oc5ccccc5c4c32)c(-n2c3ccccc3c3ccc4oc5ccccc5c4c32)c1-c1ccccc1 ; N#Cc1cc(-c2nc(-c3ccccc3)nc(-c3ccccc3)n2)c(-n2c3ccccc3c3c4c(ccc32)oc2ccccc24)c(-n2c3ccccc3c3c4c(ccc32)oc2ccccc24)c1-c1ccccc1 ; N#Cc1cc(-c2nc(-c3ccccc3)nc(-c3ccccc3)n2)c(-n2c3ccccc3c3cc4c(cc32)oc2ccccc24)c(-n2c3ccccc3c3cc4c(cc32)oc2ccccc24)c1-c1ccccc1]

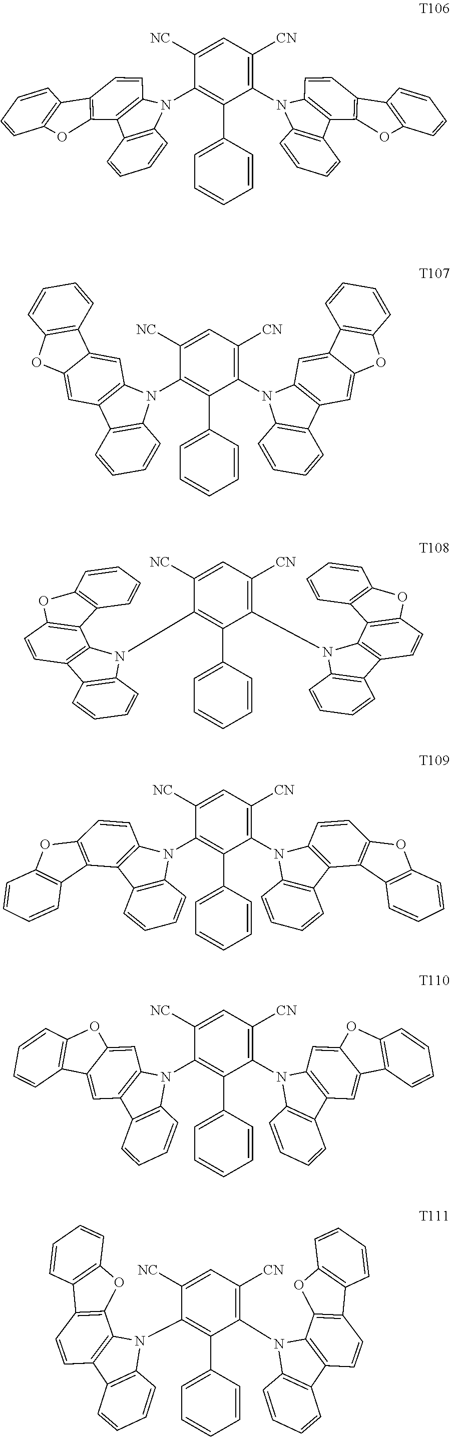

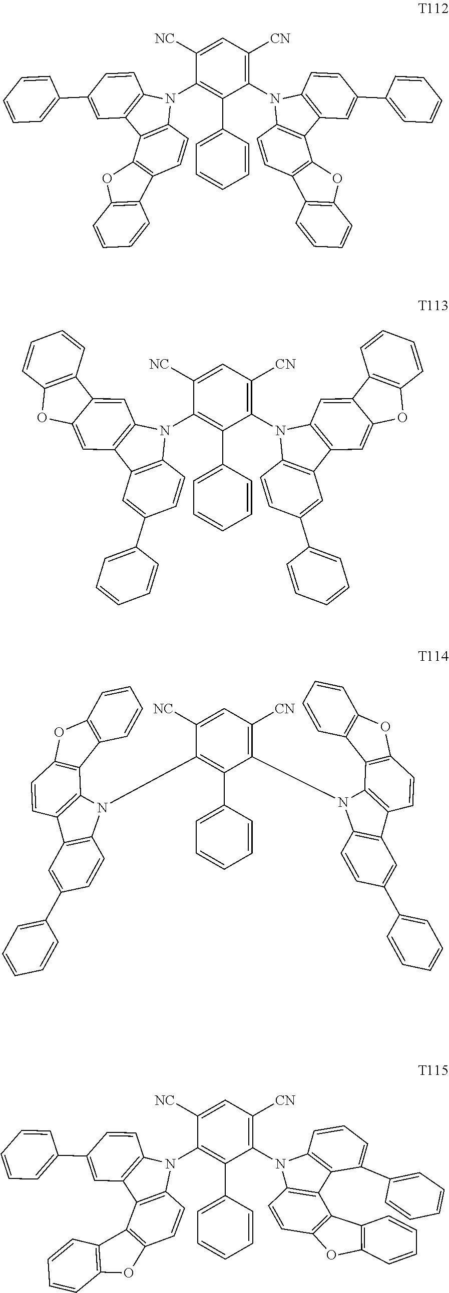 [SMILES: N#Cc1cc(C#N)c(-n2c3ccc(-c4ccccc4)cc3c3c4oc5ccccc5c4ccc32)c(-c2ccccc2)c1-n1c2ccc(-c3ccccc3)cc2c2c3oc4ccccc4c3ccc21 ; N#Cc1cc(C#N)c(-n2c3ccc(-c4ccccc4)cc3c3cc4oc5ccccc5c4cc32)c(-c2ccccc2)c1-n1c2ccc(-c3ccccc3)cc2c2cc3oc4ccccc4c3cc21 ; N#Cc1cc(C#N)c(-n2c3ccc(-c4ccccc4)cc3c3ccc4oc5ccccc5c4c32)c(-c2ccccc2)c1-n1c2ccc(-c3ccccc3)cc2c2ccc3oc4ccccc4c3c21 ; N#Cc1cc(C#N)c(-n2c3cccc(-c4ccccc4)c3c3c4c(ccc32)oc2ccccc24)c(-c2ccccc2)c1-n1c2ccc(-c3ccccc3)cc2c2c3c(ccc21)oc1ccccc13]

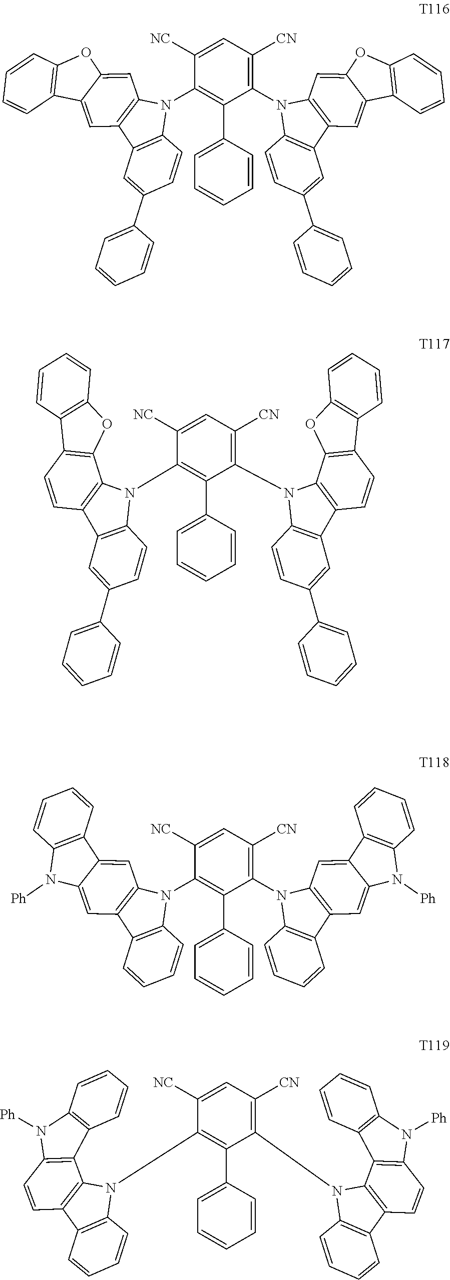 [SMILES: N#Cc1cc(C#N)c(-n2c3ccc(-c4ccccc4)cc3c3cc4c(cc32)oc2ccccc24)c(-c2ccccc2)c1-n1c2ccc(-c3ccccc3)cc2c2cc3c(cc21)oc1ccccc13 ; N#Cc1cc(C#N)c(-n2c3ccc(-c4ccccc4)cc3c3ccc4c5ccccc5oc4c32)c(-c2ccccc2)c1-n1c2ccc(-c3ccccc3)cc2c2ccc3c4ccccc4oc3c21 ; N#Cc1cc(C#N)c(-n2c3ccccc3c3cc4c(cc32)c2ccccc2n4-c2ccccc2)c(-c2ccccc2)c1-n1c2ccccc2c2cc3c(cc21)c1ccccc1n3-c1ccccc1 ; N#Cc1cc(C#N)c(-n2c3ccccc3c3ccc4c(c5ccccc5n4-c4ccccc4)c32)c(-c2ccccc2)c1-n1c2ccccc2c2ccc3c(c4ccccc4n3-c3ccccc3)c21]

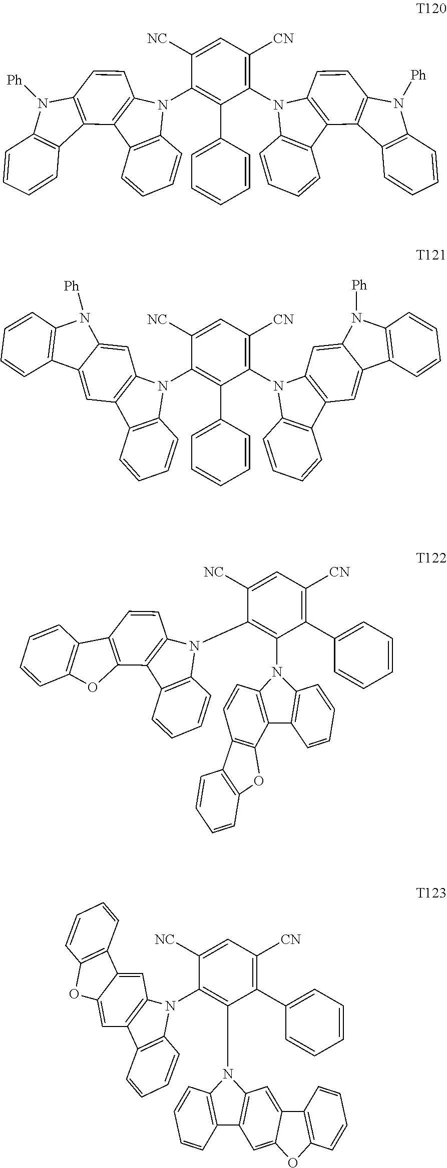 [SMILES: N#Cc1cc(C#N)c(-n2c3ccccc3c3c4c5ccccc5n(-c5ccccc5)c4ccc32)c(-c2ccccc2)c1-n1c2ccccc2c2c3c4ccccc4n(-c4ccccc4)c3ccc21 ; N#Cc1cc(C#N)c(-n2c3ccccc3c3cc4c5ccccc5n(-c5ccccc5)c4cc32)c(-c2ccccc2)c1-n1c2ccccc2c2cc3c4ccccc4n(-c4ccccc4)c3cc21 ; N#Cc1cc(C#N)c(-n2c3ccccc3c3c4oc5ccccc5c4ccc32)c(-n2c3ccccc3c3c4oc5ccccc5c4ccc32)c1-c1ccccc1 ; N#Cc1cc(C#N)c(-n2c3ccccc3c3cc4oc5ccccc5c4cc32)c(-n2c3ccccc3c3cc4oc5ccccc5c4cc32)c1-c1ccccc1]

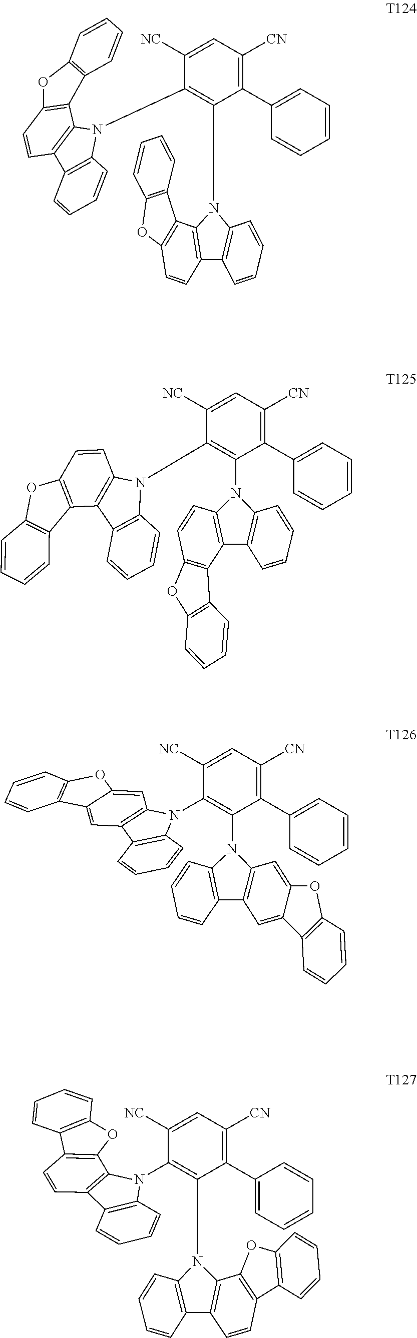 [SMILES: N#Cc1cc(C#N)c(-n2c3ccccc3c3ccc4oc5ccccc5c4c32)c(-n2c3ccccc3c3ccc4oc5ccccc5c4c32)c1-c1ccccc1 ; N#Cc1cc(C#N)c(-n2c3ccccc3c3c4c(ccc32)oc2ccccc24)c(-n2c3ccccc3c3c4c(ccc32)oc2ccccc24)c1-c1ccccc1 ; N#Cc1cc(C#N)c(-n2c3ccccc3c3cc4c(cc32)oc2ccccc24)c(-n2c3ccccc3c3cc4c(cc32)oc2ccccc24)c1-c1ccccc1 ; N#Cc1cc(C#N)c(-n2c3ccccc3c3ccc4c5ccccc5oc4c32)c(-n2c3ccccc3c3ccc4c5ccccc5oc4c32)c1-c1ccccc1]

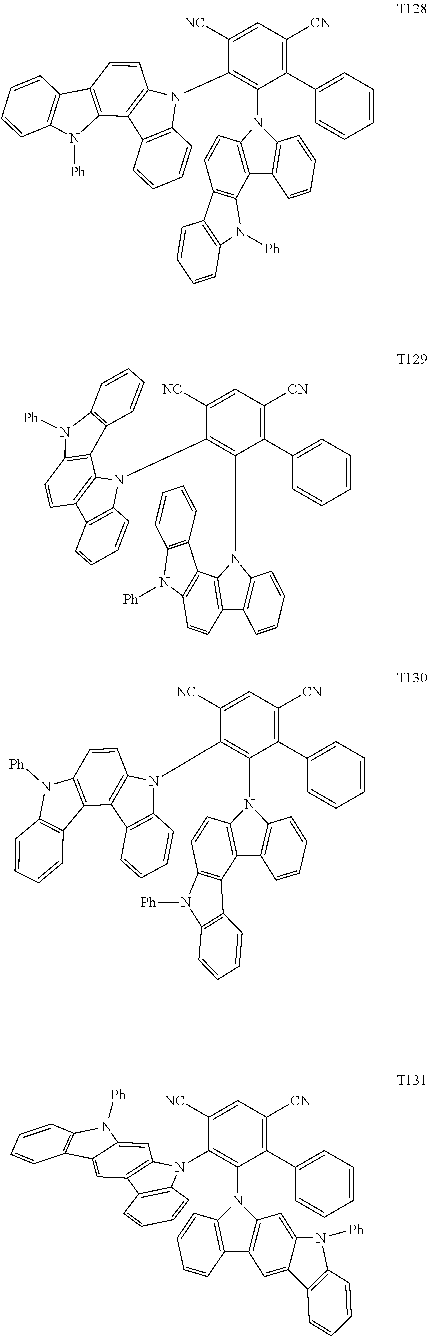 [SMILES: N#Cc1cc(C#N)c(-n2c3ccccc3c3c2ccc2c4ccccc4n(-c4ccccc4)c23)c(-n2c3ccccc3c3c2ccc2c4ccccc4n(-c4ccccc4)c23)c1-c1ccccc1 ; N#Cc1cc(C#N)c(-n2c3ccccc3c3ccc4c(c5ccccc5n4-c4ccccc4)c32)c(-n2c3ccccc3c3ccc4c(c5ccccc5n4-c4ccccc4)c32)c1-c1ccccc1 ; N#Cc1cc(C#N)c(-n2c3ccccc3c3c4c5ccccc5n(-c5ccccc5)c4ccc32)c(-n2c3ccccc3c3c4c5ccccc5n(-c5ccccc5)c4ccc32)c1-c1ccccc1 ; N#Cc1cc(C#N)c(-n2c3ccccc3c3cc4c5ccccc5n(-c5ccccc5)c4cc32)c(-n2c3ccccc3c3cc4c5ccccc5n(-c5ccccc5)c4cc32)c1-c1ccccc1]

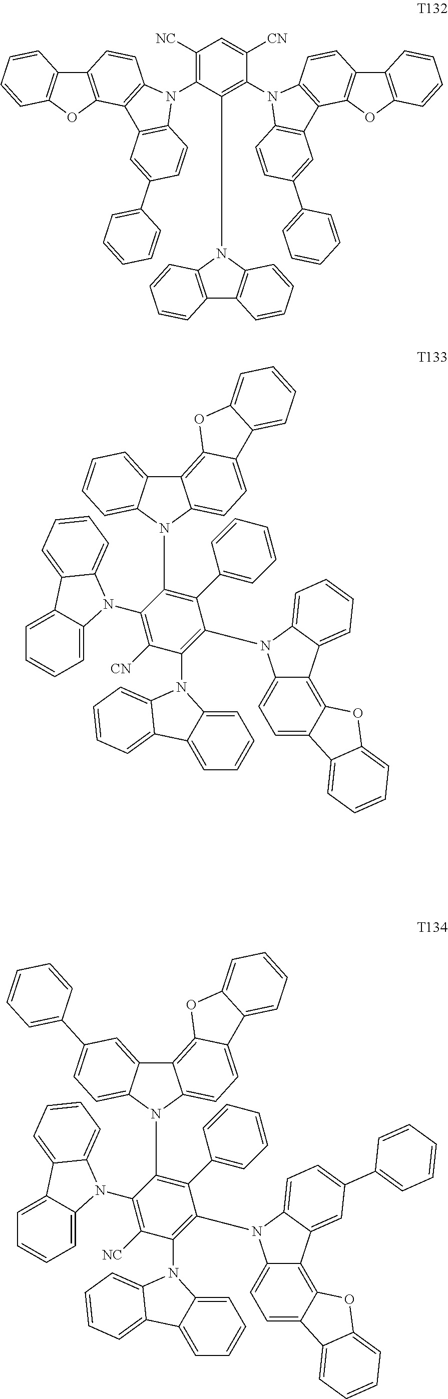

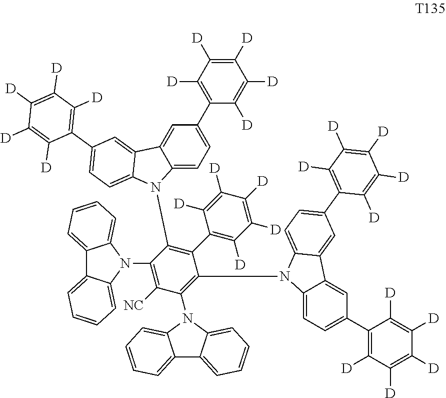 [SMILES: [2H]c1c([2H])c([2H])c(-c2ccc3c(c2)c2cc(-c4c([2H])c([2H])c([2H])c([2H])c4[2H])ccc2n3-c2c(-c3c([2H])c([2H])c([2H])c([2H])c3[2H])c(-n3c4ccc(-c5c([2H])c([2H])c([2H])c([2H])c5[2H])cc4c4cc(-c5c([2H])c([2H])c([2H])c([2H])c5[2H])ccc43)c(-n3c4ccccc4c4ccccc43)c(C#N)c2-n2c3ccccc3c3ccccc32)c([2H])c1[2H]]

The known delayed fluorescent materials other than above can be appropriately combined and used as the second organic compound. An unknown delayed fluorescent material can also be used.

As preferred delayed fluorescent materials, there can be mentioned compounds included in the general formulae described in WO2013/154064, paragraphs 0008 to 0048 and 0095 to 0133; WO2013/011954, paragraphs 0007 to 0047 and 0073˜0085; WO2013/011955, paragraphs 0007 to 0033 and 0059 to 0066; WO2013/081088, paragraphs 0008 to 0071 and 0118 to 0133; JP 2013-256490 A, paragraphs 0009 to 0046 and 0093 to 0134; JP 2013-116975 A, paragraphs 0008 to 0020 and 0038 to 0040; WO2013/133359, paragraphs 0007 to 0032 and 0079 to 0084; WO2013/161437, paragraphs 0008 to 0054 and 0101˜0121; JP 2014-9352 A, paragraphs 0007 to 0041 and 0060 to 0069; and JP 2014-9224 A, paragraphs 0008 to 0048 and 0067 to 0076; JP 2017-119663 A, paragraphs 0013 to 0025; JP 2017-119664 A, paragraphs 0013 to 0026; JP 2017-222623 A, paragraphs 0012 to 0025; JP 2017-226838 A, paragraphs 0010 to 0050; JP 2018-100411 A, paragraphs 0012 to 0043; WO2018/047853, paragraphs 0016 to 0044; and especially, exemplary compounds therein capable of emitting delayed fluorescence. In addition, also preferably employable here are light emitting materials capable of emitting delayed fluorescence, as described in JP 2013-253121 A, WO2013/133359, WO2014/034535, WO2014/115743, WO2014/122895, WO2014/126200, WO2014/136758, WO2014/133121, WO2014/136860, WO2014/196585, WO2014/189122, WO2014/168101, WO2015/008580, WO2014/203840, WO2015/002213, WO2015/016200, WO2015/019725, WO2015/072470, WO2015/108049, WO2015/080182, WO2015/072537, WO2015/080183, JP 2015-129240 A, WO2015/129714, WO2015/129715, WO2015/133501, WO2015/136880, WO2015/137244, WO2015/137202, WO2015/137136, WO2015/146541 and WO2015/159541. These patent publications described in this paragraph are hereby incorporated as a part of this description by reference.

### (Third Organic Compound)

The light emitting layer of the organic light emitting device of the present invention may further contain a third organic compound. The third organic compound is a fluorescent material having lowest excited singlet energy that is lower than the first organic compound and the second organic compound. In one preferred embodiment of the present invention, the third organic compound is a fluorescent material having lowest excited triplet energy that is smaller than the first organic compound and the second organic compound. The third organic compound may be a delayed fluorescent material, or may be a compound that does not emit delayed fluorescent light. In the case where the third organic compound is a delayed fluorescent material, the lowest excited triplet energy thereof may be higher than the lowest excited triplet energy of the second organic compound. The third organic compound may be a compound having energy of the HOMO that is higher than the energy of the HOMO of the second organic compound or a compound having energy of the HOMO that is lower than the energy of the HOMO of the second organic compound. The third organic compound may be a compound having energy of the LUMO that is higher than the energy of the LUMO of the second organic compound or a compound having energy of the LUMO that is lower than the energy of the HOMO of the second organic compound. In one embodiment of the present invention, the third organic compound has energy of the HOMO that is lower than the second organic compound and energy of LUMO that is lower than the second organic compound.

The organic light emitting device using the third organic compound emits fluorescent light derived from the third organic compound. The light emission from the third organic compound generally includes delayed fluorescent light. The largest component of the light emission from the organic light emitting device of the present invention is the light emission from the third organic compound. Therefore, the light emission amount from the third organic compound is the largest in the light emission from the organic light emitting device of the present invention. In the light emission from the organic light emitting device of the present invention, 70% or more thereof may be the light emission from the third organic compound, 90% or more thereof may be the light emission from the third organic compound, or 99% or more thereof may be the light emission from the third organic compound. The third organic compound transitions to the excited singlet state through reception of energy from the first organic compound in the excited singlet state, the second organic compound in the excited singlet state, and the second organic compound that transitions from the excited triplet state to the excited singlet state through reverse intersystem crossing. In a preferred embodiment of the present invention, the third organic compound transitions to the excited singlet state through reception of energy from the second organic compound in the excited singlet state and the second organic compound that transitions from the excited triplet state to the excited singlet state through reverse intersystem crossing. Thereafter, fluorescent light is emitted in returning the occurring excited singlet state of the third organic compound to the ground state.

The fluorescent material used as the third organic compound is not particularly limited, as far as being capable of emitting light through reception of energy from the first organic compound and the second organic compound, and the light emission may include any of fluorescent light, delayed fluorescent light, and phosphorescent light. It is preferred that the light emission includes fluorescent light and delayed fluorescent light, and it is more preferred that the largest component of the light emission from the third organic compound is fluorescent light. In one embodiment of the present invention, the organic light emitting device does not emit phosphorescent light, or the radiation amount of phosphorescent light thereof is 1% or less.

Two or more kinds of the third organic compounds may be used, as far as satisfying the conditions of the present invention. For example, the combination use of two or more kinds of the third organic compounds different in light emission color from each other enables light emission with intended color. One kind of the third organic compound may also be used to achieve monochromatic light emission from the third organic compound.

In the present invention, the maximum light emission wavelength of the compound that can be used as the third organic compound is not particularly limited. Accordingly, a light emitting material having a maximum light emission wavelength in the visible region (380 to 780 nm), a light emitting material having a maximum light emission wavelength in the infrared region (780 nm to 1 mm), a light emitting material having a maximum light emission wavelength in the ultraviolet region (for example, 280 to 380 nm), and the like can be appropriately selected and used. A fluorescent material having a maximum light emission wavelength in the visible region is preferably used. For example, within a range of 380 to 780 nm, a light emitting material having a maximum light emission wavelength in a range of 380 to 570 nm can be selected and used, a light emitting material having a maximum light emission wavelength in a range of 570 to 650 nm can be selected and used, a light emitting material having a maximum light emission wavelength in a range of 650 to 700 nm can be selected and used, and a light emitting material having a maximum light emission wavelength in a range of 700 to 780 nm can be selected and used.

In a preferred embodiment of the present invention, the second organic compound and the third organic compound are selected and combined so that the light emission wavelength region of the second organic compound and the absorption wavelength region of the third organic compound overlap each other. It is particularly preferred that the edge on the short wavelength side of the light emission spectrum of the second organic compound overlaps the edge on the long wavelength side of the absorption spectrum of the third organic compound.

The third organic compound preferably contains no other metal atom than a boron atom. For example, the third organic compound may be a compound that contains both a boron atom and a fluorine atom, may be a compound that contains a boron atom but no fluorine atom, or may be a compound that contains no metal atom. For example, the third organic compound selected may be a compound consisting of atoms selected from the group consisting of a carbon atom, a hydrogen atom, a deuterium atom, a nitrogen atom, an oxygen atom, a sulfur atom, a fluorine atom, and a boron atom. For example, the third organic compound selected may be a compound consisting of atoms selected from the group consisting of a carbon atom, a hydrogen atom, a deuterium atom, a nitrogen atom, an oxygen atom, a fluorine atom, and a boron atom. For example, the third organic compound selected may be a compound consisting of atoms selected from the group consisting of a carbon atom, a hydrogen atom, a deuterium atom, a nitrogen atom, an oxygen atom, a sulfur atom, and a boron atom. For example, the third organic compound selected may be a compound consisting of atoms selected from the group consisting of a carbon atom, a hydrogen atom, a deuterium atom, a nitrogen atom, and a boron atom. For example, the third organic compound selected may be a compound consisting of atoms selected from the group consisting of a carbon atom, a hydrogen atom, a deuterium atom, a nitrogen atom, an oxygen atom, and a sulfur atom. For example, the third organic compound selected may be a compound consisting of atoms selected from the group consisting of a carbon atom, a hydrogen atom, a deuterium atom, a nitrogen atom, and an oxygen atom. For example, the third organic compound selected may be a compound consisting of atoms selected from the group consisting of a carbon atom and a hydrogen atom.

Examples of the third organic compound include a compound having a multiple resonance effect of a boron atom and a nitrogen atom, and a compound including a condensed aromatic cyclic structure, such as anthracene, pyrene, and perylene.

In one preferred embodiment of the present invention, a compound represented by the following general formula (15) is used as the third organic compound.

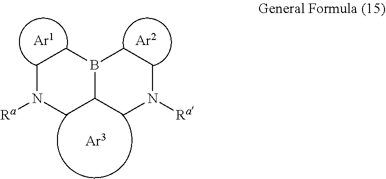

In the general formula (15), Ar¹ to Ar³ each independently represent an aryl ring or a heteroaryl ring, in which at least one hydrogen atom in the ring may be substituted, and a ring may be condensed thereto. In the case where the hydrogen atom is substituted, the hydrogen atom is preferably substituted by one group or a group combining two or more groups selected from the group consisting of a deuterium atom, an aryl group, a heteroaryl group, and an alkyl group. In the case where a ring is condensed thereto, a benzene ring or a heteroaromatic ring (such as a furan ring, a thiophene ring, and a pyrrole ring) is preferably condensed. R^{a} and R^{a′} each independently represent a substituent, and preferably represent one group or a group combining two or more groups selected from the group consisting of a deuterium atom, an aryl group, a heteroaryl group, and an alkyl group. R^{a} and Ar¹, Ar¹ and Ar², Ar² and R^{a′}, R^{a′} and Ar³, and Ar³ and R^{a} each may be bonded to each other to form a cyclic structure.

The compound represented by the general formula (15) preferably includes at least one carbazole structure. For example, one of the benzene rings constituting the carbazole structure may be the ring represented by Ar¹, one of the benzene rings constituting the carbazole structure may be the ring represented by Ar², and one of the benzene rings constituting the carbazole structure may be the ring represented by Ar³. The carbazolyl group may be bonded to one or more of Ar¹ to Ar³. For example, a substituted or unsubstituted carbazol-9-yl group may be bonded to the ring represented by Ar³.

A condensed aromatic cyclic structure, such as anthracene, pyrene, and perylene, may be bonded to Ar¹ to Ar³. Ar¹ to Ar³ may be one ring constituting a condensed aromatic cyclic structure. At least one of R^{a} and R^{a′} may be a group having a condensed aromatic cyclic structure.

The compound may have multiple skeletons each represented by the general formula (15) existing therein. For example, the compound may have a structure including skeletons each represented by the general formula (15) bonded via a single bond or a linking group. The skeleton represented by the general formula (15) may have added thereto a structure showing a multiple resonance effect including benzene rings bonded via a boron atom, a nitrogen atom, an oxygen atom, or a sulfur atom.

In one preferred embodiment of the present invention, a compound including a BODIPY (4,4-difluoro-4-bora-3a,4a-diaza-s-indacene) structure is used as the third organic compound. For example, a compound represented by the following general formula (16) is used.

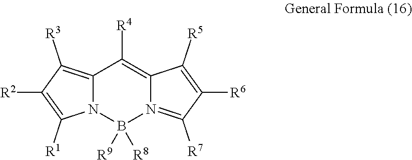

In the general formula (16), R¹ to R⁷ each independently represent a hydrogen atom, a deuterium atom, or a substituent. At least one of R¹ to R⁷ preferably represents a group represented by the following general formula (17).

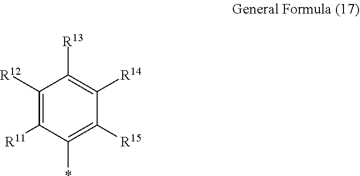

In the general formula (17), R¹¹ to R¹⁵ each independently represent a hydrogen atom, a deuterium atom, or a substituent, and * indicates the bonding position.

The group represented by the general formula (17) may be one of R¹ to R⁷ in the general formula (16), two thereof, or three thereof, and may be at least four thereof, for example, four or five thereof. In one preferred embodiment of the present invention, one of R¹ to R⁷ is the group represented by the general formula (17). In one preferred embodiment of the present invention, at least R¹, R³, R⁵, and R⁷ are the groups represented by the general formula (17). In one preferred embodiment of the present invention, only R¹, R³, R⁴, R⁵, and R⁷ are the groups represented by the general formula (17). In one preferred embodiment of the present invention, R¹, R³, R⁴, R⁵, and R⁷ are the groups represented by the general formula (17), and R² and R⁴ are a hydrogen atom, a deuterium atom, an unsubstituted alkyl group (for example, having 1 to 10 carbon atoms), or an unsubstituted aryl group (for example, having 6 to 14 carbon atoms). In one embodiment of the present invention, all R¹ to R⁷ are the groups represented by the general formula (17).

In one preferred embodiment of the present invention, R¹ and R⁷ are the same as each other. In one preferred embodiment of the present invention, R³ and R⁵ are the same as each other. In one preferred embodiment of the present invention, R² and R⁶ are the same as each other. In one preferred embodiment of the present invention, R¹ and R⁷ are the same as each other, R³ and R⁵ are the same as each other, and R¹ and R³ are different from each other. In one preferred embodiment of the present invention, R¹, R³, R⁵, and R⁷ are the same as each other. In one preferred embodiment of the present invention, R¹, R⁴, and R⁷ are the same as each other, which are different from R³ and R⁵. In one preferred embodiment of the present invention, R³, R⁴, and R⁵ are the same as each other, which are different from R¹ and R⁷. In one preferred embodiment of the present invention, R¹, R³, R⁵, and R⁷ are different from R⁴.

For example, the substituent that R¹¹ to R¹⁵ in the general formula (17) can represent can be selected from the substituent group A described later, can be selected from the substituent group B described later, can be selected from the substituent group C described later, or can be selected from the substituent group D described later. In the case where a substituted amino group is selected as the substituent, a di-substituted amino group is preferred, in which two substituent on the amino group each independently are preferably a substituted or unsubstituted aryl group, a substituted or unsubstituted heteroaryl group, or a substituted or unsubstituted alkyl group, and particularly preferably a substituted or unsubstituted aryl group (i.e., forming a diarylamino group). For example, the substituent that the two aryl groups of the diarylamino group can have can be selected from the substituent group A described later, can be selected from the substituent group B described later, can be selected from the substituent group C described later, or can be selected from the substituent group D described later. The two aryl groups of the diarylamino group may be bonded via a single bond or a linking group, and for the description of the linking group herein, reference may be made to the description for the linking group represented by R³³ and R³⁴. Specific examples of the diarylamino group include a substituted or unsubstituted carbazol-9-yl group. Examples of the substituted or unsubstituted carbazol-9-yl group include a group represented by the general formula (9), wherein L¹¹ represents a single bond.

In one preferred embodiment of the present invention, in the general formula (17), only R¹³ is a substituent, and R¹¹, R¹², R¹⁴, and R¹⁵ are hydrogen atoms. In one preferred embodiment of the present invention, in the general formula (17), only R¹¹ is a substituent, and R¹², R¹³, R¹⁴, and R¹⁵ are hydrogen atoms. In one preferred embodiment of the present invention, in the general formula (17), only R¹¹ and R¹³ are substituents, and R¹², R¹⁴, and R¹⁵ are hydrogen atoms.

R¹ to R⁷ in the general formula (16) each may include a group represented by the general formula (17), wherein all R¹¹ to R¹⁵ are hydrogen atoms (i.e., a phenyl group). For example, R², R⁴, and R⁶ each may be a phenyl group.

In the general formula (16), R⁸ and R⁹ each independently preferably represent one group or a group combining two or more groups selected from the group consisting of a hydrogen atom, a deuterium atom, a halogen atom, an alkyl group (for example, having 1 to 40 carbon atoms), an alkoxy group (for example, having 1 to 40 carbon atoms), an aryloxy group (for example, having 6 to 30 carbon atoms), and a cyano group. In a preferred embodiment of the present invention, R⁸ and R⁹ are the same as each other. In a preferred embodiment of the present invention, R⁸ and R⁹ each represent a halogen atom, and particularly preferably a fluorine atom.

In one embodiment of the present invention, the total number of the substituted or unsubstituted alkoxy group, the substituted or unsubstituted aryloxy group, and the substituted or unsubstituted amino group existing in R¹ to R⁹ in the general formula (16) is preferably 3 or more, and for example, a compound having the number of 3 or a compound having the number of 4 may be used. In one more preferred embodiment, the total number of the substituted or unsubstituted alkoxy group, the substituted or unsubstituted aryloxy group, and the substituted or unsubstituted amino group existing in R¹ to R⁷ in the general formula (16) is preferably 3 or more, and for example, a compound having the number of 3 or a compound having the number of 4 may be used. In this case, an alkoxy group, an aryloxy group, and an amino group may not exist in R⁸ and R⁹. In one further preferred embodiment, the total number of the substituted or unsubstituted alkoxy group, the substituted or unsubstituted aryloxy group, and the substituted or unsubstituted amino group existing in R¹, R³, R⁴, R⁵, and R⁷ in the general formula (16) is preferably 3 or more, and for example, a compound having the number of 3 or a compound having the number of 4 may be used. In this case, an alkoxy group, an aryloxy group, and an amino group may not exist in R², R⁶, R⁸, and R⁹. In one preferred embodiment of the present invention, 3 or more substituted or unsubstituted alkoxy groups exist. In one preferred embodiment of the present invention, 4 or more substituted or unsubstituted alkoxy groups exist. In one preferred embodiment of the present invention, 1 or more substituted or unsubstituted alkoxy group and two or more substituted or unsubstituted aryloxy groups exist. In one preferred embodiment of the present invention, 2 or more substituted or unsubstituted alkoxy groups and one or more substituted or unsubstituted amino group exist. In one preferred embodiment of the present invention, a substituted or unsubstituted alkoxy group or a substituted or unsubstituted aryloxy group exists in each of R¹, R⁴, and R⁷. In one preferred embodiment of the present invention, a substituted or unsubstituted alkoxy group exists in each of R¹, R⁴, and R⁷.

In one embodiment of the present invention, the total number of the substituent that has a Hammett's σₚ value of less than −0.2 existing in R¹ to R⁹ in the general formula (16) is 3 or more. Examples of the substituent that has a Hammett's σₚ value of less than −0.2 include a methoxy group (−0.27), an ethoxy group (−0.24), a n-propoxy group (−0.25), an isopropoxy group (−0.45), and an n-butoxy group (−0.32). A fluorine atom (0.06), a methyl group (−0.17), an ethyl group (−0.15), a tert-butyl group (−0.20), a n-hexyl group (−0.15), a cyclohexyl group (−0.15), and the like are not the substituent that has a Hammett's σₚ value of less than −0.2.

In one embodiment of the present invention, a compound having 3 of substituents that have a Hammett's σₚ value of less than −0.2 existing in R¹ to R⁹ in the general formula (16) may be used, or a compound having 4 thereof may be used. In one more preferred embodiment, the total number of the substituent that has a Hammett's σₚ value of less than −0.2 existing in R¹ to R⁷ in the general formula (16) is 3 or more, and for example, a compound having 3 thereof may be used, or a compound having 4 thereof may be used. In this case, the substituent that has a Hammett's σₚ value of less than −0.2 may not exist in R⁸ and R⁹. In one further preferred embodiment, the total number of the substituent that has a Hammett's σₚ value of less than −0.2 existing in R¹, R³, R⁴, R⁵, and R⁷ in the general formula (16) is 3 or more, and for example, a compound having 3 thereof may be used, or a compound having 4 thereof may be used. In this case, the substituent that has a Hammett's σₚ value of less than −0.2 may not exist in R², R⁶, R⁸, and R⁹. In a preferred embodiment of the present invention, the substituent that has a Hammett's σₚ value of less than −0.2 exists in each of R¹, R⁴, and R⁷.

In the present invention, a compound including a carbazole structure may be selected as the third organic compound. A compound that does not include any of a carbazole structure, a dibenzofuran structure, and a dibenzothiophene structure may also be selected as the third organic compound.

Preferred examples of the compound that can be used as the third organic compound are shown below. In the following structural formulae of the example compounds, t-Bu represents a tert-butyl group.

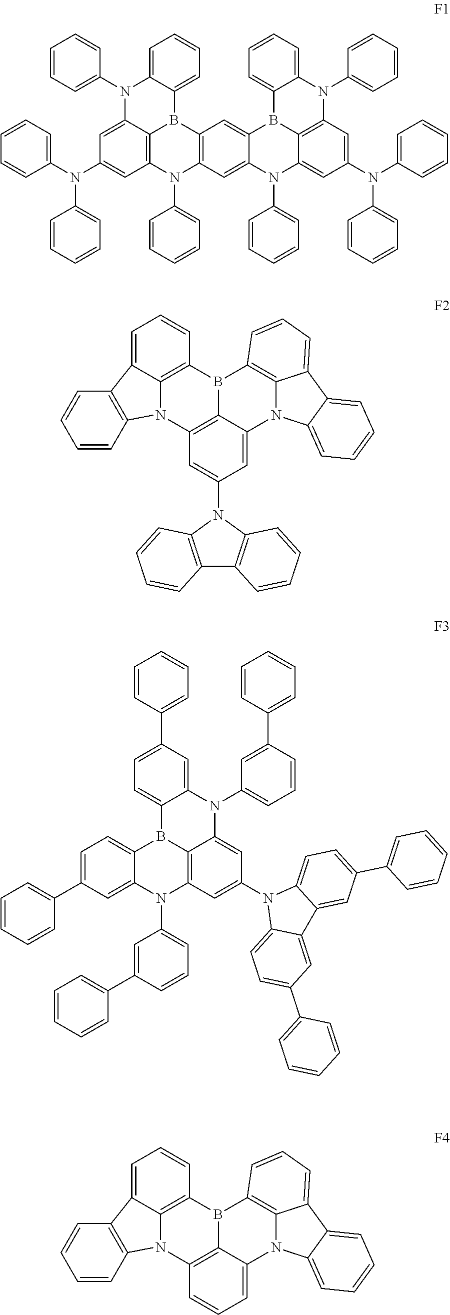 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1 ; c1ccc2c(c1)c1ccccc1n2-c1cc2c3c(c1)-n1c4ccccc4c4cccc(c41)B3c1cccc3c4ccccc4n-2c13 ; c1ccc(-c2cccc(N3c4cc(-c5ccccc5)ccc4B4c5ccc(-c6ccccc6)cc5N(c5cccc(-c6ccccc6)c5)c5cc(-n6c7ccc(-c8ccccc8)cc7c7cc(-c8ccccc8)ccc76)cc3c54)c2)cc1 ; c1cc2c3c(c1)-n1c4ccccc4c4cccc(c41)B3c1cccc3c4ccccc4n-2c13]

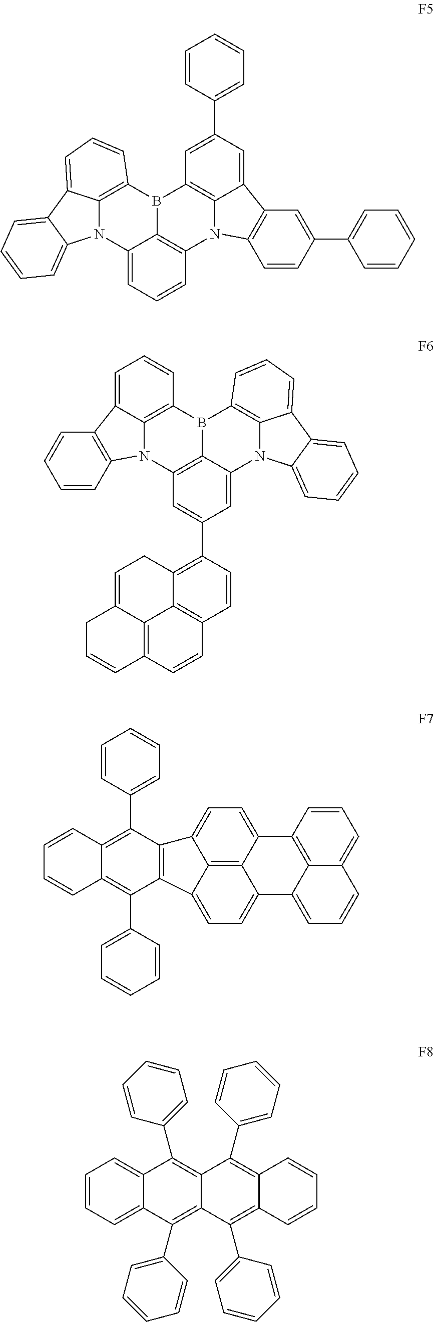

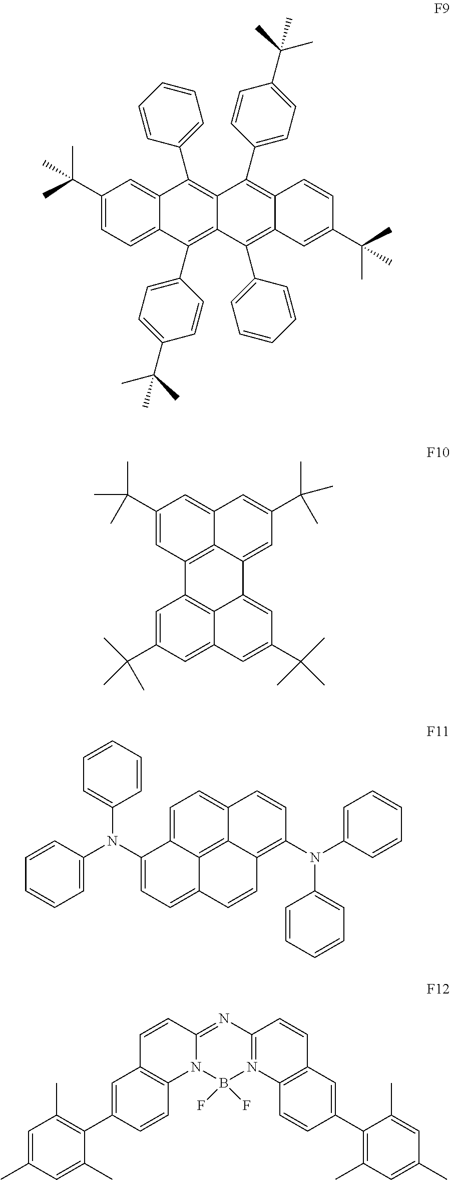

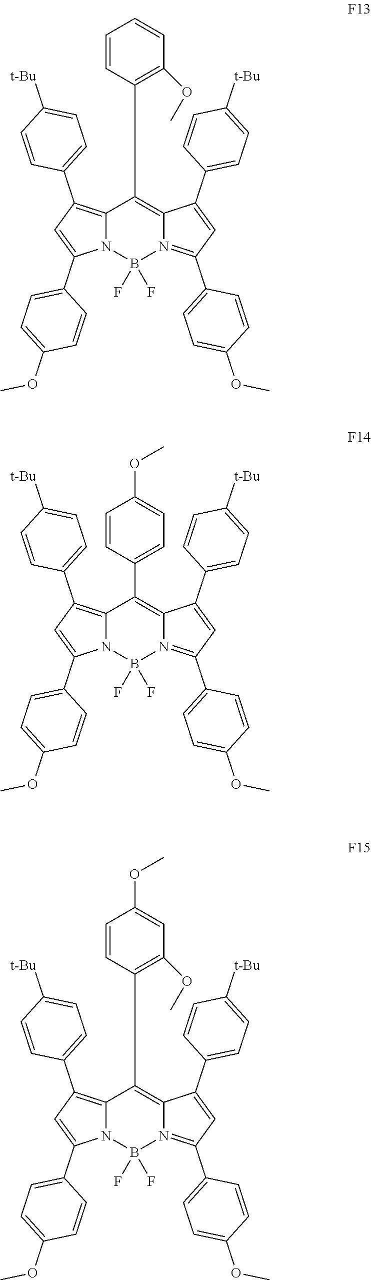

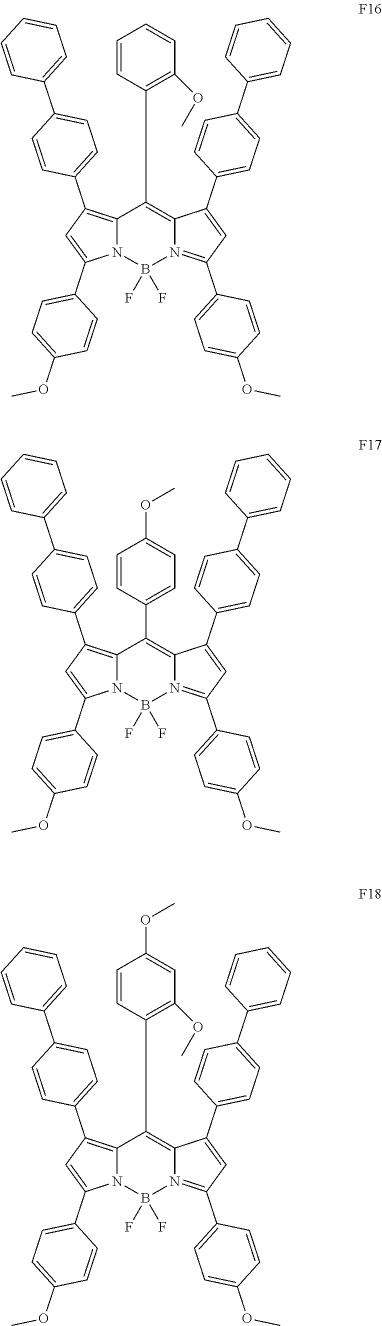

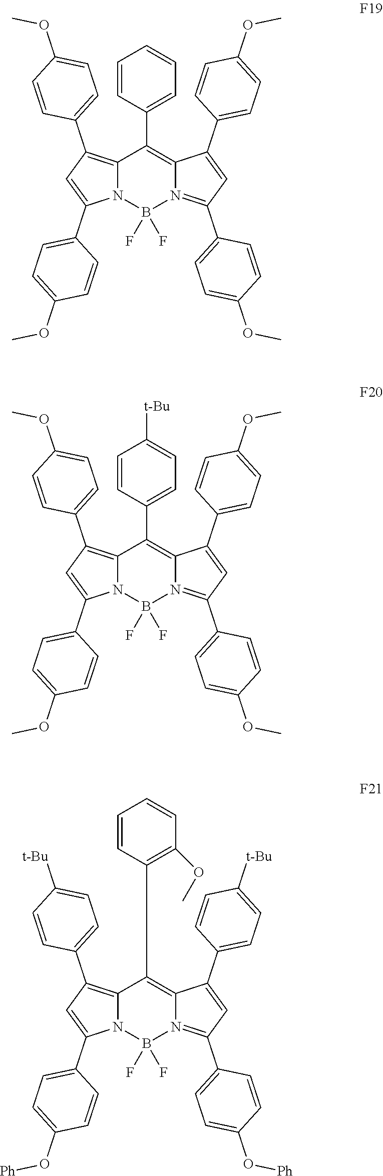

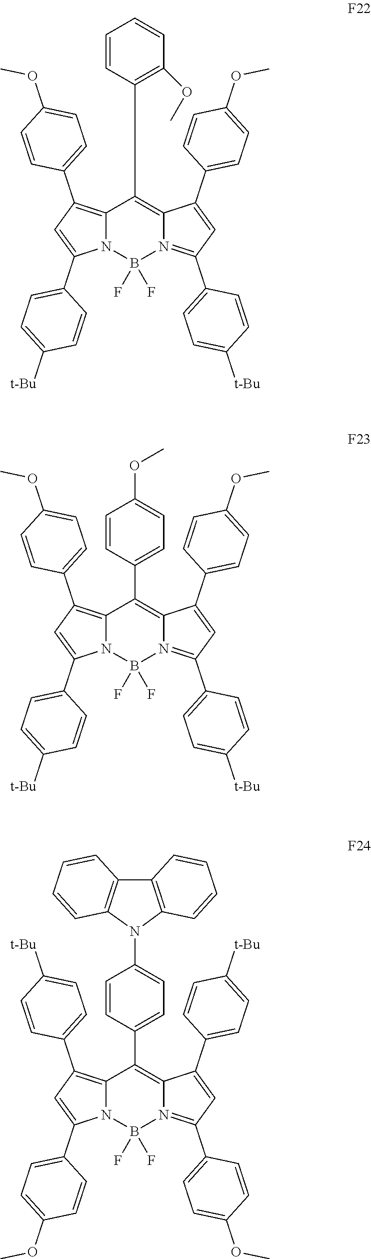

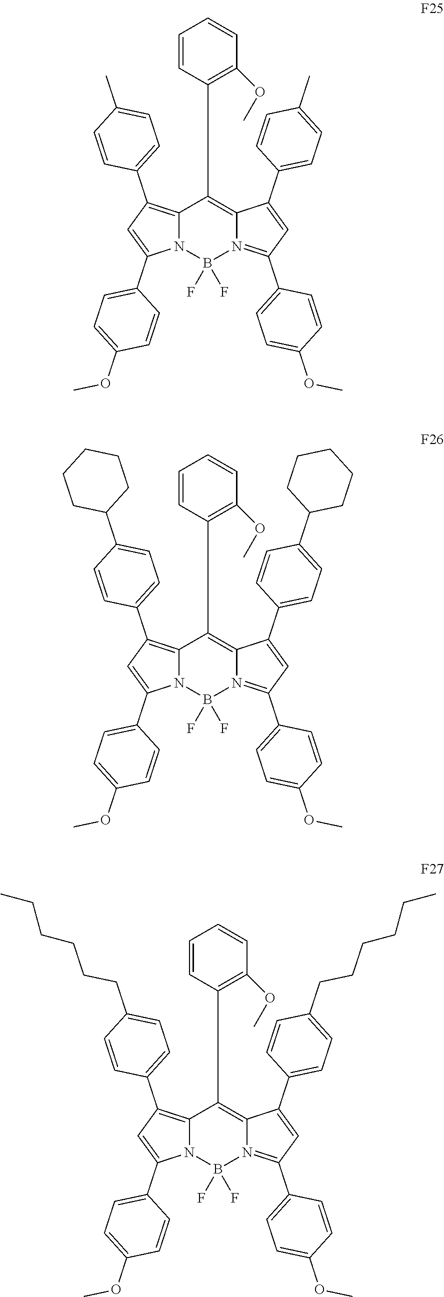

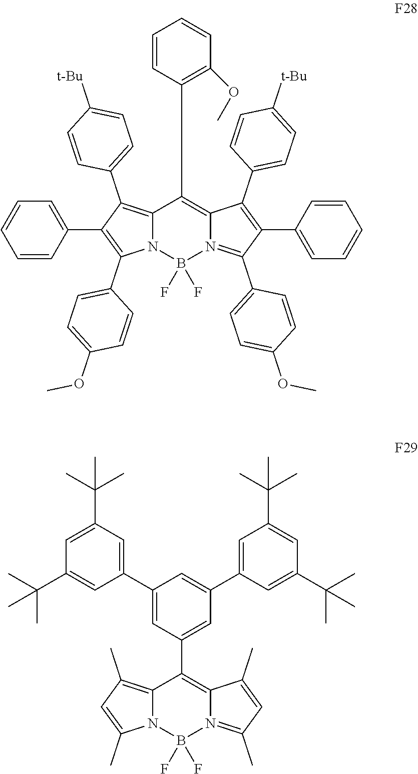

Examples of derivatives of the example compounds include compounds obtained by substituting at least one hydrogen atom by a deuterium atom, an alkyl group, an aryl group, a heteroaryl group, or a diarylamino group.

The compounds described in WO 2015/022974, paragraphs 0220 to 0239 can also particularly preferably used as the third organic compound in the present invention.

Here, “alkyl group” can be linear, branched or cyclic. Two or more of a linear moiety, a cyclic moiety and a branched moiety can be in the group as mixed. The carbon number of the alkyl group can be, for example, 1 or more, 2 or more, or 4 or more. The carbon number can also be 30 or less, 20 or less, 10 or less, 6 or less, or 4 or less. Specific examples of the alkyl group include a methyl group, an ethyl group, an n-propyl group, an isopropyl group, an n-butyl group, an isobutyl group, a tert-butyl group, an n-pentyl group, an isopentyl group, an n-hexyl group, an isohexyl group, a 2-ethylhexyl group, an n-heptyl group, an isoheptyl group, an n-octyl group, an isooctyl group, an n-nonyl group, an isononyl group, an n-decanyl group, an isodecanyl group, a cyclopentyl group, a cyclohexyl group, and a cycloheptyl group. The alkyl group of a substituent can be further substituted with an aryl group.

“Alkenyl group” can be linear, branched or cyclic. Two or more of a linear moiety, a cyclic moiety and a branched moiety can be in the group as mixed. The carbon number of the alkyl group can be, for example, 2 or more, or 4 or more. The carbon number can also be 30 or less, 20 or less, 10 or less, 6 or less, or 4 or less. Specific examples of the alkenyl group include an ethenyl group, an n-propenyl group, an isopropenyl group, an n-butenyl group, an isobutenyl group, an n-pentenyl group, an isopentenyl group, an n-hexenyl group, an isohexenyl group, and a 2-ethylhexenyl group. The alkenyl group to be a substituent can be further substituted with an aryl group.

The “aryl group” and the “heteroaryl group” each may be a monocyclic ring or a condensed ring including two or more rings condensed. The number of rings condensed to form the condensed ring is preferably 2 to 6, and may be selected, for example, from 2 to 4. Specific examples of the ring include a benzene ring, a pyridine ring, a pyrimidine ring, a triazine ring, a napthalene ring, an anthracene ring, a phenanthrene ring, a triphenylene ring, a quinoline ring, a pyrazine ring, a quinoxaline ring, and a naphthyridine ring. Specific examples of the aryl group and the heteroaryl group include a phenyl group, a 1-naphtyl group, a 2-naphthyl group, a 1-anthracenyl group, a 2-anthracenyl group, a 9-anthracenyl group, a 2-pyridyl group, a 3-pyridyl group, and a 4-pyridyl group. The “arylene group” and the “heteroarylene group” may be groups obtained by changing the valence of the groups described for the aryl group and the heteroaryl group from 1 to 2.

In the description herein, the “substituent group A” means one group or a group combining two or more groups selected from the group consisting of a hydroxy group, a halogen atom (such as a fluorine atom, a chlorine atom, a bromine atom, and an iodine atom), an alkyl group (for example, having 1 to 40 carbon atoms), an alkoxy group (for example, having 1 to 40 carbon atoms), an alkylthio group (for example, having 1 to 40 carbon atoms), an aryl group (for example, having 6 to 30 carbon atoms), an aryloxy group (for example, having 6 to 30 carbon atoms), an arylthio group (for example, having 6 to 30 carbon atoms), a heteroaryl group (for example, having 5 to 30 ring skeleton-forming carbon atoms), a heteroaryloxy group (for example, having 5 to 30 ring skeleton-forming carbon atoms), a heteroarylthio group (for example, having 5 to 30 ring skeleton-forming carbon atoms), an acyl group (for example, having 1 to 40 carbon atoms), an alkenyl group (for example, having 1 to 40 carbon atoms), an alkynyl group (for example, having 1 to 40 carbon atoms), an alkoxycarbonyl group (for example, having 1 to 40 carbon atoms), an aryloxycarbonyl group (for example, having 1 to 40 carbon atoms), a heteroaryloxycarbonyl group (for example, having 1 to 40 carbon atoms), a silyl group (for example, a trialkylsilyl group having 1 to 40 carbon atoms), and a nitro group.

In the description herein, the “substituent group B” means one group or a group combining two or more groups selected from the group consisting of an alkyl group (for example, having 1 to 40 carbon atoms), an alkoxy group (for example, having 1 to 40 carbon atoms), an aryl group (for example, having 6 to 30 carbon atoms), an aryloxy group (for example, having 6 to 30 carbon atoms), a heteroaryl group (for example, having 5 to 30 ring skeleton-forming carbon atoms), a heteroaryloxy group (for example, having 5 to 30 ring skeleton-forming carbon atoms), and a diarylamino group (for example, having 0 to 20 carbon atoms).

In the description herein, the “substituent group C” means one group or a group combining two or more groups selected from the group consisting of an alkyl group (for example, having 1 to 20 carbon atoms), an aryl group (for example, having 6 to 22 carbon atoms), a heteroaryl group (for example, having 5 to 20 ring skeleton-forming carbon atoms), and a diarylamino group (for example, having 12 to 20 carbon atoms).

In the description herein, the “substituent group D” means one group or a group combining two or more groups selected from the group consisting of an alkyl group (for example, having 1 to 20 carbon atoms), an aryl group (for example, having 6 to 22 carbon atoms), and a heteroaryl group (for example, having 5 to 20 ring skeleton-forming carbon atoms).

### (Light Emitting Layer)

The light emitting layer of the organic light emitting device of the present invention contains the first organic compound and the second organic compound. The light emitting layer may contain the third organic compound in addition to the first organic compound and the second organic compound. The light emitting layer may have a configuration that does not contain a compound donating or receiving charge or energy or a metal element other than boron, in addition to these compounds. The light emitting layer may be constituted only by a compound or compounds consisting of atoms selected from the group consisting of a carbon atom, a hydrogen atom, a deuterium atom, a nitrogen atom, a boron atom, a fluorine atom, an oxygen atom, and a sulfur atom. For example, the light emitting layer may be constituted only by a compound or compounds consisting of atoms selected from the group consisting of a carbon atom, a hydrogen atom, a deuterium atom, a nitrogen atom, a boron atom, a fluorine atom, and an oxygen atom. For example, the light emitting layer may be constituted only by a compound or compounds consisting of atoms selected from the group consisting of a carbon atom, a hydrogen atom, a deuterium atom, a nitrogen atom, a boron atom, a fluorine atom, and a sulfur atom. For example, the light emitting layer may be constituted only by a compound or compounds consisting of atoms selected from the group consisting of a carbon atom, a hydrogen atom, a deuterium atom, a nitrogen atom, and a boron atom. For example, the light emitting layer may be constituted only by a compound or compounds consisting of atoms selected from the group consisting of a carbon atom, a hydrogen atom, a deuterium atom, a nitrogen atom, an oxygen atom, and a sulfur atom. For example, the light emitting layer may be constituted only by a compound or compounds consisting of atoms selected from the group consisting of a carbon atom, a hydrogen atom, a deuterium atom, and a nitrogen atom. The light emitting layer may include the first organic compound constituted by atoms selected from the group consisting of a carbon atom, a hydrogen atom, a nitrogen atom, an oxygen atom, and a sulfur atom, the second organic compound constituted by atoms selected from the group consisting of a carbon atom, a hydrogen atom, a deuterium atom, a nitrogen atom, an oxygen atom, and a sulfur atom, the third organic compound constituted by atoms selected from the group consisting of a carbon atom, a hydrogen atom, a deuterium atom, a nitrogen atom, a boron atom, a fluorine atom, an oxygen atom, and a sulfur atom. The light emitting layer may include the first organic compound constituted by atoms selected from the group consisting of a carbon atom, a hydrogen atom, a nitrogen atom, and an oxygen atom, the second organic compound constituted by atoms selected from the group consisting of a carbon atom, a hydrogen atom, a deuterium atom, and a nitrogen atom, and the third organic compound constituted by atoms selected from the group consisting of a carbon atom, a hydrogen atom, a deuterium atom, a nitrogen atom, and a boron atom.

The light emitting layer may be formed through vapor co-deposition of the first organic compound, the second organic compound, and optionally the third organic compound, or may be formed by a coating method using a solution having the first organic compound, the second organic compound, and optionally the third organic compound dissolved therein. In the formation of the light emitting layer through vapor co-deposition of the first organic compound, the second organic compound, and the third organic compound, it is possible that two or more of the first organic compound, the second organic compound, and the third organic compound are mixed in advance and the placed as a vapor deposition source in a crucible, and the light emitting layer is formed through vapor co-deposition with the vapor deposition source. For example, it is possible that the first organic compound and the second organic compound are mixed in advance to form a single vapor deposition source, and the light emitting layer is formed through vapor co-deposition using the vapor deposition source and the third organic compound as another vapor deposition source.

### (Layer Configuration of Organic Light Emitting Device)

The organic light emitting device of the present invention includes the base layer and the light emitting layer laminated on the surface of the base layer.

For example, the thickness of the light emitting layer may be 5 nm or more, may be 10 nm or more, may be 20 nm or more, or may be 40 nm or more, and may be 80 nm or less, or may be 60 nm or less.

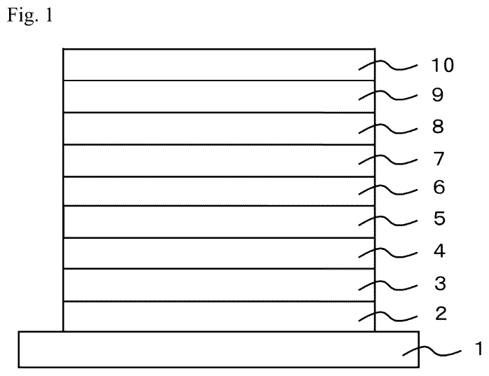

Examples of the organic light emitting device of the present invention include an organic photoluminescent device (organic PL device) and an organic electroluminescent device (organic EL device). The organic photoluminescent device has a structure including a substrate having thereon a base layer and a light emitting layer laminated on the surface of the base layer. The organic electroluminescent device has a structure including at least an anode, a cathode, and an organic layer formed between the anode and the cathode. The organic layer includes at least a base layer and a light emitting layer laminated on the surface of the base layer, may include only the base layer and the light emitting layer adjacent thereto, or may include one or more layer of an organic layer in addition to the base layer and the light emitting layer adjacent thereto. Examples of the organic layer other than the light emitting layer include a hole transporting layer, a hole injection layer, an electron barrier layer, a hole barrier layer, an electron injection layer, an electron transporting layer, and an exciton barrier layer. The hole transporting layer may be a hole injection transporting layer having a hole injection function, and the electron transporting layer may be an electron injection transporting layer having an electron injection function. The present invention has a structure including the light emitting layer laminated on the surface of the base layer on the cathode side. The base layer may also function as an electron barrier layer. A specific example of the structure of the organic electroluminescent device is shown in FIG. 1. In FIG. 1, numeral 1 denotes a glass substrate, 2 denotes an anode, 3 denotes a hole injection layer, 4 denotes a hole transporting layer, 5 denotes a base layer, 6 denotes a light emitting layer, 7 denotes a hole barrier layer, 8 denotes an electron transporting layer, 9 denotes an electron injection layer, and 10 denotes a cathode.

In the case where the organic light emitting device of the present invention is a multi-wavelength emission type organic light emitting device, the light emission of the shortest wavelength may contain delayed fluorescent light, or the light emission of the shortest wavelength may not contain delayed fluorescent light.

### (Production Method of Organic Light Emitting Device)

The organic light emitting device of the present invention can be produced by laminating the light emitting layer on the surface of the base layer. For example, in the case where the organic electroluminescent device is produced by laminating the organic layer on the anode, it is possible that the base layer containing the compound represented by the general formula (1) is formed on the anode or the organic layer formed on the anode, and the light emitting layer containing the first organic compound and the second organic compound is formed to laminate on the base layer.

The formation method of the base layer and the light emitting layer is not particularly limited. Examples of the preferred formation method include a vapor deposition method. The layers may also be formed by a coating method. The base layer and the light emitting layer adjacent to each other may be formed continuously, or may be formed intermittently. The layers are preferably formed continuously.

The organic light emitting device of the present invention can be easily produced by using an ordinary production line (production equipment) of an organic light emitting device. Specifically, in the ordinary production line, the organic light emitting device of the present invention can be conveniently produced only by changing the material used for forming the base layer to the compound represented by the general formula (1), and allowing the material used for forming the light emitting layer to contain the first organic compound and the second organic compound. Therefore, the organic light emitting device of the present invention has an advantage that the device can be produced without changing or newly building a production line itself. Furthermore, after producing the organic light emitting device of the present invention, the materials used may be changed to restore the production line for other organic light emitting devices than the present invention. Consequently, the organic light emitting device of the present invention has a high industrial applicability since the production thereof and the diversion of the production equipment therefor can be performed in a short time with high economical efficiency.

In the production of the organic light emitting device of the present invention, the structures and the formation methods of the other layers are not particularly limited, as far as forming the base layer and the light emitting layer satisfying the conditions of the present invention. For example, the production method may further include a step of forming an electrode, such as an anode and a cathode, and may further include a step of forming other layers than the base layer and the light emitting layer. In the case where the production method of the present invention is applied, for example, to the production of an organic electroluminescent device, the steps can be performed in such a manner that one or more layers of organic layers are formed sequentially on an anode, the base layer is formed thereon, the light emitting layer is formed thereon, one or more layers of organic layers are formed thereon, and a cathode is formed thereon. Modifications and additions that are apparent to a skilled person in the art may be applied thereto.

In the following, the constituent members and the other layers than the light emitting layer of the organic electroluminescent device are described.

### Substrate:

In some embodiments, the organic electroluminescent device of the invention is supported by a substrate, wherein the substrate is not particularly limited and may be any of those that have been commonly used in an organic electroluminescent device, for example those formed of glass, transparent plastics, quartz, and silicon.

### Anode

In some embodiments, the anode of the organic electroluminescent device is made of a metal, an alloy, an electroconductive compound, or a combination thereof. In some embodiments, the metal, alloy, or electroconductive compound has a large work function (4 eV or more). In some embodiments, the metal is Au. In some embodiments, the electroconductive transparent material is selected from CuI, indium tin oxide (ITO), SnO₂, and ZnO. In some embodiments, an amorphous material capable of forming a transparent electroconductive film, such as IDIXO (In₂O₃—ZnO), is be used. In some embodiments, the anode is a thin film. In some embodiments the thin film is made by vapor deposition or sputtering. In some embodiments, the film is patterned by a photolithography method. In some embodiments, where the pattern may not require high accuracy (for example, approximately 100 μm or more), the pattern may be formed with a mask having a desired shape on vapor deposition or sputtering of the electrode material. In some embodiments, when a material can be applied as a coating, such as an organic electroconductive compound, a wet film forming method, such as a printing method and a coating method is used. In some embodiments, when the emitted light goes through the anode, the anode has a transmittance of more than 10%, and the anode has a sheet resistance of several hundred Ohm per square or less. In some embodiments, the thickness of the anode is from 10 to 1,000 nm. In some embodiments, the thickness of the anode is from 10 to 200 nm. In some embodiments, the thickness of the anode varies depending on the material used.

### Cathode

In some embodiments, the cathode is made of an electrode material a metal having a small work function (4 eV or less) (referred to as an electron injection metal), an alloy, an electroconductive compound, or a combination thereof. In some embodiments, the electrode material is selected from sodium, a sodium-potassium alloy, magnesium, lithium, a magnesium-cupper mixture, a magnesium-silver mixture, a magnesium-aluminum mixture, a magnesium-indium mixture, an aluminum-aluminum oxide (Al₂O₃) mixture, indium, a lithium-aluminum mixture, and a rare earth metal. In some embodiments, a mixture of an electron injection metal and a second metal that is a stable metal having a larger work function than the electron injection metal is used. In some embodiments, the mixture is selected from a magnesium-silver mixture, a magnesium-aluminum mixture, a magnesium-indium mixture, an aluminum-aluminum oxide (Al₂O₃) mixture, a lithium-aluminum mixture, and aluminum. In some embodiments, the mixture increases the electron injection property and the durability against oxidation. In some embodiments, the cathode is produced by forming the electrode material into a thin film by vapor deposition or sputtering. In some embodiments, the cathode has a sheet resistance of several hundred Ohm per square or less. In some embodiments, the thickness of the cathode ranges from 10 nm to 5 μm. In some embodiments, the thickness of the cathode ranges from 50 to 200 nm. In some embodiments, for transmitting the emitted light, any one of the anode and the cathode of the organic electroluminescent device is transparent or translucent. In some embodiments, the transparent or translucent electroluminescent devices enhances the light emission luminance.

In some embodiments, the cathode is formed with an electroconductive transparent material, as described for the anode, to form a transparent or translucent cathode. In some embodiments, a device comprises an anode and a cathode, both being transparent or translucent.

### Injection Layer

An injection layer is a layer between the electrode and the organic layer. In some embodiments, the injection layer decreases the driving voltage and enhances the light emission luminance. In some embodiments the injection layer includes a hole injection layer and an electron injection layer. The injection layer can be positioned between the anode and the light-emitting layer or the hole transporting layer, and between the cathode and the light-emitting layer or the electron transporting layer. In some embodiments, an injection layer is present. In some embodiments, no injection layer is present.

Preferred compound examples for use as a hole injection material are shown below.

### MoO₃,

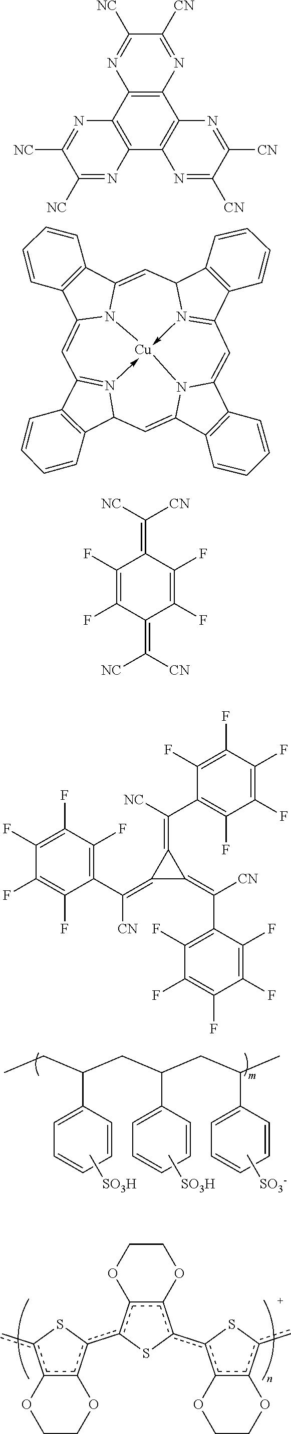

Next, preferred compound examples for use as an electron injection material are shown below.

### LiF, CsF,

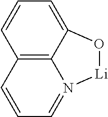

### Barrier Layer

A barrier layer is a layer capable of inhibiting charges (electrons or holes) and/or excitons present in the light-emitting layer from being diffused outside the light-emitting layer. In some embodiments, the electron barrier layer is between the light-emitting layer and the hole transporting layer, and inhibits electrons from passing through the light-emitting layer toward the hole transporting layer. In some embodiments, the hole barrier layer is between the light-emitting layer and the electron transporting layer, and inhibits holes from passing through the light-emitting layer toward the electron transporting layer. In some embodiments, the barrier layer inhibits excitons from being diffused outside the light-emitting layer. In some embodiments, the electron barrier layer and the hole barrier layer are exciton barrier layers. As used herein, the term “electron barrier layer” or “exciton barrier layer” includes a layer that has the functions of both electron barrier layer and of an exciton barrier layer.

### Hole Barrier Layer

A hole barrier layer acts as an electron transporting layer. In some embodiments, the hole barrier layer inhibits holes from reaching the electron transporting layer while transporting electrons. In some embodiments, the hole barrier layer enhances the recombination probability of electrons and holes in the light-emitting layer. The material for the hole barrier layer may be the same materials as the ones described for the electron transporting layer.

Preferred compound examples for use for the hole barrier layer are shown below.

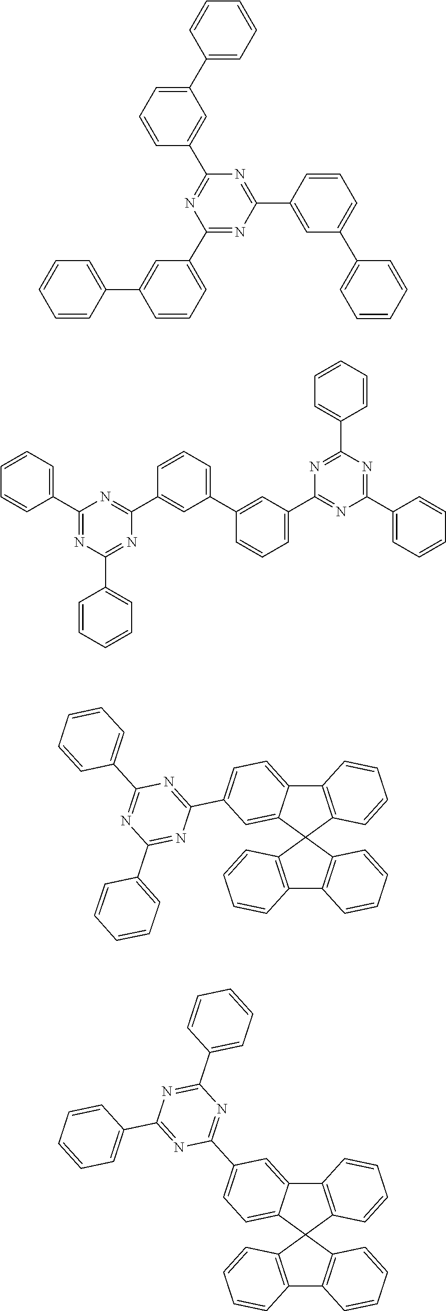

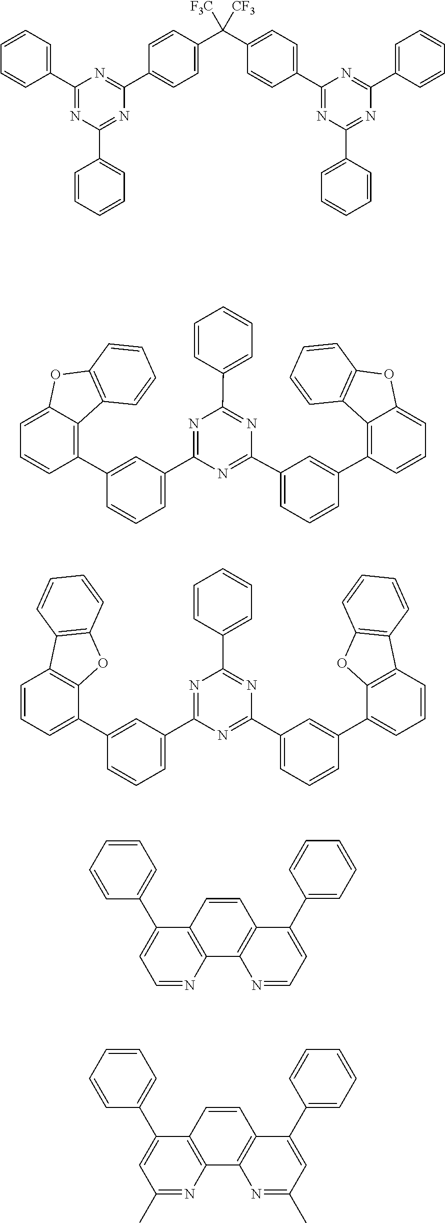 [SMILES: FC(F)(F)C(c1ccc(-c2nc(-c3ccccc3)nc(-c3ccccc3)n2)cc1)(c1ccc(-c2nc(-c3ccccc3)nc(-c3ccccc3)n2)cc1)C(F)(F)F ; c1ccc(-c2nc(-c3cccc(-c4cccc5oc6ccccc6c45)c3)nc(-c3cccc(-c4cccc5oc6ccccc6c45)c3)n2)cc1 ; c1ccc(-c2nc(-c3cccc(-c4cccc5c4oc4ccccc45)c3)nc(-c3cccc(-c4cccc5c4oc4ccccc45)c3)n2)cc1 ; c1ccc(-c2ccnc3c2ccc2c(-c4ccccc4)ccnc23)cc1 ; Cc1cc(-c2ccccc2)c2ccc3c(-c4ccccc4)cc(C)nc3c2n1]

### Electron Barrier Layer

As electron barrier layer transports holes. In some embodiments, the electron barrier layer inhibits electrons from reaching the hole transporting layer while transporting holes. In some embodiments, the electron barrier layer enhances the recombination probability of electrons and holes in the light-emitting layer. The material used for the electron barrier layer may be the same materials as the ones mentioned above for the hole transporting layer.

Preferred compound examples for use as the electron barrier material are shown below.

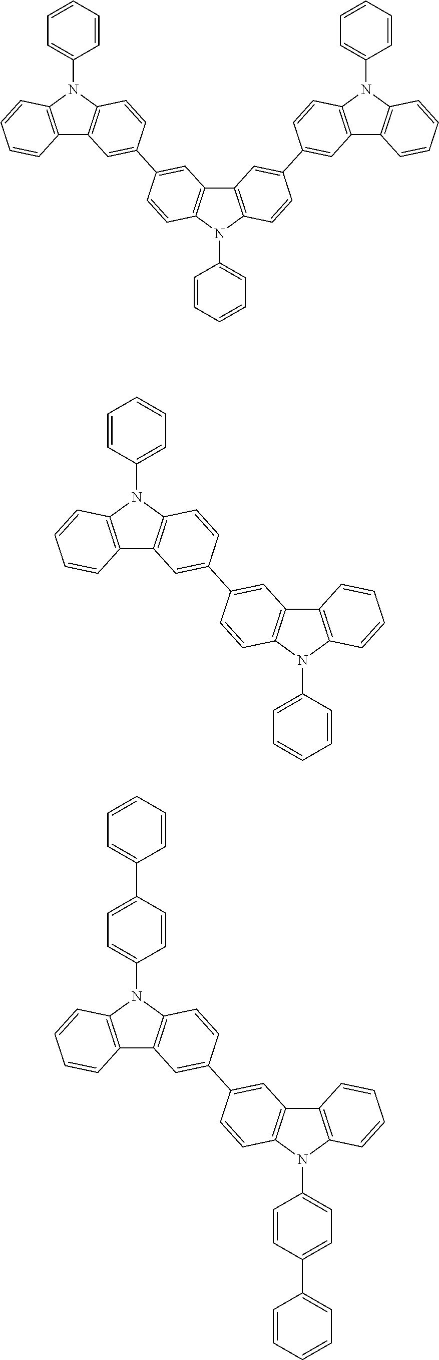 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-n2c3ccccc3c3cc(-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

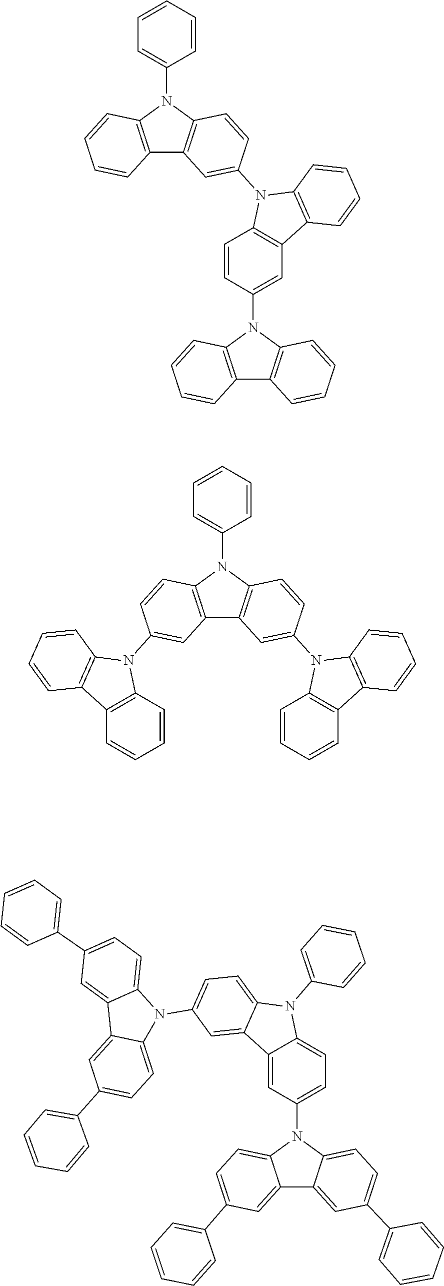 [SMILES: c1ccc(-n2c3ccccc3c3cc(-n4c5ccccc5c5cc(-n6c7ccccc7c7ccccc76)ccc54)ccc32)cc1 ; c1ccc(-n2c3ccc(-n4c5ccccc5c5ccccc54)cc3c3cc(-n4c5ccccc5c5ccccc54)ccc32)cc1 ; c1ccc(-c2ccc3c(c2)c2cc(-c4ccccc4)ccc2n3-c2ccc3c(c2)c2cc(-n4c5ccc(-c6ccccc6)cc5c5cc(-c6ccccc6)ccc54)ccc2n3-c2ccccc2)cc1]

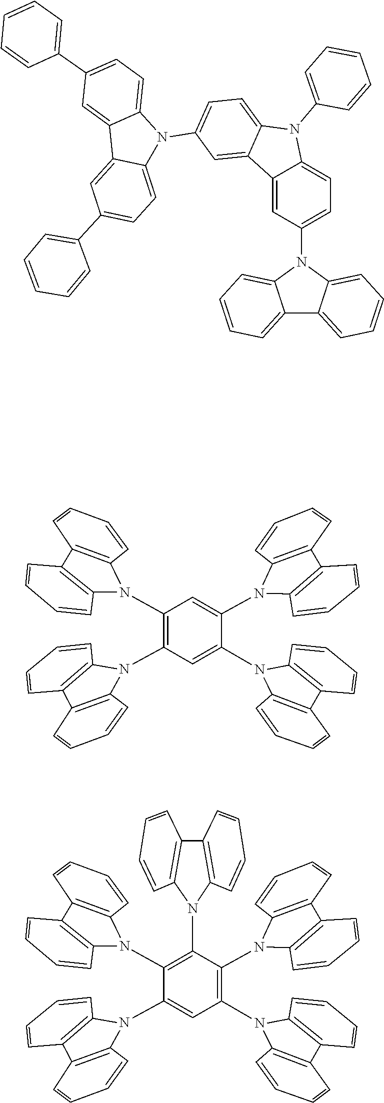 [SMILES: c1ccc(-c2ccc3c(c2)c2cc(-c4ccccc4)ccc2n3-c2ccc3c(c2)c2cc(-n4c5ccccc5c5ccccc54)ccc2n3-c2ccccc2)cc1 ; c1ccc2c(c1)c1ccccc1n2-c1cc(-n2c3ccccc3c3ccccc32)c(-n2c3ccccc3c3ccccc32)cc1-n1c2ccccc2c2ccccc21 ; c1ccc2c(c1)c1ccccc1n2-c1cc(-n2c3ccccc3c3ccccc32)c(-n2c3ccccc3c3ccccc32)c(-n2c3ccccc3c3ccccc32)c1-n1c2ccccc2c2ccccc21]

### Exciton Barrier Layer

An exciton barrier layer inhibits excitons generated through recombination of holes and electrons in the light-emitting layer from being diffused to the charge transporting layer. In some embodiments, the exciton barrier layer enables effective confinement of excitons in the light-emitting layer. In some embodiments, the light emission efficiency of the device is enhanced. In some embodiments, the exciton barrier layer is adjacent to the light-emitting layer on any of the side of the anode and the side of the cathode, and on both the sides. In some embodiments, where the exciton barrier layer is on the side of the anode, the layer can be between the hole transporting layer and the light-emitting layer and adjacent to the light-emitting layer. In some embodiments, where the exciton barrier layer is on the side of the cathode, the layer can be between the light-emitting layer and the cathode and adjacent to the light-emitting layer. In some embodiments, a hole injection layer, an electron barrier layer, or a similar layer is between the anode and the exciton barrier layer that is adjacent to the light-emitting layer on the side of the anode. In some embodiments, a hole injection layer, an electron barrier layer, a hole barrier layer, or a similar layer is between the cathode and the exciton barrier layer that is adjacent to the light-emitting layer on the side of the cathode. In some embodiments, the exciton barrier layer comprises excited singlet energy and excited triplet energy, at least one of which is higher than the excited singlet energy and the excited triplet energy of the light-emitting material, respectively.

### Hole Transporting Layer

The hole transporting layer comprises a hole transporting material. In some embodiments, the hole transporting layer is a single layer. In some embodiments, the hole transporting layer comprises a plurality layers.

In some embodiments, the hole transporting material has one of injection or transporting property of holes and barrier property of electrons. In some embodiments, the hole transporting material is an organic material. In some embodiments, the hole transporting material is an inorganic material. Examples of known hole transporting materials that may be used herein include but are not limited to a triazole derivative, an oxadiazole derivative, an imidazole derivative, a carbazole derivative, an indolocarbazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline copolymer and an electroconductive polymer oligomer, particularly a thiophene oligomer, or a combination thereof. In some embodiments, the hole transporting material is selected from a porphyrin compound, an aromatic tertiary amine compound, and a styrylamine compound. In some embodiments, the hole transporting material is an aromatic tertiary amine compound. Preferred compound examples for use as the hole transporting material are shown below.

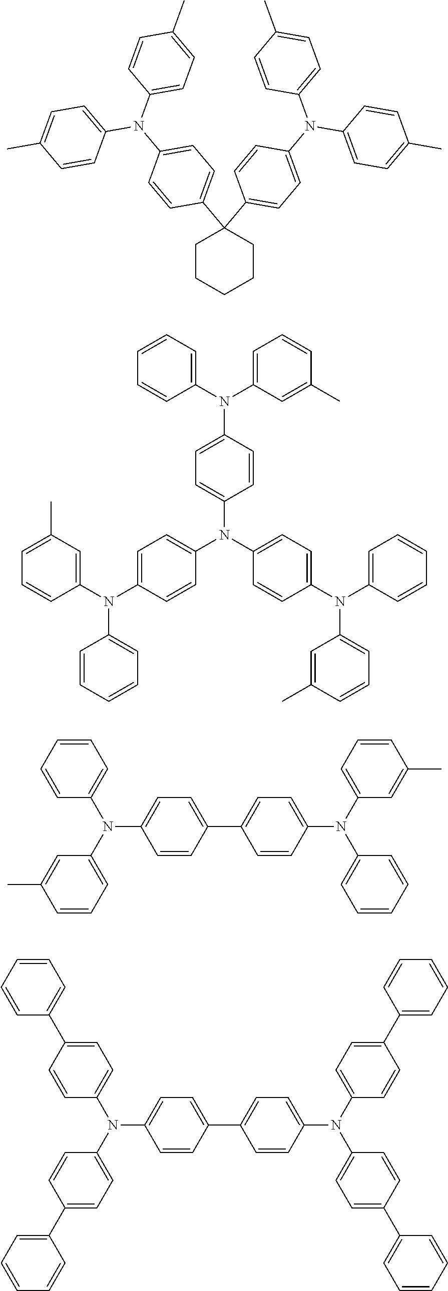

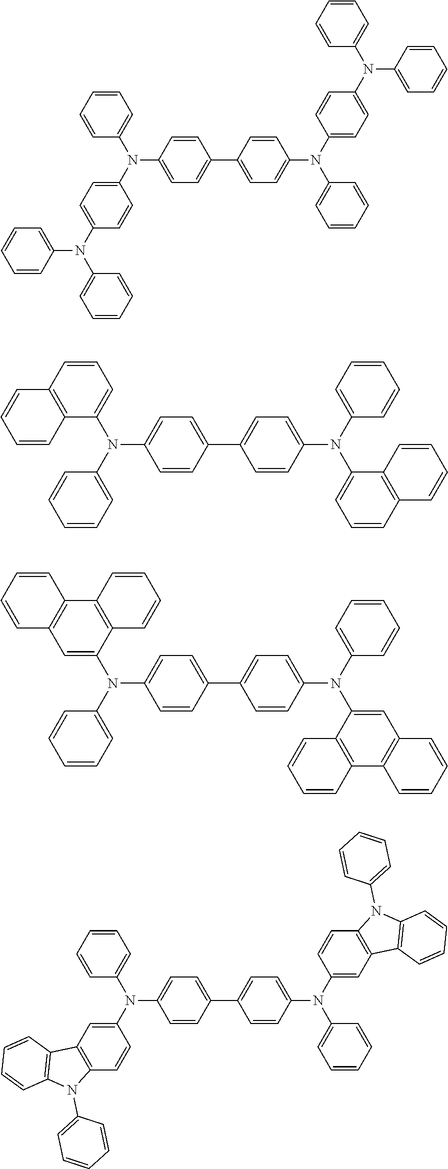 [SMILES: c1ccc(N(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1 ; c1ccc(N(c2ccc(-c3ccc(N(c4ccccc4)c4cccc5ccccc45)cc3)cc2)c2cccc3ccccc23)cc1 ; c1ccc(N(c2ccc(-c3ccc(N(c4ccccc4)c4cc5ccccc5c5ccccc45)cc3)cc2)c2cc3ccccc3c3ccccc23)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

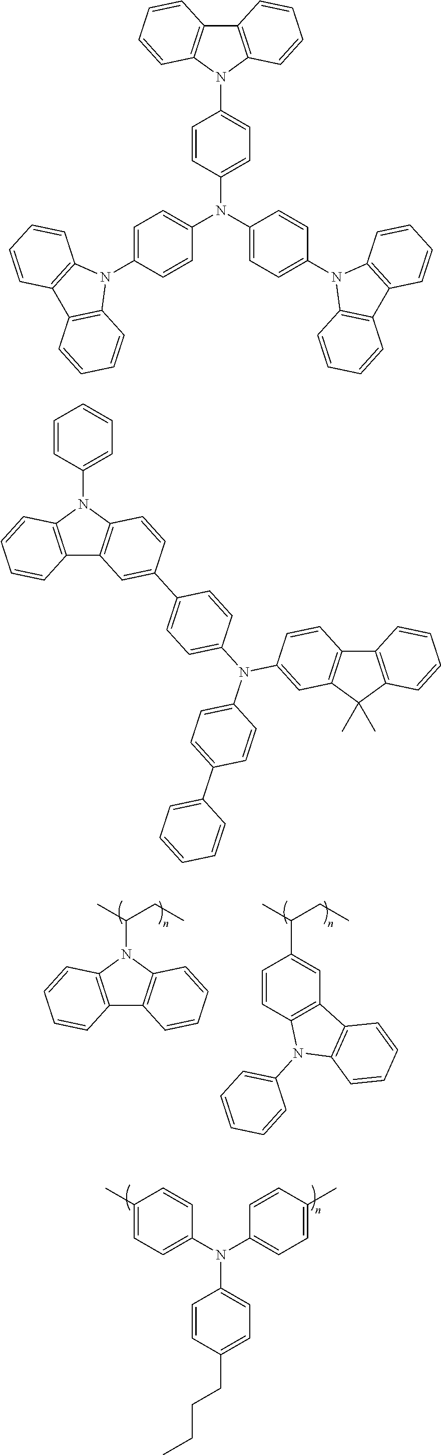

### Electron Transporting Layer

The electron transporting layer comprises an electron transporting material. In some embodiments, the electron transporting layer is a single layer. In some embodiments, the electron transporting layer comprises a plurality of layer.

In some embodiments, the electron transporting material needs only to have a function of transporting electrons, which are injected from the cathode, to the light-emitting layer. In some embodiments, the electron transporting material also function as a hole barrier material. Examples of the electron transporting layer that may be used herein include but are not limited to a nitro-substituted fluorene derivative, a diphenylquinone derivative, a thiopyran dioxide derivative, carbodiimide, a fluorenylidene methane derivative, anthraquinodimethane, an anthrone derivatives, an azole derivative, an azine derivative, an oxadiazole derivative, or a combination thereof, or a polymer thereof. In some embodiments, the electron transporting material is a thiadiazole derivative, or a quinoxaline derivative. In some embodiments, the electron transporting material is a polymer material. Preferred compound examples for use as the electron transporting material are shown below.

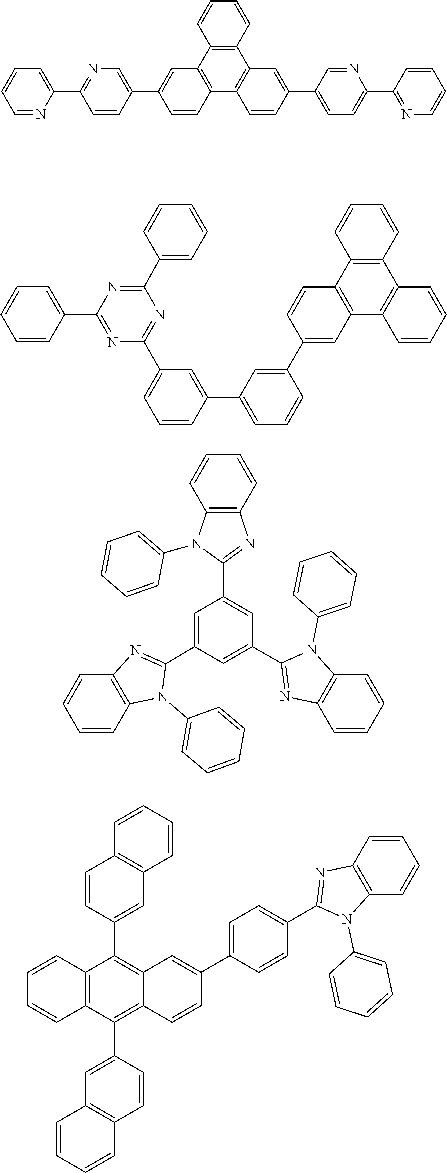

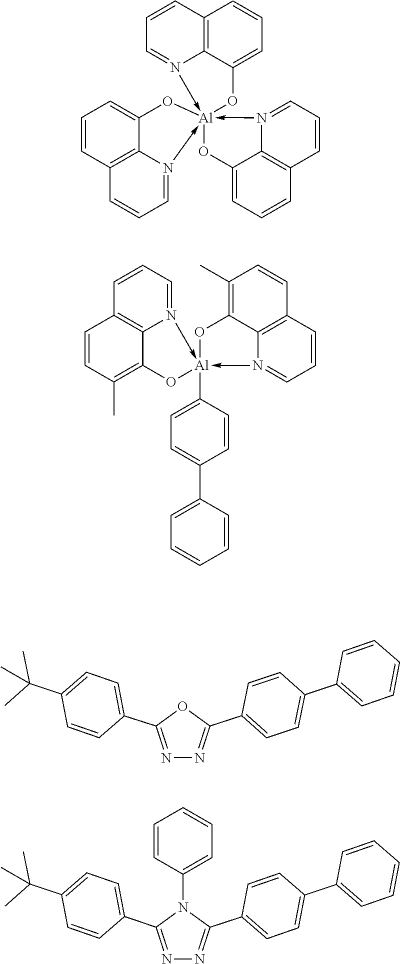

Hereinunder compound examples preferred as a material that can be added to the organic layers are shown. For example, these can be added as a stabilization material.

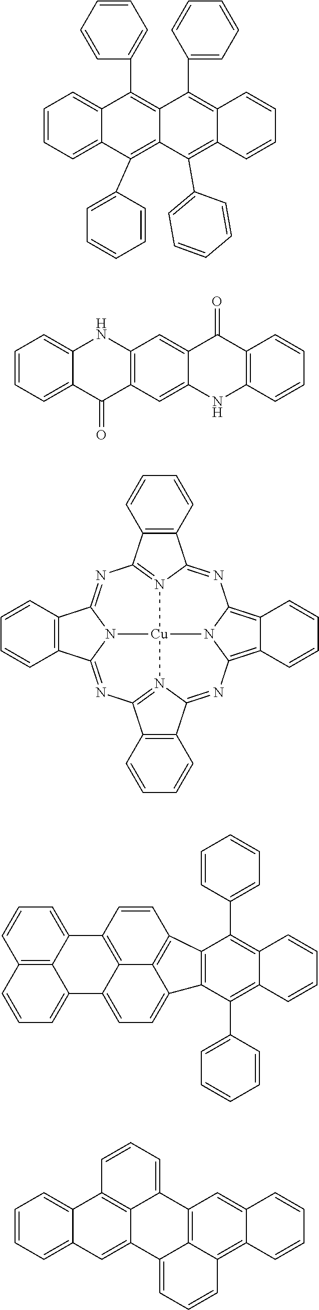

While the preferred materials that can be used in the organic electroluminescent device have been specifically exemplified, the material that can be used in the present invention are not interpreted as being limited by the aforementioned compounds. Evan though a compound is exemplified as a material having a particular function, the compound may be diverted as a material having another function.

### Devices

In some embodiments, a light emitting layer is incorporated into a device. For example, the device includes, but is not limited to an OLED bulb, an OLED lamp, a television screen, a computer monitor, a mobile phone, and a tablet.

In some embodiments, an electronic device comprises an OLED comprising an anode, a cathode, and at least one organic layer comprising a light emitting layer between the anode and the cathode.

In some embodiments, compositions described herein may be incorporated into various light-sensitive or light-activated devices, such as a OLEDs or photovoltaic devices. In some embodiments, the composition may be useful in facilitating charge transfer or energy transfer within a device and/or as a hole-transport material. The device may be, for example, an organic light-emitting diode (OLED), an organic integrated circuit (O-IC), an organic field-effect transistor (O-FET), an organic thin-film transistor (O-TFT), an organic light-emitting transistor (O-LET), an organic solar cell (O-SC), an organic optical detector, an organic photoreceptor, an organic field-quench device (O-FQD), a light-emitting electrochemical cell (LEC) or an organic laser diode (O-laser).

### Bulbs or Lamps

In some embodiments, an electronic device comprises an OLED comprising an anode, a cathode, and at least one organic layer comprising a light emitting layer between the anode and the cathode.

In some embodiments, a device comprises OLEDs that differ in color. In some embodiments, a device comprises an array comprising a combination of OLEDs. In some embodiments, the combination of OLEDs is a combination of three colors (e.g., RGB). In some embodiments, the combination of OLEDs is a combination of colors that are not red, green, or blue (for example, orange and yellow green). In some embodiments, the combination of OLEDs is a combination of two, four, or more colors.

In some embodiments, a device is an OLED light comprising:
a circuit board having a first side with a mounting surface and an opposing second side, and defining at least one aperture;
at least one OLED on the mounting surface, the at least one OLED configured to emanate light, comprising:
   an anode, a cathode, and at least one organic layer comprising a light emitting layer between the anode and the cathode;
a housing for the circuit board; and
at least one connector arranged at an end of the housing, the housing and the connector defining a package adapted for installation in a light fixture.

In some embodiments, the OLED light comprises a plurality of OLEDs mounted on a circuit board such that light emanates in a plurality of directions. In some embodiments, a portion of the light emanated in a first direction is deflected to emanate in a second direction. In some embodiments, a reflector is used to deflect the light emanated in a first direction.

### Displays or Screens

In some embodiments, the compounds of the invention can be used in a screen or a display. In some embodiments, the compounds of the invention are deposited onto a substrate using a process including, but not limited to, vacuum evaporation, deposition, vapor deposition, or chemical vapor deposition (CVD). In some embodiments, the substrate is a photoplate structure useful in a two-sided etch provides a unique aspect ratio pixel. The screen (which may also be referred to as a mask) is used in a process in the manufacturing of OLED displays. The corresponding artwork pattern design facilitates a very steep and narrow tie-bar between the pixels in the vertical direction and a large, sweeping bevel opening in the horizontal direction. This allows the close patterning of pixels needed for high definition displays while optimizing the chemical deposition onto a TFT backplane.

The internal patterning of the pixel allows the construction of a 3-dimensional pixel opening with varying aspect ratios in the horizontal and vertical directions. Additionally, the use of imaged “stripes” or halftone circles within the pixel area inhibits etching in specific areas until these specific patterns are undercut and fall off the substrate. At that point the entire pixel area is subjected to a similar etch rate but the depths are varying depending on the halftone pattern. Varying the size and spacing of the halftone pattern allows etching to be inhibited at different protection rates within the pixel allowing for a localized deeper etch needed to create steep vertical bevels.

A preferred material for the deposition mask is invar. Invar is a metal alloy that is cold rolled into long thin sheet in a steel mill. Invar cannot be electrodeposited onto a rotating mandrel as the nickel mask. A preferred and more cost feasible method for forming the open areas in the mask used for deposition is through a wet chemical etching.

In some embodiments, a screen or display pattern is a pixel matrix on a substrate. In some embodiments, a screen or display pattern is fabricated using lithography (e.g., photolithography and e-beam lithography). In some embodiments, a screen or display pattern is fabricated using a wet chemical etch. In further embodiments, a screen or display pattern is fabricated using plasma etching.

### Methods of Manufacturing Devices Using the Disclosed Compounds

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light-emitting layer, a counter electrode, and an encapsulation layer, and then is cut from the mother panel.

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light-emitting layer, a counter electrode, and an encapsulation layer, and then is cut from the mother panel.

In another aspect, provided herein is a method of manufacturing an organic light-emitting diode (OLED) display, the method comprising:
forming a barrier layer on a base substrate of a mother panel;
forming a plurality of display units in units of cell panels on the barrier layer;
forming an encapsulation layer on each of the display units of the cell panels;
applying an organic film to an interface portion between the cell panels.

In some embodiments, the barrier layer is an inorganic film formed of, for example, SiNx, and an edge portion of the barrier layer is covered with an organic film formed of polyimide or acryl. In some embodiments, the organic film helps the mother panel to be softly cut in units of the cell panel.

In some embodiments, the thin film transistor (TFT) layer includes a light-emitting layer, a gate electrode, and a source/drain electrode. Each of the plurality of display units may include a thin film transistor (TFT) layer, a planarization film formed on the TFT layer, and a light-emitting unit formed on the planarization film, wherein the organic film applied to the interface portion is formed of a same material as a material of the planarization film and is formed at a same time as the planarization film is formed. In some embodiments, a light-emitting unit is connected to the TFT layer with a passivation layer and a planarization film therebetween and an encapsulation layer that covers and protects the light-emitting unit. In some embodiments of the method of manufacturing, the organic film contacts neither the display units nor the encapsulation layer.

Each of the organic film and the planarization film may include any one of polyimide and acryl. In some embodiments, the barrier layer may be an inorganic film. In some embodiments, the base substrate may be formed of polyimide. The method may further include, before the forming of the barrier layer on one surface of the base substrate formed of polyimide, attaching a carrier substrate formed of a glass material to another surface of the base substrate, and before the cutting along the interface portion, separating the carrier substrate from the base substrate. In some embodiments, the OLED display is a flexible display.

In some embodiments, the passivation layer is an organic film disposed on the TFT layer to cover the TFT layer. In some embodiments, the planarization film is an organic film formed on the passivation layer. In some embodiments, the planarization film is formed of polyimide or acryl, like the organic film formed on the edge portion of the barrier layer. In some embodiments, the planarization film and the organic film are simultaneously formed when the OLED display is manufactured. In some embodiments, the organic film may be formed on the edge portion of the barrier layer such that a portion of the organic film directly contacts the base substrate and a remaining portion of the organic film contacts the barrier layer while surrounding the edge portion of the barrier layer.

In some embodiments, the light-emitting layer includes a pixel electrode, a counter electrode, and an organic light-emitting layer disposed between the pixel electrode and the counter electrode. In some embodiments, the pixel electrode is connected to the source/drain electrode of the TFT layer.

In some embodiments, when a voltage is applied to the pixel electrode through the TFT layer, an appropriate voltage is formed between the pixel electrode and the counter electrode, and thus the organic light-emitting layer emits light, thereby forming an image. Hereinafter, an image forming unit including the TFT layer and the light-emitting unit is referred to as a display unit.

In some embodiments, the encapsulation layer that covers the display unit and prevents penetration of external moisture may be formed to have a thin film encapsulation structure in which an organic film and an inorganic film are alternately stacked. In some embodiments, the encapsulation layer has a thin film encapsulation structure in which a plurality of thin films are stacked. In some embodiments, the organic film applied to the interface portion is spaced apart from each of the plurality of display units. In some embodiments, the organic film is formed such that a portion of the organic film directly contacts the base substrate and a remaining portion of the organic film contacts the barrier layer while surrounding an edge portion of the barrier layer.

In one embodiment, the OLED display is flexible and uses the soft base substrate formed of polyimide. In some embodiments, the base substrate is formed on a carrier substrate formed of a glass material, and then the carrier substrate is separated.

In some embodiments, the barrier layer is formed on a surface of the base substrate opposite to the carrier substrate. In one embodiment, the barrier layer is patterned according to a size of each of the cell panels. For example, while the base substrate is formed over the entire surface of a mother panel, the barrier layer is formed according to a size of each of the cell panels, and thus a groove is formed at an interface portion between the barrier layers of the cell panels. Each of the cell panels can be cut along the groove.

In some embodiments, the method of manufacture further comprises cutting along the interface portion, wherein a groove is formed in the barrier layer, wherein at least a portion of the organic film is formed in the groove, and wherein the groove does not penetrate into the base substrate. In some embodiments, the TFT layer of each of the cell panels is formed, and the passivation layer which is an inorganic film and the planarization film which is an organic film are disposed on the TFT layer to cover the TFT layer. At the same time as the planarization film formed of, for example, polyimide or acryl is formed, the groove at the interface portion is covered with the organic film formed of, for example, polyimide or acryl. This is to prevent cracks from occurring by allowing the organic film to absorb an impact generated when each of the cell panels is cut along the groove at the interface portion. That is, if the entire barrier layer is entirely exposed without the organic film, an impact generated when each of the cell panels is cut along the groove at the interface portion is transferred to the barrier layer, thereby increasing the risk of cracks. However, in one embodiment, since the groove at the interface portion between the barrier layers is covered with the organic film and the organic film absorbs an impact that would otherwise be transferred to the barrier layer, each of the cell panels may be softly cut and cracks may be prevented from occurring in the barrier layer. In one embodiment, the organic film covering the groove at the interface portion and the planarization film are spaced apart from each other. For example, if the organic film and the planarization film are connected to each other as one layer, since external moisture may penetrate into the display unit through the planarization film and a portion where the organic film remains, the organic film and the planarization film are spaced apart from each other such that the organic film is spaced apart from the display unit.

In some embodiments, the display unit is formed by forming the light-emitting unit, and the encapsulation layer is disposed on the display unit to cover the display unit. As such, once the mother panel is completely manufactured, the carrier substrate that supports the base substrate is separated from the base substrate. In some embodiments, when a laser beam is emitted toward the carrier substrate, the carrier substrate is separated from the base substrate due to a difference in a thermal expansion coefficient between the carrier substrate and the base substrate.

In some embodiments, the mother panel is cut in units of the cell panels. In some embodiments, the mother panel is cut along an interface portion between the cell panels by using a cutter. In some embodiments, since the groove at the interface portion along which the mother panel is cut is covered with the organic film, the organic film absorbs an impact during the cutting. In some embodiments, cracks may be prevented from occurring in the barrier layer during the cutting.

In some embodiments, the methods reduce a defect rate of a product and stabilize its quality.

Another aspect is an OLED display including: a barrier layer that is formed on a base substrate; a display unit that is formed on the barrier layer; an encapsulation layer that is formed on the display unit; and an organic film that is applied to an edge portion of the barrier layer.

### EXAMPLES

The present invention will be described more specifically with reference to examples below. The materials, the contents of the process, the procedures of the process, and the like shown below can be appropriately modified unless deviating from the substance of the present invention. Therefore, the scope of the present invention should not be interpreted as being limited by the specific examples shown below. The light emission capabilities were evaluated by using a source meter (2400 Series, available from Keithley, Tektronix, Inc.), a semiconductor parameter analyzer (E5273A, available from Agilent Technologies, Inc.), an optical power meter (1930C, available from Newport Corporation), an optical spectrometer (USB2000, available from Ocean Optics, Inc.), a spectroradiometer (SR-3, available from Topcon Corporation), and a streak camera (Model C4334, available from Hamamatsu Photonics K.K.).

### Example 1

In Example 1, it was investigated how the S value of the light emitting layer changed depending on the material of the base layer.

On a glass substrate, one of U1 to U5 and a comparative compound (H1) was vapor-deposited to form a base layer having a thickness of 10 nm. On the base layer, H1 and T60 were vapor-co-deposited at a weight ratio of 65/35 from separate vapor deposition sources to form a light emitting layer having a thickness of 40 nm. The S value of T60 in the light emitting layer formed was measured. The results are shown in Table 1.

The results of Table 1 show that the S value of the second organic compound of the light emitting layer in the present invention using the base layer formed of the compound represented by the general formula (1) is smaller than that in the comparative example using the base layer formed of the same material (H1) as the first organic compound contained in the light emitting layer in an amount of 65% by weight. This shows that the use of the compound represented by the general formula (1) in the base layer can significantly enhance the orientation of the second organic compound of the light emitting layer formed thereon.

TABLE 1

| Constitutional material | |
|---|---|
| of base layer | S Value |
| H1 (comparative example) | −0.18 |
| U1 (present invention) | −0.29 |
| U2 (present invention) | −0.28 |
| U3 (present invention) | −0.25 |
| U4 (present invention) | −0.24 |
| U5 (present invention) | −0.23 |

### Example 2

In Example 2, it was investigated how the S value of the light emitting layer changed depending on the change of the combination of the material of the base layer and the first organic compound of the light emitting layer.

A base layer and a light emitting layer were formed on a glass substrate in the same manner as in Example 1 except that the combination of the material of the base layer and the first organic compound of the light emitting layer was changed as shown in Table 2. The S value of T60 in the light emitting layer formed was measured. The results are shown in Table 2.

The results of Table 2 show that the orientation of the second organic compound of the light emitting layer can be further enhanced not only by constituting the base layer with the compound represented by the general formula (1), but also by using the compound represented by the general formula (1) as the first organic compound contained in the light emitting layer.

TABLE 2

| Constitutional material | First organic compound | |
|---|---|---|
| of base layer | of light emitting layer | S Value |
| H1 (comparative example) | H1 | −0.18 |
| U4 (present invention) | U5 | −0.33 |
| U4 (present invention) | U2 | −0.25 |
| U5 (present invention) | U5 | −0.28 |
| U2 (present invention) | U2 | −0.22 |

### Example 3

In Example 3, the relationship between the material of the base layer and the S value of the light emitting layer when changing the second organic compound of the light emitting layer was investigated.

A base layer and a light emitting layer were formed on a glass substrate in the same manner as in Example 1 except that the second organic compound of the light emitting layer was changed from T60 to T3, and the combination of the material of the base layer and the first organic compound of the light emitting layer was changed as shown in Tables 3 and 4. At this time, the weight ratio of the first organic compound and the second organic compound of the light emitting layer was changed to 70/30. The S value of T3 in the light emitting layer formed was measured. The results are shown in Tables 3 and 4.

The results of Tables 3 and 4 show that even though the second organic compound of the light emitting layer is changed to another delayed fluorescent material, the use of the compound represented by the general formula (1) in the base layer can significantly enhance the orientation of the second organic compound of the light emitting layer formed thereon. Furthermore, the results show that the orientation of the second organic compound of the light emitting layer can be further enhanced by using the compound represented by the general formula (1) as the first organic compound contained in the light emitting layer.

TABLE 3

| Constitutional material | First organic compound | |
|---|---|---|
| of base layer | of light emitting layer | S Value |
| H1 (comparative example) | H1 | −0.26 |
| U4 (present invention) | H1 | −0.34 |
| U5 (present invention) | H1 | −0.30 |

TABLE 4

| | First organic | |
|---|---|---|
| Constitutional material | compound of | |
| of base layer | light emitting layer | S Value |
| U4 (present invention) | U5 | −0.39 |
| U4 (present invention) | U2 | −0.40 |
| U4 (present invention) | U3 | −0.41 |
| U5 (present invention) | U5 | −0.39 |
| U2 (present invention) | U2 | −0.40 |

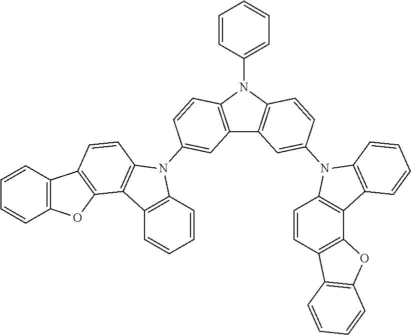 [SMILES: c1ccc(-n2c3ccc(-n4c5ccccc5c5c6oc7ccccc7c6ccc54)cc3c3cc(-n4c5ccccc5c5c6oc7ccccc7c6ccc54)ccc32)cc1]

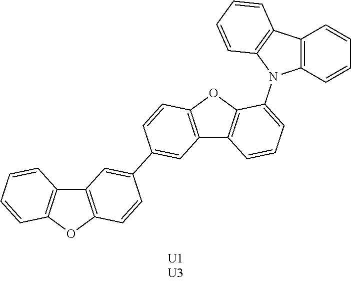 [SMILES: c1ccc2c(c1)oc1ccc(-c3ccc4oc5c(-n6c7ccccc7c7ccccc76)cccc5c4c3)cc12]

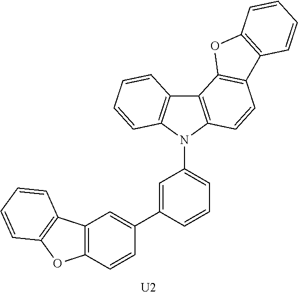

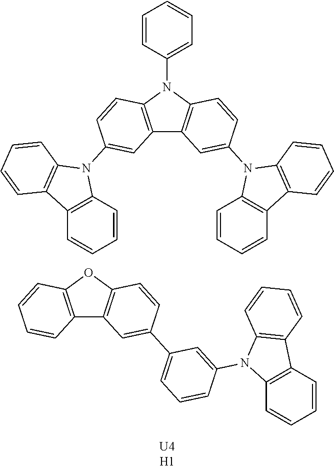

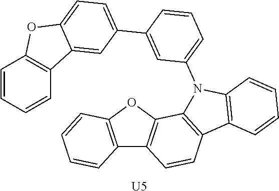

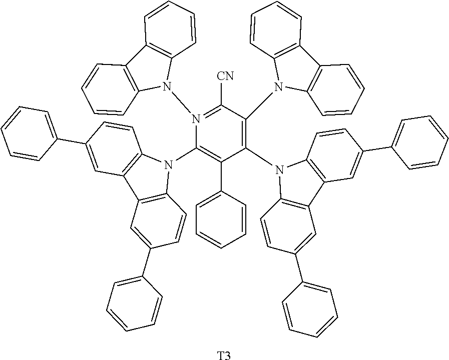

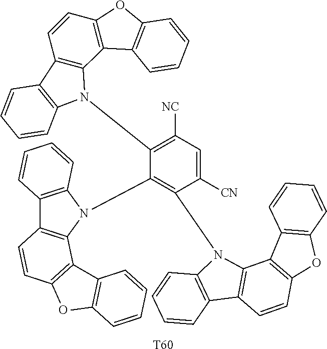

### Example 4

In Example 4, organic electroluminescent devices having various base layers were produced and evaluated.

Thin films were laminated by the vacuum vapor deposition method at a vacuum degree of 1×10⁻⁶ Pa on a glass substrate having formed thereon an anode formed of indium tin oxide (ITO) having a thickness of 100 nm. HATCN was formed on ITO to a thickness of 10 nm, and NPD was formed thereon to a thickness of 35 nm. Subsequently, U4 was formed thereon to a thickness of 10 nm as a base layer, and H1 and T3 were vapor-co-deposited at a weight ratio of 70/30 from separate vapor deposition sources to form a light emitting layer having a thickness of 40 nm. HB1 was further formed thereon to a thickness of 10 nm, and furthermore, HB1 and Liq were vapor-co-deposited at a weight ratio of 70/30 from separate vapor deposition sources to a thickness of 20 nm. Furthermore, Liq was formed to a thickness of 2 nm, and then aluminum (Al) was vapor deposited to a thickness of 100 nm to form a cathode. An organic electroluminescent device of the present invention was produced according to the aforementioned procedures.

For compassion, a comparative organic electroluminescent device using a base layer constituted by H1 was produced.

When the device was driven, light emission having a maximum light emission wavelength of 484 nm was observed. The results of the measurement of the external quantum efficiency (EQE) and the initial driving voltage of the devices are shown in Table 5. The results of Table 5 show that the use of the compound represented by the general formula (1) in the base layer enhances the orientation of the second organic compound in the light emitting layer, enhances the light emission efficiency of the device, and suppresses the initial driving voltage.

TABLE 5

| Constitutional material | | | Initial driving |
|---|---|---|---|
| of base layer | S Value | EQE (%) | voltage (V) |
| H1 (comparative example) | −0.26 | 17.0 | 5.01 |
| U4 (present invention) | −0.34 | 19.3 | 5.01 |

### Example 5

In Example 5, organic electroluminescent devices using various first organic compounds of the light emitting layer were produced and evaluated.

An organic electroluminescent device was produced in the same manner as in Example 4 except that the base layer was formed with U4, and the first organic compound of the light emitting layer was changed to H1 or U5. The results of the measurement of the S value, the external quantum efficiency (EQE), and the initial driving voltage of the devices as similar to Example 4 are shown in Table 6. The results of Table 6 show that the orientation of the second organic compound of the light emitting layer can be further enhanced, the light emission efficiency of the device can be enhanced, and the initial driving voltage can be suppressed, not only by constituting the base layer with the compound represented by the general formula (1), but also by using the compound represented by the general formula (1) as the first organic compound contained in the light emitting layer.

TABLE 6

| Constitutional material | First organic compound | | | Initial driving |
|---|---|---|---|---|
| of base layer | of light emitting layer | S Value | EQE (%) | voltage (V) |
| U4 (present invention) | H1 | −0.30 | 24.1 | 3.6 |
| U4 (present invention) | U5 | −0.39 | 25.2 | 3.5 |

### Example 6

In Example 6, organic electroluminescent devices having a light emitting layer further containing the third organic compound having lowest excited singlet energy lower than the first organic compound and the second organic compound were produced.

An organic electroluminescent device was produced in the same manner as in Example 4 except that F1 was further added to the light emitting layer in an amount of 0.5% by weight as the third organic compound, and the concentration of the first organic compound was changed to 69.5% by weight.

The S value measured for the devices as similar to Example 4 was −0.293 for the device using H1 in the base layer, and −0.344 for the device using U4 in the base layer. The initial driving voltage was also smaller in the device using U4 in the base layer. The results show that the use of the base layer constituted by the compound represented by the general formula (1) can enhance the orientation of the second organic compound of the light emitting layer, and can suppress the initial driving voltage.

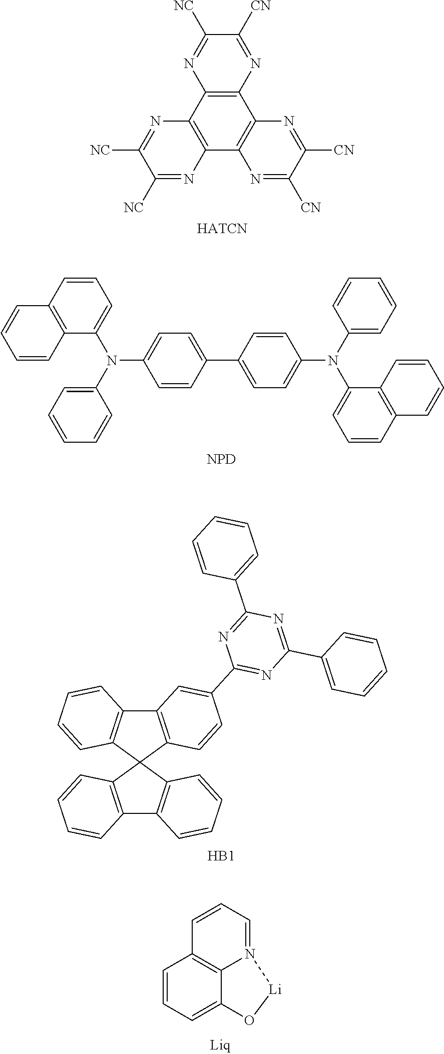

### INDUSTRIAL APPLICABILITY

The use of the compound represented by the general formula (1) in the base layer according to the present invention can enhance the orientation of the light emitting material of the light emitting layer formed thereon. Accordingly, an organic electroluminescent device having a high light emission efficiency can be provided. According to the production method of the present invention, an organic light emitting device having a light emitting layer that has a high orientation of the light emitting material can be easily produced. Consequently, the present invention has high industrial applicability.

### REFERENCE SIGN LIST

1: Substrate
2: Anode
3: Hole injection layer
4: Hole transporting layer
5: Base layer
6: Light emitting layer
7: Hole barrier layer
8: Electron transporting layer
9: Electron injection layer
10: Cathode

1. An organic light emitting device comprising a base layer and a light emitting layer laminated on a surface of the base layer,
the light emitting layer containing a first organic compound and a second organic compound,
the second organic compound being a delayed fluorescent material having lowest excited singlet energy that is lower than the first organic compound,
the base layer containing a compound represented by the following general formula (1): 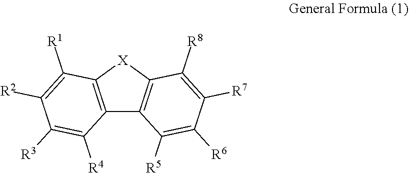
wherein in the general formula (1), X represents O, S, or N(R⁹), R¹ to R⁸ each independently represent a hydrogen atom, a deuterium atom, or a substituent, and R⁹ represents a substituent, in which R¹ and R², R² and R³, R³ and R⁴, R⁵ and R⁶, R⁶ and R⁷, and R⁷ and R⁸ each may be bonded to each other to form a hydrocarbon ring, and a hydrogen atom of the hydrocarbon ring may be substituted,
provided that R¹ and R², R² and R³, or R³ and R⁴ are bonded to each other to form a substituted or unsubstituted benzofuro structure, a substituted or unsubstituted benzothieno structure, or a substituted or unsubstituted indolo structure, or
R⁶ represents a substituted or unsubstituted carbazolyl group, a substituted or unsubstituted dibenzofuryl group, or a substituted or unsubstituted dibenzothienyl group.

2. The organic light emitting device according to claim 1, wherein all condensed ring structures included in the compound each contain 5 or less rings.

3. The organic light emitting device according to claim 1, wherein all condensed ring structures included in the compound each contain 3 or less rings.

4. The organic light emitting device according to claim 1, wherein X represents N(R⁹), and R⁹ represents a substituted or unsubstituted aryl group.

5. The organic light emitting device according to claim 1, wherein R¹ and R², R² and R³, or R³ and R⁴ are bonded to each other to form a substituted or unsubstituted benzofuro structure.

6. The organic light emitting device according to claim 1, wherein in the case where X represents N(R⁹), and R⁶ represents a substituted or unsubstituted carbazolyl group, the carbazolyl group is a substituted or unsubstituted carbazol-9-yl group.

7. The organic light emitting device according to claim 1, wherein the first organic compound includes a carbazole structure, a dibenzofuran structure, or a dibenzothiophene structure.

8. The organic light emitting device according to claim 1, wherein the first organic compound is a compound represented by the general formula (1), and may be the same as or different from the compound contained in the base layer.

9. The organic light emitting device according to claim 1, wherein the second organic compound includes a carbazole structure, a dibenzofuran structure, or a dibenzothiophene structure.

10. The organic light emitting device according to claim 1, wherein the second organic compound has a difference ΔE_{ST} in energy between lowest excited singlet state and lowest excited triplet state at 77 K of 0.3 eV or less.

11. The organic light emitting device according to claim 1, wherein the second organic compound is a compound consisting of atoms selected from the group consisting of a carbon atom, a hydrogen atom, a deuterium atom, a nitrogen atom, an oxygen atom, and a sulfur atom.

12. The organic light emitting device according to claim 1, wherein the light emitting layer has a concentration of the second organic compound of 5 to 50% by weight.

13. The organic light emitting device according to claim 1, wherein the light emitting layer further contains a third organic compound having lowest excited singlet energy that is lower than the first organic compound and the second organic compound.

14. The organic light emitting device according to claim 13, wherein the light emitting layer has a concentration of the third organic compound of 3% by weight or less.

15. The organic light emitting device according to claim 13, wherein the third organic compound is a compound consisting of atoms selected from the group consisting of a carbon atom, a hydrogen atom, a deuterium atom, a nitrogen atom, a boron atom, a fluorine atom, an oxygen atom, and a sulfur atom.

16. The organic light emitting device according to claim 1, wherein the organic light emitting device is an organic electroluminescent device.

17. The organic light emitting device according to claim 16, wherein the base layer is an electron barrier layer.

18. A method of producing an organic light emitting device, comprising forming a light emitting layer on a surface of a base layer,
the light emitting layer containing a first organic compound and a second organic compound,
the second organic compound being a delayed fluorescent material having lowest excited singlet energy that is lower than the first organic compound,
the base layer containing a compound represented by the general formula (1):
General Formula (1) 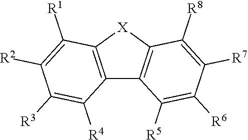
wherein in the general formula (1), X represents O, S, or N(R⁹), R¹ to R⁸ each independently represent a hydrogen atom, a deuterium atom, or a substituent, and R⁹ represents a substituent, in which R¹ and R², R² and R³, R³ and R⁴, R⁵ and R⁶, R⁶ and R⁷, and R⁷ and R⁸ each may be bonded to each other to form a hydrocarbon ring, and a hydrogen atom of the hydrocarbon ring may be substituted,
provided that R¹ and R², R² and R³, or R³ and R⁴ are bonded to each other to form a substituted or unsubstituted benzofuro structure, a substituted or unsubstituted benzothieno structure, or a substituted or unsubstituted indolo structure, or
R⁶ represents a substituted or unsubstituted carbazolyl group, a substituted or unsubstituted dibenzofuryl group, or a substituted or unsubstituted dibenzothienyl group.
